(19) United States
(12) Patent Application Publication
(10) Pub. No.: US 2011/0013865 A1
(43) Pub. Date: Jan. 20, 2011

(54) METHOD OF MANUFACTURING WIRING BOARD, METHOD OF MANUFACTURING OPTOELECTRIC COMPOSITE MEMBER, AND METHOD OF MANUFACTURING OPTOELECTRIC COMPOSITE BOARD

(76) Inventors: Tomoaki Shibata, Ibaraki (JP); Daichi Sakai, Ibaraki (JP); Toshihiro Kuroda, Ibaraki (JP); Shigeyuki Yagi, Ibaraki (JP); Atsushi Takahashi, Ibaraki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/736,297

(22) PCT Filed: Mar. 30, 2009
(86) PCT No.: PCT/JP2009/056454

§ 371 Date: Sep. 28, 2010

(30) Foreign Application Priority Data
Mar. 28, 2008 (JP) 2008 086981
Mar. 28, 2008 (JP) 2008 086987
Oct. 8, 2008 (JP) 2008 261621
Oct. 8, 2008 (JP) 2008 261629

(51) Int. Cl. H05K 3/46; G02B 6/12

(52) U.S. Cl. 385/14; 156/150; 216/13

(57) ABSTRACT

A method for producing a circuit board, contains, in this order, a step A of forming a circuit on a first substrate; a step B of laminating a first support on a surface of the first substrate having the circuit formed, through a first releasing layer; and a step C of forming a second substrate or circuit on a surface of the first substrate opposite to the surface having the circuit formed, and a method for producing an optoelectronic composite member, contains, in this order, a step of laminating an electric circuit board on a second support; a step of laminating a first support; a step of releasing the second support; and a step of forming an optical waveguide on a surface where the second support is released.

A method for producing a circuit board capable of forming a circuit with a uniform width and forming a circuit with good dimensional stability, and a method for producing an optoelectronic composite member capable of reducing distortion formed in an optical waveguide during the production process, thereby enhancing the dimensional stability are provided.

### TECHNICAL FIELD

The present invention relates to a method for producing a circuit board that is capable of processing a width of a wiring uniformly and forming a circuit with good dimensional stability, a method for producing an optoelectronic composite member that is decreased in distortion occurring in an optical waveguide in a production process, a method for producing an optoelectronic composite substrate, an optoelectronic composite substrate produced thereby, and an optoelectronic composite substrate module using the same.

### BACKGROUND ART

Along with remarkable progress of information-intensive society in recent years, consumer equipments, such as personal computers and mobile phones, are being subjected to reduction in size and weight and enhancement in performance and capability, and industrial equipments, such as wireless base stations, optical communication devices and network devices including servers and routers, are also demanded to be enhanced in capability irrespective of the scale thereof.

According to the increase of information traffic, there is a tendency of increasing the frequency of signals to be handled, and thus high-speed processing and high-speed transmission techniques are being developed.

For these purposes, a build-up type multilayer circuit board is being used as a flexible board including a semiconductor chip-mounted board and a mother board for achieving the high frequency, the high-density wiring and the high capability.

In the formation of the high-density fine wiring, the wiring width and the wiring distance of the wiring that are produced by the subtractive method, in which the wiring is formed by etching, with good yield are limited to 50 μm and 50 μm respectively.

For forming a finer wiring, a semi-additive method is started to be employed, in which a plating resist is formed on a relatively thin metal layer (a seed layer) formed on a surface of an insulating layer, a wiring is formed by electroplating to a necessary thickness, the plating resist is released, and then the seed layer is removed by soft etching. As the method for forming the seed layer, an electroless plating method, a method of adhering a thin metal foil and a method of forming by a sputtering method are ordinarily known, and there is a tendency of decreasing the pitch thereof year by year.

A circuit board having an interlayer dielectric layer and at least one layer of circuits is proposed, in which at least one layer of circuits has a mixed layer containing a metal and an insulating material between the circuit and the interlayer dielectric layer, and the mixed layer is removed to make an insulating resistance between the circuits of 1 GΩ or more (see Patent Document 1).

In the high-speed and high-density signal transmission between electronic devices or circuit boards, transmission with a conventional electric wiring appears to encounter a limitation on enhancement in speed and density due to the mutual interference and attenuation of signals as barriers. In order to break the barriers, a so-called optical interconnection, i.e., a technique of connecting electronic devices or circuit boards with light, is proposed, and various investigations are made for forming a composite of an electric wiring and an optical wiring.

Specifically, an optoelectronic composite board formed by combining an optical transmission path with an electric circuit board is developed for short-distance signal transmission between boards inside a router or a server or within the boards with light. The optical transmission path used is desirably an optical waveguide, which has high degree of freedom in wiring and can be formed with high density as compared to an optical fiber, and in particular, an optical waveguide formed of a polymer material, which is excellent in workability and economy, is promising.

The fine circuit board having a fine wiring formed therein is produced by forming a metal pattern on an insulating resin layer, and associated with reduction in thickness of the insulating layer and increase in density of the fine wiring, it is necessary to align the patterns on front and back surfaces with high accuracy. However, when the wirings are formed simultaneously on both front and back surfaces of a thin board, it is difficult to align with an electric wiring or an optical waveguide to be laminated due to distortion in dimension occurring. The method disclosed in Patent Document 1 is useful for forming a fine wiring on one surface, but it is difficult to form wirings simultaneously on both surfaces, and thus circuits are formed sequentially on each surface. In general, when wirings are formed on front and back surfaces of a board, which is fixed to a holding plate or a support substrate for dimensional stability, there is a problem that the relief of the wiring formed first is transferred to the opposite surface, thereby promoting short circuit, unevenness in wiring width, deviation in position of the wirings on the front and back surfaces, and the like, due to misregistration of the metallic pattern on the back surface. The optical waveguide also suffers the similar problem, and formation of an optical waveguide by building up on a resin or a substrate with relief promotes unevenness in wiring width, which largely influences the transmission loss. Under the circumstances, a method of forming a circuit of an electric wiring after forming an optical waveguide is adopted, as disclosed in Patent Document 2.

With respect to formation of a composite of an optical wiring and an electric wiring, a method of adhering a semiconductor chip and an optical waveguide with an adhesive sheet is proposed, as disclosed, for example, Patent Document 3. However, the method involves a problem of a complicated fabrication process due to the formation of an optical waveguide for each chip and the cutout of the adhesive film, which are performed in separate steps.

Patent Document 4 proposes formation of a composite of an optical circuit board (an optical waveguide) and an electric circuit board, which is formed easily with an adhesive in a sheet form.

What is easily thought of as a method for forming a composite of an optical wiring and an electric wiring is a method of joining an optical waveguide and an optical circuit board with an adhesive layer as described above, but in this method, it is difficult to join the optical waveguide and optical circuit board with accurate relative alignment of them, and there is a possibility of decreasing the productivity due to decrease in joining efficiency of the optical wiring and an electric wiring. As disclosed in Patent Document 5, on the other hand, there is a proposal that a flexible optical wiring film is firstly formed, a base metal layer is formed on the back surface thereof by electroless plating or vapor deposition, and patterned, and then an electric wiring is constructed by performing electrolytic plating. In this method, however, the adhesion strength between the back surface of the flexible optical wiring film and the base metal layer (the electric wiring) is insufficient, which may impair the reliability.

[Patent Document 1] JP-A-2006-93199

[Patent Document 2] JP-A-2004-341454

[Patent Document 3] JP-A-2006-39390

[Patent Document 4] JP-A-2008-122908

[Patent Document 5] U.S. Pat. No. 3,193,500

### DISCLOSURE OF THE INVENTION

An object of the present invention is to provide a method for producing a circuit board that is capable of processing a width of a wiring uniformly and forming a circuit with good dimensional stability (a first object).

In the method disclosed in Patent Document 4, an optical waveguide is formed on a support, then the support is released, an adhesive in a sheet form is adhered to the optical waveguide, and then an electric circuit board is laminated. Accordingly, it involves a problem that when the releasing strength upon releasing the optical waveguide from the support is large, the optical waveguide is elongated, or even when it can be released with a small releasing strength, the stress accumulated in the waveguide is released to cause distortion, thereby impairing the dimensional stability of the optical waveguide. Thus, another object of the present invention is to provide a method for producing an optoelectronic composite member that is decreased in distortion occurring in an optical waveguide in a production process, thereby enhancing the dimensional stability (a second object).

A further object of the present invention is to provide a method for producing an optoelectronic composite substrate excellent in productivity, an optoelectronic composite substrate produced thereby, and an optoelectronic composite substrate module using the same (a third object).

As a result of earnest investigations made by the inventors, it has been found that:

(1) the first object can be attained by fixing a substrate having a circuit formed thereon to a support through a releasing layer, and embedding the circuit on the substrate into the releasing layer,

(2) the second object can be attained by adhering an upper support onto an electric circuit board, and then releasing a lower support, in addition to the conventional method,

(3) the third object can be attained by providing an electric circuit board having a lower clad layer, and then constructing an optical waveguide containing the lower clad layer as a constitutional component, and

(4) the third object can be attained by forming a lower clad layer on a surface of a substrate having a metal foil, and then performing sequentially construction of an optical waveguide containing the lower clad layer as a constitutional element, and construction of an electric circuit board from the substrate having a metal foil.

Accordingly, the present invention provides:

(1) a method for producing a circuit board, containing, in this order, a step A of forming a circuit on a first substrate; a step B of laminating a first support on a surface of the first substrate having the circuit formed, through a first releasing layer; and a step C of forming a second substrate or circuit on a surface of the first substrate opposite to the surface having the circuit formed (a first invention),

(2) a method for producing an optoelectronic composite member, containing, in this order, a step of laminating an electric circuit board on a second support; a step of laminating a first support; a step of releasing the second support; and a step of forming an optical waveguide on a surface where the second support is released (a second invention),

(3) a method for producing an optoelectronic composite substrate, containing a first step of forming a lower clad layer on a substrate surface of an electric circuit board directly or through an adhesive layer, or forming a lower clad layer on a substrate surface of a substrate having a metal foil directly or through an adhesive layer, and then converting the metal foil of the substrate having the metal foil to a conductor pattern to construct an electric circuit board, thereby providing an electric circuit board having the lower clad layer; and a second step of forming sequentially a core pattern and an upper clad layer on the lower clad layer to construct an optical waveguide (a third invention), and

(4) a method for producing an optoelectronic composite substrate, containing a modified first step of forming a lower clad layer on a substrate surface of a substrate having a metal foil directly or through an adhesive layer; a second step of forming sequentially a core pattern and an upper clad layer on the lower clad layer to construct an optical waveguide; and a third step of converting the metal foil of the substrate having the metal foil to a conductor pattern to construct an electric circuit board (a fourth invention).

According to the method for producing a circuit board of the present invention (the first invention), upon forming wirings on the front and back surfaces, the relief of the wiring formed firstly is not transferred to the back surface of the substrate, whereby the wiring can be processed with a uniform width, and the circuit can be formed with good dimensional stability.

According to the method for producing an optoelectronic composite member of the present invention (the second invention), the distortion formed in the optical waveguide during the production process can be reduced, thereby enhancing the dimensional stability.

According to the present invention (the third invention), the optical waveguide is constructed while viewing the conductor pattern, which is easily recognized visibly, of the electric circuit board having been constructed, and thus the optical waveguide and the electric circuit board can be formed into a composite with high positional accuracy, whereby an optoelectronic composite substrate having a large area can be easily produced with good productivity.

According to the present invention (the fourth invention), conductor pattern or the like is formed while viewing the optical waveguide having been constructed, and thus the optical waveguide and the electric circuit board can be formed into a composite with high positional accuracy, whereby an optoelectronic composite substrate having a large area can be easily produced with good productivity. Furthermore, in the case where the lower clad layer is to be joined to the electric circuit board that has a high relief, air may be entrained in the joined part to impair the quality, and a relief may be formed on the lower clad layer thus joined to impair the subsequent construction of the optical waveguide. According to the present invention, however, the problems do not occur since flat members are joined to each other. Therefore, the present invention can be applied not only to the case where the electric circuit board is in a flat shape with an internal circuit, but also to the case where the electric circuit board has a high relief.

### BRIEF DESCRIPTION OF THE DRAWINGS

FIG. 1 is an illustration explaining the method for producing a circuit board of the present invention (the first invention).

FIG. 2 is an illustration explaining one embodiment of the method for producing a circuit board of the present invention (the first invention).

FIG. 3 is an illustration explaining another embodiment of the method for producing a circuit board of the present invention (the first invention).

FIG. 4 is an illustration explaining still another embodiment of the method for producing a circuit board of the present invention (the first invention).

FIG. 5 is an illustration explaining a method for measuring a relief of a substrate in the present invention (the first invention).

FIG. 6 is an illustration explaining the method for producing an optoelectronic composite member of the present invention (the second invention).

FIG. 7 is an illustration explaining one embodiment of the method for producing an optoelectronic composite member of the present invention (the second invention).

FIG. 8 is an illustration explaining another embodiment of the method for producing an optoelectronic composite member of the present invention (the second invention).

FIG. 9 is an illustration explaining still another embodiment of the method for producing an optoelectronic composite member of the present invention (the second invention).

FIG. 10 is an illustration explaining a further embodiment of the method for producing an optoelectronic composite member of the present invention (the second invention).

FIG. 11 is an illustration explaining a still further embodiment of the method for producing an optoelectronic composite member of the present invention (the second invention).

FIG. 12 is a schematic illustration showing the method for producing an optoelectronic composite substrate of the present invention (the third invention).

FIG. 13 is a schematic illustration showing the method for producing an optoelectronic composite substrate of the present invention (the fourth invention).

### EXPLANATION OF SYMBOLS

1-1 first substrate
1-2 first releasing layer
1-3 first adhesive layer
1-4 first support
1-5 second substrate
1-6 second releasing layer
1-7 second adhesive layer
1-8 second support
1-9 circuit
1-10 adhesive layer
1-11 lower clad layer
1-12 core pattern
1-13 upper clad layer
1-14 substrate
1-15 optical waveguide
1-16 substrate X
1-17 metal layer
1-101 surface of substrate on a releasing surface side where first substrate 1 has wiring
1-102 surface of the substrate on a releasing surface side where first substrate 1 has no wiring
2-1 lower support
2-2 electric circuit board
2-3 upper support
2-4 lower clad layer
2-5 core pattern
2-6 upper clad layer
2-7 substrate
2-8 optical waveguide
2-9 mirror part
2-10 electric circuit
2-11 adhesive or adhesive film
2-12 releasing sheet
2-13 lower support separating surface
2-14 upper support separating surface
3-10, 4-10 electric circuit board
3-11, 4-11 metal foil
3-12, 4-12 substrate
3-13, 4-13 substrate having metal foil
3-14, 4-14 conductor protective layer
3-20, 4-20 adhesive layer
3-30, 4-30 optical waveguide
3-31, 4-31 lower clad layer
3-32, 4-32 core pattern
3-33, 4-33 upper clad layer

### BEST MODE FOR CARRYING OUT THE INVENTION

### (I) First Invention

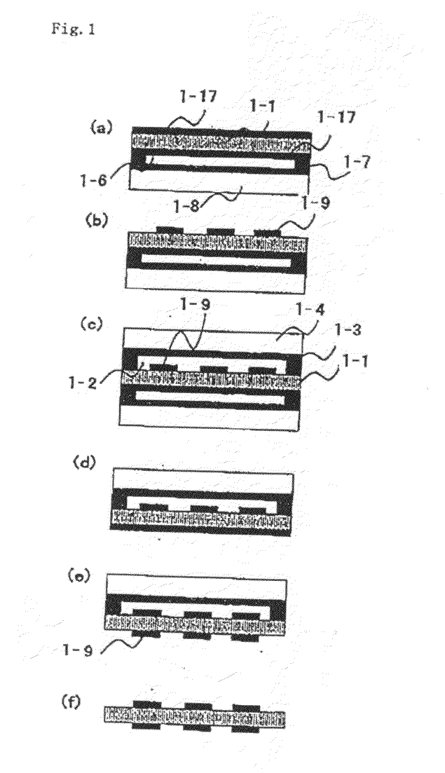

In a circuit board produced by the present invention (the first invention) contains, for example, as shown in FIG. 1(c), a first substrate 1-1 is laminated on a first support 1-4 through a releasing layer 1-2, and a circuit 1-9 of the first substrate 1-4 is embedded in the releasing layer 1-2. The first support 1-4 and the first substrate 1-1 are fixed to each other with a first adhesive layer 1-3.

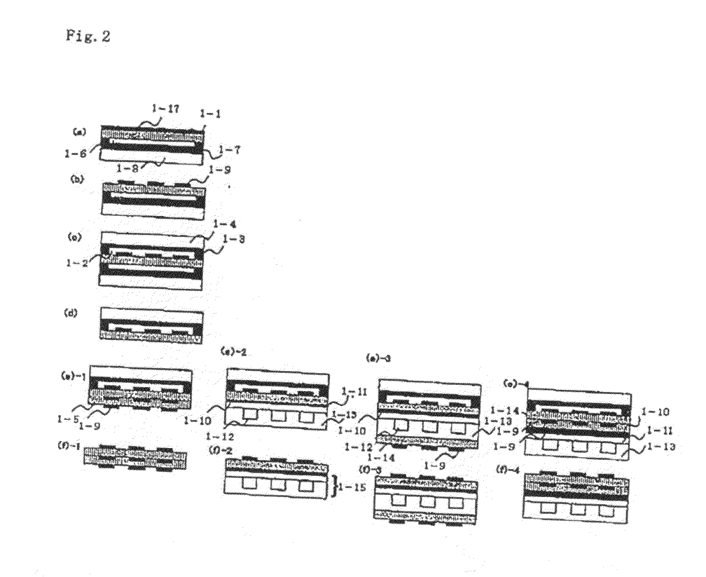

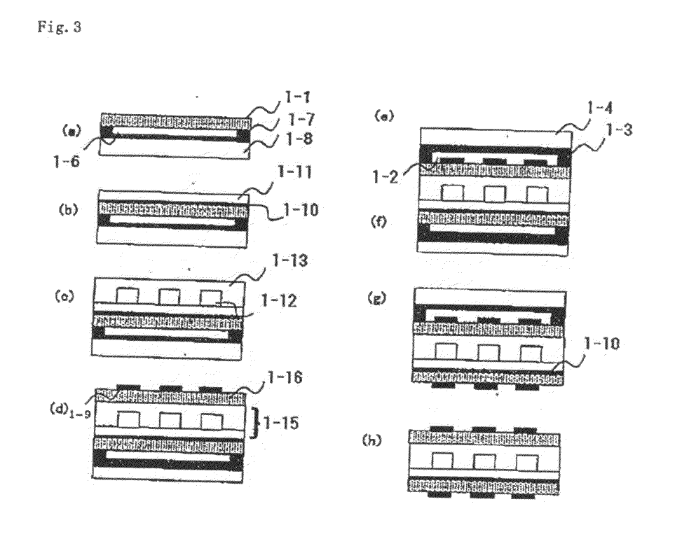

Thereafter, on the surface of the first substrate 1-1 opposite to the first support 1-4, a circuit is formed (see FIG. 1(f)), a layer having a circuit formed therein is laminated thereon to form a multilayer structure as shown in FIG. 2(f)-1, an optical waveguide 1-15 containing a lower clad layer 1-11, a core pattern 1-12 and an upper clad layer 1-13 laminated in this order is laminated thereon through an adhesive layer 1-10 as shown in FIG. 2(f)-2, a substrate is further laminated on the surface of the upper clad layer 1-13 in FIG. 2(f)-2 as shown in FIG. 2(f)-3, or after laminating a layer having a circuit formed therein thereon to form a multilayer structure as in FIG. 2(f)-1, an optical waveguide 1-15 is formed thereon as in FIG. 2 (f)-2 as shown in FIG. 2(f)-4. As shown in FIG. 3, furthermore, an optical waveguide 1-15 is disposed as an internal layer in the first substrate 1-1, and circuits are provided above and below the substrate. In this case, a circuit is formed on the surface of the substrate X opposite to the surface of the substrate X having the optical waveguide formed, and the circuit 1-9 is embedded in the first releasing layer 1-2 (see FIG. 3(e)).

The term “circuit” referred in the present invention includes an electric circuit and an optical circuit (an optical waveguide).

The method for laminating the first substrate 1-1 and the first support 1-4 will be described.

### Method for Laminating First Substrate and First Support

As a preceding step before laminating the first substrate 1-1 to the first support 1-4, a first releasing layer 1-2 that is smaller than the first support 1-4 and the first substrate 1-1 by from 5 to 30 mm for each edge is inserted, and they are adhered to each other through a first adhesive layer 1-3 having the same size as the first support 1-4 between the first releasing layer 1-2 and the first support 1-4, whereby the circuit 1-9 can be embedded in the first releasing layer 1-2, and simultaneously the first substrate 1-1 can be fixed to the first support 1-4 (see FIG. 1(c)).

The laminating method is not particularly designated, and preferred examples thereof include manual lamination, a laminator, a vacuum laminator, pressing and vacuum pressing. Entrainment of air between the first support 1-4 and the first substrate 1-1 promotes blistering in a heating step, and thus a vacuum laminator and vacuum pressing are more preferred for the method where no air is entrained.

For enhancing the embedding property of the circuit 1-9 and for flattening the surface of the first substrate 1-1 opposite to the first support 1-1, it is more preferred that the first substrate 1-1 is held with a hard plate on the opposite side to the first support 1-4 upon laminating the first substrate 1-1 and the first support 1-4, or a second support 1-8 is laminated on the first substrate 1-1 before laminating the first substrate 1-1 and the first support 1-4. The hard plate may be any material that is less deformed on pressure than the first releasing layer 1-2.

The method for laminating the first substrate 1-1 and the second support 1-8 will be described.

### Method for Laminating First Substrate and Second Support

For laminating the first substrate 1-1 to the second support 1-8 in a step D, they may be adhered through a second adhesive layer 1-7 having removability, and upon separating, the second support 1-8 and the second adhesive layer 1-7 may be released off from the first substrate 1-1. In the case where the second support 1-8 is not laminated, a second releasing layer 1-6 and the second adhesive layer 1-7 may not be used.

In the case where a second adhesive layer 1-7 having no removability is used, as a preceding step before laminating the first substrate 1-1 to the second support 1-8, because the first support 1-4 and the second support 1-8 are separated sequentially, a second releasing layer 1-6 that is smaller than the first releasing layer 1-2 by from 1 to 30 mm for each edge is inserted, and they are adhered through the second adhesive layer 1-7 having the same size as the second support 1-8 between the second releasing layer 1-6 and the second support 1-8, whereby the first substrate 1-1 or a second substrate 1-5 can be fixed to the second support 1-8. Upon separating only the first support 1-4 after laminating the second support 1-8, the product may be cut into a size that is smaller than the first releasing layer 1-2 but is larger than the second releasing layer 1-6.

The laminating method is not particularly designated and may be the same method for laminating the first support and the first substrate.

From the standpoint that the circuit 1-9 is formed on the side of the first substrate 1-1 opposite to the second support 1-8, the surface of the first substrate 1-1 on the side of the second support 1-8 is preferably a flat surface, and the second releasing layer 1-6 in this case preferably undergoes less deformation on pressure than the first releasing layer 1-2.

The constitutional components that are necessary for laminating the first substrate 1-1 and the second substrate 1-5 to the first support 1-4 and the second support 1-8 will be described.

### First Support and Second Support

The kinds of the first support 1-4 and the second support 1-8 are not particularly limited, and examples thereof include an FR-4 substrate, a semiconductor substrate, a silicon substrate, a glass substrate and a metal plate, with one formed of a non-flexible hard material being preferred.

The use of a thick support having dimensional stability as the first support 1-4 and the second support 1-8 may impart dimensional stability to the first substrate 1-1 and the second substrate 1-5 themselves and may enhance the embedding property of the circuit 1-9. The material of the thick support having dimensional stability is not particularly limited, and preferred examples thereof include an FR-4 substrate, a semiconductor substrate, a silicon substrate, a glass plate and a metal plate, from the standpoint of dimensional stability.

The thickness of the support may be appropriately changed depending on warpage, dimensional stability and productivity of the support, and is preferably from 0.1 to 10.0 mm.

The hard plate is preferably made of the same material as above and preferably has the support thickness above.

### Substrate

The substrate used in the present invention (the first invention) (i.e., the first substrate 1-1, the second substrate 1-5 and the substrate X 16) is not particularly limited and preferably has a flat surface of the first substrate 1-1 on the side of the second support 1-8. Therefore, preferred examples of the surface include a metal layer flat surface before forming a circuit by the subtractive method, a resin flat surface before forming a circuit by the semi-additive method, and a resin or metal flat surface that is suitable for forming the optical waveguide 1-15. The presence of the metal layers disposed above and below the substrate shown in FIGS. 1 to 3 may be determined depending on the method for forming a circuit.

The kind of the substrate is not particularly limited, and examples thereof include an FR-4 substrate, a build-up substrate, a polyimide substrate, a semiconductor substrate, a silicon substrate and a glass substrate. The substrate may be formed of a flexible material or a non-flexible hard material, and in the case where a fine wiring is to be formed, an insulating resin layer for a fine wiring is preferred.

The material of the insulating resin layer may be a thermosetting resin and a thermoplastic resin. Examples of the thermosetting resin include a phenol resin, a urea resin, a melamine resin, an alkyd resin, an acrylic resin, an unsaturated polyester resin, a diallyl phthalate resin, an epoxy resin, a silicone resin, a resin synthesized from cyclopentadiene, a resin containing tris(2-hydroxyethyl) isocyanurate, a resin synthesized from an aromatic nitrile, an aromatic dicyanamide trimer resin, a resin containing triallyl trimethacrylate, a furan resin, a ketone resin, a xylene resin and a thermosetting resin containing a condensed polycyclic aromatic compound.

Examples of the thermoplastic resin include a polyimide resin, a polyphenylene oxide resin, a polyphenylene sulfide resin and an aramid resin.

The use of a film as the substrate may impart flexibility and toughness to the first substrate 1-1, the second substrate 1-5, the substrate X 1-16 and the optical waveguide 1-15. The material of the film is not particularly limited, and preferred examples thereof include films of a polyester, such as polyethylene terephthalate, polybutylene terephthalate and polyethylene naphthalate, polyethylene, polypropylene, polyamide, polycarbonate, polyphenylene ether, polyether sulfide, polyarylate, a liquid crystal polymer, polysulfone, polyether sulfone, polyether ether ketone, polyether imide, polyamideimide and polyimide, from the standpoint of flexibility and toughness.

The thickness of the film may be changed depending on the target flexibility and is preferably from 5 to 250 μm. When the thickness is 5 μm or more, the toughness can be advantageously obtained, and when the thickness is 250 μm or less, sufficient flexibility can be obtained.

### Releasing Layer

The kind of the releasing layer is not particularly limited, and examples thereof include a releasing sheet for pressing, a resin or an adhesive having releasing property, and a resin having UV or heat releasing property.

The surface of the first substrate 1-1 on the side of the second support 1-8 is preferably a flat surface as described above, and the surface can be flattened by using a material in a film form as the second releasing layer 1-6. The material of the film is not particularly limited, and preferred examples thereof include a copper foil, a silver foil, a gold foil, a polyester, such as polyethylene terephthalate, polybutylene terephthalate and polyethylene naphthalate, polyethylene, polypropylene, polyamide, polycarbonate, polyphenylene ether, polyether sulfide, polyarylate, a liquid crystal polymer, polysulfone, polyether sulfone, polyether ether ketone, polyether imide, polyamideimide and polyimide, from the standpoint of flatness. More preferred examples thereof include a copper foil, a polyimide film and an aramid film, from the standpoint of heat resistance and releasing property from the substrate.

The thickness of the film may be changed depending on the target flatness and is preferably from 5 to 250 m. When the thickness is 5 μm or more, the toughness can be advantageously obtained, and when the thickness is 250 μm or less, sufficient embedding property by the second adhesive layer 1-7 can be obtained.

It is necessary to embed the circuit 1-9 of the first substrate 1-1 in the first releasing layer 1-2, and thus a material that has favorably circuit embedding property is preferably used. Preferred examples of the material of the first releasing layer 1-2 include the same material as in the second releasing layer 1-6, and a releasing sheet for pressing is more preferred from the standpoint of circuit embedding property.

The thickness of the releasing layer may be changed depending on the target thickness of the circuit and is preferably larger than the thickness of the circuit by 5 μm or more.

### Adhesive Layer

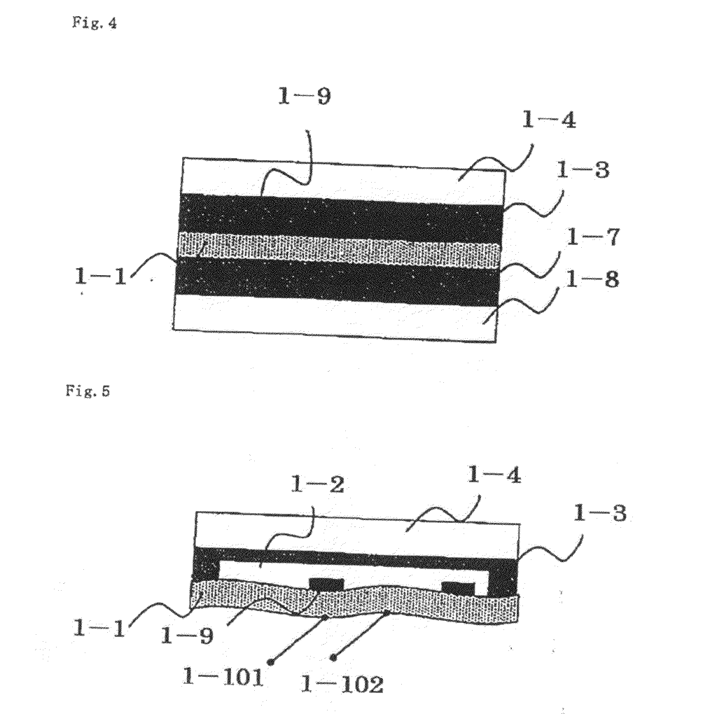

For adhering the first substrate 1-1 and the second substrate 1-5 to the first support 1-4 and the second support 1-8, adhesive layers 1-3 and 1-7 having removability are preferably used as a releasing adhesive layer while not limiting. The layer structure in this case is shown in FIG. 4. Preferred examples of the material of the adhesive layer having removability include a double-face adhesive tape with one surface having slight tackiness, a hot-melt adhesive and a UV-curable adhesive. It is necessary to embed the circuit 1-9 of the first substrate 1-1 in the first releasing layer 1-2, and thus a material having a thickness that is capable of embedding the circuit is preferably used.

For adhering through a releasing layer that is not necessarily removable, and for adhering the first substrate 1-1, the second substrate 1-5 and the optical waveguide 1-15 (an adhesive layer 1-10), an adhesive layer having heat resistance is preferred. The material of the adhesive layer that is not necessarily removable is not particularly limited, and preferred examples thereof include a prepreg, a build-up material, a heat resistant adhesive and the insulating resins having been listed for the substrate, from the standpoint of heat resistance. In the optical waveguide 1-15, an adhesive layer having high transmittance is necessary for adhering the part, through which an optical signal passes, and the material of the adhesive layer 1-10 is preferably the adhesive disclosed in PCT/JP2008/05465 while not limiting. In the case where the first substrate 1-1 and the second substrate 1-5 are adhered to the first support 1-4 and the second support 1-8 through the releasing layer, the thickness of the adhesive layer is preferably larger than the releasing layer by 5 μm or more.

The methods for forming the layers constituting the circuit board of the present invention will be described.

### Method for Forming Circuit

Examples of the method for forming a circuit include a method, in which a metal layer is formed on a surface where a circuit is to be formed, an etching resist is further formed thereon, and an unnecessary part of the metal layer is removed by etching (the subtractive method), a method, in which a plating resist is formed, and a circuit is formed only on a necessary portion on the surface where a circuit is to be formed by plating (the additive method), and a method, in which a thin metal layer (a seed layer) is formed on the surface where a circuit is to be formed, a plating resist is further formed thereon, then a necessary circuit is formed by electroplating, and then the thin metal layer is removed by etching (the semi-additive method).

The method for forming a circuit may be any one of these methods, and for forming a fine wiring having a circuit width of 20 μm or less, the semi-additive method is preferred.

The etching resist or the plating resist used for forming a circuit may be a positive type or a negative type, and a positive resist is more preferred since a fine wiring can be easily formed.

### Formation of Seed Layer in Semi-Additive Method

Upon forming a circuit by the semi-additive method, the method for forming the seed layer on the surface where a circuit is to be formed includes a method by vapor deposition or plating and a method of adhering a metal layer.

### Formation of Seed Layer by Vapor Deposition or Plating

The seed layer may be formed on the surface where a circuit is to be formed, by vapor deposition or plating as described above.

For example, in the case where an underlayer metal and a thin copper layer are formed as the seed layer by sputtering, examples of the sputtering apparatus used for forming the thin copper layer include a diode sputter, a triode sputter, a tetraode sputter, a magnetron sputter and a mirrortron sputter.

The target used for forming the underlayer by sputtering may be, for example, a metal, such as Cr, Ni, Co, Pd, Zr, Ni/Cr and Ni/Cu, for ensuring adhesion, and the target is sputtered to from 5 to 50 nm.

Thereafter, copper as a target is sputtered to from 200 to 500 nm, thereby forming the seed layer.

The seed layer may also be formed by plating copper on the surface where a circuit is to be formed, by electroless copper plating to from 0.5 to 3 μm.

### Method of Adhering Metal Layer

In the case where the surface where a circuit is to be formed has an adhesive function, the seed layer may be formed by adhering a metal layer by pressing or laminating, as described above.

However, it is very difficult to adhere directly a thin metal layer, such methods may be employed as a method of thinning a thick metal layer having been adhered by the etching or the like, and a method of adhering a metal layer with a carrier layer, and then removing only the carrier layer.

Examples of the former include a three-layer foil of carrier copper/nickel/copper thin foil, in which the carrier copper is removed with an alkaline etching solution, and the nickel is removed with a nickel etching solution. Examples of the latter include a releasable copper foil having aluminum, copper, an insulating resin or the like as the carrier, and a seed layer having a thickness of 5 μm or less can be formed thereby.

The seed layer may also be formed in such a manner that a copper foil having a thickness of from 9 to 18 μm is adhered and then thinned by etching to 5 μm or less.

The kind of the electroplating used in the semi-additive method may be one that is ordinarily employed and is not particularly limited, and copper is preferably used as the plating metal for forming the circuit.

### Formation of Circuit by Additive Method

The formation of a circuit by the additive method may be performed by plating only on a portion where a circuit is to be formed, as similar to the semi-additive method, and the plating used in the additive method is generally electroless plating.

For example, after adhering a catalyst for electroless plating to the surface where a circuit is to be formed, a plating resist is formed on a portion of the surface where plating is not to be formed. The substrate is then immersed in an electroless plating solution, and electroless plating is performed only on the portion that is not covered with the plating resist, thereby forming a circuit.

### Formation of Multilayer Structure of Substrate Having Circuit

Upon forming a multilayer structure of the substrate having a circuit, a substrate of an insulating layer may be formed on the surface where a circuit is to be formed, and then a circuit may be formed on the surface of the substrate of the insulating layer by one of the subtractive method, the semi-additive method and the additive method. Preferred examples of the substrate of the insulating layer include a build-up substrate, a prepreg and a polyimide substrate.

The method for forming the substrate of the insulating layer is not particularly limited, and in the case where a build-up substrate is used, the substrate of the insulating layer is formed with a roll laminator or a vacuum laminator, and then a circuit may be formed by the semi-additive method or the additive method. In the case where a prepreg is used, a prepreg and a metal layer are sequentially formed on the surface where a circuit is to be formed, and after press laminating, the metal layer may be removed by the subtractive method or the semi-additive method, thereby forming a circuit. In the case where a polyimide substrate is used, when a polyimide substrate having a metal layer may be used, a circuit may be formed by the subtractive method or the semi-additive method after press laminating, roll laminating or vacuum laminating through an adhesive layer on the surface where a circuit to be formed. When a polyimide substrate having no metal layer is used, a circuit may be formed by the semi-additive method or the additive method after laminating the polyimide substrate by the method similar to the above.

### Interlayer Connection of Circuit

The circuits in the layers may be connected appropriately. A method of interlayer connection of the circuits will be described in detail below.

### Via Hole

The circuit board of the present invention may have plural layers each having a circuit, and thus a via hole for electrically connecting the circuits of the layers may be provided.

The via hole may be formed by forming a connecting hole in the substrate between the circuit layers, and filling the hole with a conductive paste, plating or the like.

Examples of the method for forming the hole include a mechanical process, such as punching and drilling, a laser process, a chemical etching process, and a dry etching method using plasma.

### Desmear

Removal of smear of the via hole formed by the aforementioned method may be performed by a dry process or a wet process.

Examples of the dry process include a plasma process, a reverse sputtering process and an ion gun process.

Examples of the plasma process include an atmospheric pressure plasma process, a vacuum plasma process and an RIE process, which may be selected depending on necessity.

Preferred examples of the gas used in these processes include nitrogen, oxygen, argon, Freon (CF₄) and a mixed gas thereof.

In the wet process, an oxidant, such as a chromate salt and a permanganate salt, may be used.

### Interlayer Connection

Examples of the method of interlayer connection include, in addition to the method using a via hole, a method of forming a conductive layer with a conductive paste, plating or the like on the insulating layer, and laminating on the surface of the insulating layer having the circuit formed thereon, by pressing or laminating.

### Formation of Insulation Coating

An insulation coating may be formed on the circuit surface positioned as the outermost layer of the circuit board of the present invention, and may be formed before or after laminating the first support 1-1 and the second support 1-5.

The pattern of the insulation coating may be formed by printing with a material in the form of varnish, and for ensuring higher accuracy, a photosensitive solder resist, a coverlay film or a resist in the form of a film is preferably used.

Examples of the material used include an epoxy material, a polyimide material, an epoxy acrylate material and a fluorene material.

### Method for Producing Optoelectronic Composite Substrate

A method for producing the circuit board of the present invention using an optical waveguide as the second substrate 1-5 will be described in detail below (see FIG. 3).

As shown in FIGS. 3(a) to 3(c), a lower clad layer 1-11 is provided on a first substrate 1-1 fixed on a second support 1-8, a core pattern 1-12 is formed thereon, and an upper clad layer 1-13 is further laminated thereon. In the case where the first substrate 1-i and the lower clad layer 1-11 have no adhesion force, they may be adhered through an adhesive layer 1-10. An optical waveguide having the lower clad layer 1-11, the core pattern 1-12 and the upper clad layer 1-13 may be adhered directly on the circuit with an adhesive.

The lower clad layer 1-11 may be formed on the support in a known method without any particular limitation.

For example, a material for forming the lower clad layer 1-11 is coated on a lower supporting film by spin coating or the like, and after prebaking, the thin film is cured through irradiation of an ultraviolet ray, thereby forming the lower clad layer 1-11. The core pattern 1-12 may also be formed in any method without particular limitation. For example, a core layer having a refractive index higher than the lower clad layer 1-11 is formed on the lower clad layer 1-11, and the core pattern may be formed by etching. The upper clad layer 1-13 may also be formed in any method without particular limitation. For example, it may be formed in the similar method as the lower clad layer 1-11.

Between the lower clad layer 1-11 and the substrate, an adhesive may be coated, or an adhesive sheet may be laminated, from the standpoint of adhesion between the lower clad layer 1-11 and the substrate.

### Lower Clad Layer and Upper Clad Layer

The lower clad layer 1-11 and the upper clad layer 1-13 used in the present invention will be described. Examples of the lower clad layer 1-11 and the upper clad layer 1-13 used include a resin for forming a clad layer or a resin film for forming a clad layer.

The resin for forming a clad layer used in the present invention may be a resin composition that has a lower refractive index than the core layer and is cured by light or heat, without particular limitation, and preferred examples thereof include a thermosetting resin composition and a photosensitive resin composition. More preferably, the resin for forming a clad layer is constituted by a resin composition containing (A) a base polymer, (B) a photopolymerizable compound and (C) a photopolymerization initiator. The resin compositions used as the resin for forming a clad layer may have the same components or different components contained in the resin composition for each of the upper clad layer 1-13 and the lower clad layer 1-11, and the refractive indices of the resin compositions may be the same as or different from each other for each of them.

The base polymer (A) used herein is for forming the clad layer and ensures the strength of the clad layer, and is not particularly limited as far as it achieves the objects. Examples thereof include a phenoxy resin, an epoxy resin, a (meth)acrylic resin, a polycarbonate resin, a polyarylate resin, polyether amide, polyether imide, polyether sulfone, and derivatives thereof. The base polymer may be used solely or as a mixture of two or more thereof. Among the base polymers exemplified above, one having an aromatic skeleton in the main chain is preferred from the standpoint of high heat resistance, and a phenoxy resin is particularly preferred. An epoxy resin, particularly an epoxy resin in a solid state at room temperature, is preferred from the standpoint of enhancement in heat resistance through three-dimensional crosslinking. Furthermore, the compatibility with the photopolymerizable compound (B) described in detail later is important for ensuring transparency of the resin for forming a clad layer, and from this standpoint, a phenoxy resin and a (meth)acrylic resin are preferred. The (meth)acrylic resin referred herein means an acrylic resin and a methacrylic resin.

Preferred examples of the phenoxy resin include ones containing bisphenol A, a bisphenol A type epoxy compound or a derivative thereof, or bisphenol F, a bisphenol F type epoxy compound or a derivative thereof, as a constitutional unit of the copolymer components, since they are excellent in heat resistance, adhesion and solubility. Preferred examples of the derivative of bisphenol A or a bisphenol A type epoxy compound include tetrabromobisphenol A and a tetrabromobisphenol A type epoxy compound. Preferred examples of the derivative of bisphenol F or a bisphenol F type epoxy compound include tetrabromobisphenol F and a tetrabromobisphenol F type epoxy compound. Specific examples of the bisphenol A/bisphenol F copolymer type phenoxy resin include “Phenotohto YP-70”, a trade name, produced by Tohto Kasei Co., Ltd.

Examples of the epoxy resin in a solid state at room temperature include bisphenol A type epoxy resins, such as “Epotohto YD-7020”, “Epotohto YD-7019” and “Epotohto YD-7017”, trade names, produced by Tohto Kasei Co., Ltd., and “Epikote 1010”, “Epikote 1009” and “Epikote 1008”, trade names, produced by Japan Epoxy Resin Co., Ltd.

The photopolymerizable compound (B) is not particularly limited as far as it is polymerized through irradiation of light, such as an ultraviolet ray, and examples thereof include a compound having an ethylenic unsaturated group in the molecule and a compound having two or more epoxy groups in the molecule.

Examples of the compound having an ethylenic unsaturated group in the molecule include a (meth)acrylate, a halogenated vinylidene, vinyl ether, vinylpyridine and vinylphenol, and among these a (meth)acrylate is preferred from the standpoint of transparency and heat resistance.

Examples of the (meth)acrylate include a monofunctional compound, a bifunctional compound and a trifunctional or higher functional compound, any of which may be used. The (meth)acrylate herein means an acrylate and a methacrylate.

Examples of the compound having two or more epoxy groups in the molecule include a bifunctional or polyfunctional aromatic glycidyl ether, such as a bisphenol A type epoxy resin, a bifunctional or polyfunctional aliphatic glycidyl ether, such as polyethylene glycol type epoxy resin, a bifunctional alicyclic glycidyl ether, such as a hydrogenated bisphenol A type epoxy resin, a bifunctional aromatic glycidyl ester, such as diglycidyl phthalate, a bifunctional alicyclic glycidyl ester, such as diglycidyl tetrahydrophthalate, a bifunctional or polyfunctional aromatic glycidylamine, such as N,N-diglycidylaniline, a bifunctional alicyclic epoxy resin, such as an alicyclic diepoxy carboxylate, a bifunctional heterocyclic epoxy resin, a polyfunctional heterocyclic epoxy resin, and a bifunctional or polyfunctional silicon-containing epoxy resin. The photopolymerizable compound (B) may be used solely or in combination of two or more kinds thereof.

The photopolymerization initiator as the component (C) is not particularly limited, and examples of the initiator upon using an epoxy compound as the component (B) include an aryldiazonium salt, a diaryliodonium salt, a triarylsulfonium salt, a triarylselenonium salt, a dialkylphenazylsulfonium salt, a dialkyl-4-hydroxyphenylsulfonium salt and a sulfonate ester.

Examples of the initiator upon using a compound having an ethylenic unsaturated group in the molecule as the component (B) include an aromatic ketone, such as benzophenone, a quinone compound, such as 2-ethylanthraquinone, a benzoin ether compound, such as benzoin methyl ether, a benzoin compound, such as benzoin, a benzyl derivative, such as benzyl dimethyl ketal, a 2,4,5-triarylimidazole dimer, such as 2-(o-chlorophenyl)-4,5-diphenylimidazole dimer, a benzoimidazole compound, such as 2-mercaptobenzoimidazole, a phosphine oxide compound, such as bis(2,4,6-trimethylbenzoyl)phenylphosphine oxide, an acridine derivative, such as 9-phenylacridine, N-phenylglycine, an N-phenylglycine derivative and a coumarin compound. A combination of a thioxanthone compound and a tertiary amine compound, such as a combination of diethylthioxanthone and dimethylaminobenzoic acid, may also be used. Among these compounds, an aromatic ketone and a phosphine oxide compound are preferred from the standpoint of enhancement of transparency of the core layer and the clad layer.

the photopolymerization initiator (C) may be used solely or in combination of two or more kinds thereof.

The amount of the base polymer (A) mixed is preferably from 5 to 80% by mass based on the total amount of the component (A) and the component (B). The amount of the photopolymerizable compound (B) is preferably from 95 to 20% by mass based on the total amount of the component (A) and the component (B).

As for the amounts of the component (A) and the component (B) mixed, when the component (A) is 5% by mass or more and the component (B) is 95% by mass or less, the resin composition can be easily formed into a film. When the component (A) is 80% by mass or less and the component (B) is 20% by mass or more, the composition can be easily cured with the base polymer (A) entrained, and upon forming an optical waveguide, the pattern forming property is enhanced, and the photocuring reaction proceeds sufficiently. From these standpoint, the amounts of the component (A) and the component (B) mixed are preferably from 10 to 85% by mass for the component (A) and from 90 to 15% by mass for the component (B), and more preferably from 20 to 70% by mass for the component (A) and from 80 to 30% by mass for the component (B).

The amount of the photopolymerization initiator (C) mixed is preferably from 0.1 to 10 parts by mass per 100 parts by mass as the total amount of the component (A) and the component (B). When the amount mixed is 0.1 part by mass or more, sufficient photosensitivity is obtained, and when it is 10 parts by mass or less, absorption on the surface layer of the photosensitive resin composition is not increased upon exposure, and the interior thereof is sufficiently photocured. Furthermore, an amount in the range is preferred since increase of the transmission loss due to light absorption of the polymerization initiator itself may not occur upon using as an optical waveguide. From these standpoints, the amount of the photopolymerization initiator (C) mixed is more preferably from 0.2 to 5 parts by mass.

The resin for forming a clad layer may contain, depending on necessity, so-called additives, such as an antioxidant, a yellowing preventing agent, an ultraviolet ray absorbent, a visible ray absorbent, a colorant, a plasticizer, a stabilizer and a filler, in such proportions that do not impair the advantages of the present invention.

In the present invention, the method for forming the clad layer is not particularly limited, and the clad layer may be formed by coating the resin for forming a clad layer or laminating the resin film for forming a clad layer.

In the case of coating, the method therefor is not particularly limited, and for example, a resin composition containing the components (A) to (C) may be coated in an ordinary method.

The resin film for forming a clad layer used for laminating may be produced easily, for example, in such a manner that the resin composition is dissolved in a solvent and coated on a supporting film, and then the solvent is removed.

The supporting film used in the production process of the resin film for forming a clad layer is not particularly limited in material therefor, and various materials may be used. From the standpoint of flexibility and toughness as the supporting film, examples thereof include those exemplified for the film material of the first support 1-1, the second support 1-5 and the substrate.

The thickness of the supporting film may be appropriately changed depending on the target flexibility, and is preferably from 5 to 250 μm. When the thickness is 5 μm or more, toughness can be advantageously obtained, and when it is 250 μm less, sufficient flexibility is obtained.

The solvent used herein is not particularly limited as far as it can dissolve the resin composition, and examples of the solvent used include acetone, methyl ethyl ketone, methyl cellosolve, ethyl cellosolve, toluene, N,N-dimethylacetamide, propylene glycol monomethyl ether, propylene glycol monomethyl ether acetate, cyclohexanone, N-methyl-2-pyrrolidone and mixed solvents thereof. The solid concentration in the resin solution is preferably approximately from 30 to 80% by mass.

The thicknesses of the lower clad layer 1-11 and the upper clad layer 1-13 (which are hereinafter abbreviated as clad layers 1-11 and 1-13) each are preferably in a range of from 5 to 500 μm in terms of thickness after drying. When the thickness is 5 μm or more, a clad thickness that is necessary for confining light can be ensured, and when it is 500 g m or less, the thickness can be easily controlled uniform. From these standpoints, the thicknesses of the clad layers 11 and 13 are each more preferably in a range of from 10 to 100 μm.

The thicknesses of the clad layers 1-11 and 1-13 may be the same as or different from each other between the lower clad layer 1-11 firstly formed and the upper clad layer 1-13 for embedding the core pattern 1-12, and the thickness of the upper clad layer 13 is preferably larger than the thickness of the core layer for embedding the core pattern 1-12.

### Resin for Forming Core Layer and Resin Film for Forming Core Layer

In the present invention, the method for forming a core layer, which is laminated on the lower clad layer 1-11 for forming the core pattern 1-12, is not particularly limited, and for example, the core layer may be formed by coating a resin for forming a core layer or laminating a resin film for forming a core layer.

The resin for forming a core layer used may be a resin composition that is designed in such a manner that the core pattern 1-12 exhibits a higher refractive index than the clad layers 1-11 and 1-13, and is capable of forming the core pattern 1-12 with active light, and is preferably a photosensitive resin composition. Specifically, a resin composition that is similar to that used for the resin for forming a clad layer may be preferably used.

In the case of coating, the method therefor is not particularly limited, and the resin composition may be coated in an ordinary method.

The resin film for forming a core layer used for laminating will be described in detail.

The resin film for forming a core layer may be produced easily in such a manner that the resin composition is dissolved in a solvent and coated on the lower clad layer 2, and then the solvent is removed. The solvent used herein is not particularly limited as far as it can dissolve the resin composition, and examples thereof include acetone, methyl ethyl ketone, methyl cellosolve, ethyl cellosolve, toluene, N,N-dimethylformamide, N,N-dimethylacetamide, propylene glycol monomethyl ether, propylene glycol monomethyl ether acetate, cyclohexanone, N-methyl-2-pyrrolidone and mixed solvents thereof. The solid concentration in the resin solution is preferably from 30 to 80% by mass.

The thicknesses of the resin film for forming a core layer are not particularly limited, and the thickness of the core layer after drying is generally controlled to from 10 to 100 μm. When the thickness of the film is 10 μm or more, the positioning tolerance upon coupling a light receiving/emitting device or an optical fiber after forming an optical waveguide can be advantageously enhanced, and when it is 100 μm or less, the coupling efficiency with a light receiving/emitting device or an optical fiber after forming an optical waveguide can be advantageously improved. From these standpoints, the thickness of the film is more preferably in a range of from 30 to 70 μm.

The supporting film used in the production process of the resin film for forming a core layer is a supporting film that supports the resin for forming a core layer, and is not particularly limited in material therefor, and preferred examples thereof include a polyester, such as polyethylene terephthalate, polypropylene and polyethylene, from the standpoint that the materials facilitate release of the resin for forming a core layer and have heat resistance and solvent resistance.

the thickness of the supporting film is preferably from 5 to 50 μm. When the thickness is 5 μm or more, the strength as the supporting film can be advantageously obtained, and when it is 50 μm or less, the gap to a mask upon forming a pattern is decreased, and a finer pattern can be advantageously produced. From these standpoints, the thickness of the supporting film is more preferably in a range of from 10 to 40 μm, and particularly preferably in a range of from 15 to 30 μm.

The optical waveguide used in the present invention may be a multilayer optical waveguide containing plural polymer layers, each of which contains a core pattern and a clad layer, laminated on each other.

The lamination for forming the multilayer structure or the formation of an insulating substrate for forming the insulation coating are associated with contraction upon curing, and thus the substrate may suffer large warpage when the lamination is performed only on one surface.

Accordingly, the same material may be formed depending on necessity on the surface of the support opposite to the surface where the insulation coating or the lamination is made.

Furthermore, the warpage varies depending on the thickness of the insulation coating or the insulating substrate, and the thickness of the insulation coating or the insulating substrate formed on the surface of the support is preferably controlled to prevent the warpage from occurring.

In this case, the thicknesses of the insulating coatings on both surfaces are preferably determined after performing preliminary investigation.

### Electric Circuit or Electric Circuit Board

In the present invention, an electric circuit or an electric circuit board capable of being formed on the optical waveguide is not particularly limited, and various kinds of electric circuit boards may be used. Examples thereof include an insulating resin layer or substrate having a wiring formed directly thereon, a substrate having a metal layer on one surface or both surfaces thereof, and a resin layer having a metal layer on one surface or both surfaces thereof, and a metal layer is laminated on one surface or both surfaces of an insulating resin layer or substrate, thereby forming an electric circuit board.

Examples of the material of the substrate or the resin layer include those exemplified for the aforementioned substrate.

Examples of the metal forming the metal layer include copper, gold, silver, Al, Ni, Cr, Co, Ti, Pd, Sn, Zn, Na, alloys thereof, and one having two or more layers of these metals.

The circuit board may be formed to have a multilayer structure.

### (II) Second Invention

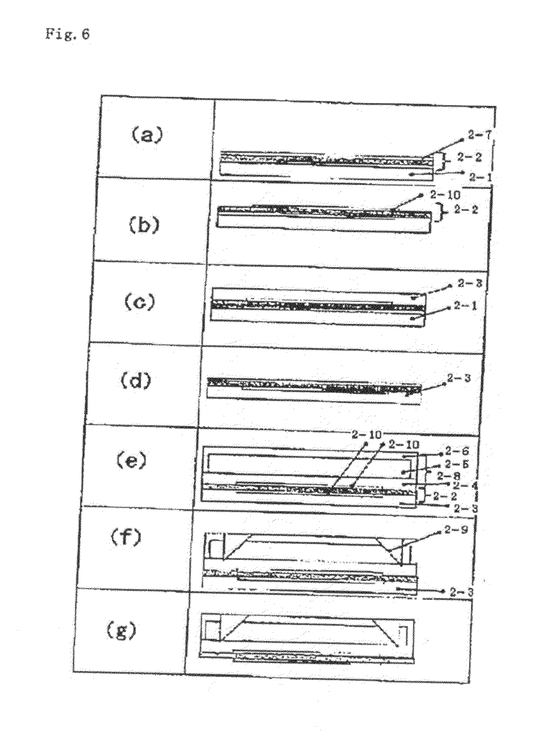

An optoelectronic composite substrate produced by the present invention (the second invention) contains, for example, as shown in FIG. 6(e), an electric circuit board 2-2 having laminated thereon an optical waveguide 2-8 containing a lower clad layer 2-4, a core pattern 2-5 and an upper clad layer 2-6 laminated in this order. In the present invention, the term “electric circuit board” means one having no electric circuit layer formed, but the term “electric circuit board” referred after forming the circuit layer means an electric circuit board having an electric circuit layer formed therein.

### Method for Producing Optoelectronic Composite Member

The method for producing an optoelectronic composite member of the present invention (second invention) will be described in detail (see FIG. 6). The method for forming an optoelectronic composite member of the present invention (the second invention) contains, in this order, a step of laminating an electric circuit board on a second support, a step of laminating a first support, a step of releasing the second support, and a step of forming an optical waveguide on the surface after releasing the second support. An example where a lower support 2-1 is used as the second support and an upper support 2-3 is used as the first support will be described.

As shown in FIGS. 6(a) and 6(b), an electric circuit board 2-2 is provided on a lower support 2-1, and an electric circuit 2-10 is formed thereon. Subsequently, an upper support 2-3 is laminated on the surface where the electric circuit 2-10 is formed (see FIG. 6(c)), and the lower support 2-1 is released (see FIG. 6(d)). Subsequently, an electric circuit 2-10 is again formed on the surface after releasing the lower support 2-1, and as shown in FIG. 6(e), a lower clad layer 2-4 is provided on the electric circuit board 2-2, a core pattern 2-5 is formed thereon, and an upper clad layer 2-6 is further laminated.

The lower clad layer 2-4 may be formed on the electric circuit board 2-2 in a known method without any particular limitation. For example, a material for forming the lower clad layer 2-4 is coated on the electric circuit board 2-2 by spin coating or the like, and after prebaking, the thin film is cured through irradiation of an ultraviolet ray, thereby forming the lower clad layer 2-4. The core pattern 2-5 may also be formed in any method without particular limitation. For example, a core layer having a refractive index higher than the lower clad layer 2-4 is formed on the lower clad layer 2-4, and a core pattern 2-5 may be formed by etching. The upper clad layer 2-6 may also be formed in any method without particular limitation. For example, it may be formed in the similar method as the lower clad layer 2-4.

The lower clad layer 2-4 has a flat surface without any step on the surface where a core layer is to be laminated, from the standpoint of adhesion to the core layer. The surface flatness of the clad layer 2-4 can be ensured by using a resin film for forming a clad layer.

The method for laminating the lower support 2-1 and the upper support 2-3 on the electric circuit board 2-2 is not particularly limited. Examples of the lamination method include a method, in which the electric circuit board 2-2 is adhered to the lower support 2-1 and the upper support 2-3 with an adhesive having good removability or through an adhesive film 2-11, and a method, in which an outer frame part of the electric circuit board 2-2 (outside the necessary pattern area) is adhered with an adhesive, and after forming the circuit of the electric circuit board 2-2 or after forming the optical waveguide 2-8, the adhered part is cut off.

Subsequently, as shown in FIG. 6(e), the upper support 2-3 is released from the electric circuit board 2-2, thereby providing an optoelectronic composite member (see FIG. 6(g)). The resulting composite of the electric circuit board 2-2 and the optical waveguide 2-8 can be used as an ordinary optoelectronic composite member in various equipments.

The constitutional components of the optoelectronic composite member will be described.

### Support and Substrate

The kinds of the lower support 2-1, the upper support 2-3 and the substrate 2-7 are not particularly limited. Examples thereof include an FR-4 substrate, a polyimide substrate, a semiconductor substrate, a silicon substrate and a glass substrate, and a flexible material or a non-flexible rigid material may be used.

The use of a material having flexibility as the substrate 2-7 provides a flexible optoelectronic composite member. The material having flexibility is not particularly limited, and preferred examples thereof include a polyester, such as polyethylene terephthalate, polybutylene terephthalate and polyethylene naphthalate, polyethylene, polypropylene, polyamide, polycarbonate, polyphenylene ether, polyether sulfide, polylarylate, a liquid crystal polymer, polysulfone, polyether sulfone, polyether ether ketone, polyether imide, polyamideimide and polyimide, from the standpoint of flexibility and toughness thereof.

The thickness of the film may be appropriately changed depending on the target flexibility and is preferably from 5 to 250 μm. When the thickness is 5 μm or more, toughness can be advantageously obtained, and when it is 250 μm or less, sufficient flexibility can be obtained.

The use of a non-flexible thick material having dimensional stability as the lower support 2-1 and the upper support 2-3 can impart dimensional stability to the optical waveguide itself. The thick substrate having dimensional stability is not particularly limited, and preferred examples thereof include an FR-4 substrate, a semiconductor substrate, a silicon plate, a glass plate and a metal plate, from the standpoint of dimensional stability.

The thick substrate having dimensional stability may be subjected to a releasing treatment, or after adhering the film, the film surface may be subjected to the releasing treatment, thereby imparting removability with the electric circuit board 2-2. Preferred examples of the material of the film include polyimide and aramid, from the standpoint of heat resistance.

The thickness of the plate may be appropriately changed depending on the warpage and the dimensional stability of the plate and is preferably from 0.1 to 10.0 mm.

An adhesive may be used for adhering the lower support 2-1 and the upper support 2-3 to the electric circuit board 2-2. In the case where an adhesive having releasing property with the electric circuit board 2-2 is used, they may be adhered through the whole surfaces thereof, but in the case where an adhesive having no releasing property with the electric circuit board 2-2 is used, a sheet having high releasing property having a size that is smaller than the product by from 5 to 30 mm may be inserted between the electric circuit board 2 and the adhesive to laminate only an outer frame part of the optical waveguide (outside the necessary pattern area), and after forming the optical waveguide, the laminated part may be cut off, thereby facilitating separation thereof. The material of the releasing sheet is not particularly limited, and preferred examples thereof include a copper foil, polyimide, aramid and a releasing sheet for pressing, from the standpoint of releasing property with the electric circuit board 2-2 and heat resistance.

### Adhesive and Adhesive Film

For adhering the lower support 2-1 and the upper support 2-3 to the electric circuit board 2-3, an adhesive or adhesive film having removability is preferably used in the case where they are to be removed, while not limiting.

Preferred examples of the material of the adhesive or the adhesive film include a double-face adhesive tape with one surface having slight tackiness, a hot-melt adhesive and a UV or heat removable adhesive.

In the case where the lower support 2-1 or the upper support 2-3 has removability with the electric circuit board 2-2, the adhesive or the adhesive film may not be necessarily used.

An adhesive or adhesive film having heat resistance is preferably used in the case where the adhesion of the lower support 2-1 and the upper support 2-3 to the electric circuit board 2-2 or the adhesion between the optical waveguide 2-8 and the electric circuit board 2-2 is not necessarily removed, in the case of adhesion requiring no removal, such as formation of the supports (such as the case where a non-flexible material is adhered to a film for subjecting the electric circuit board 2-2 to a releasing treatment), and in the case where an adhesive is necessarily used since the lower clad layer 2-4 and the electric circuit board 2-2 have no adhesive force. The material of the adhesive and the adhesive film that are not necessarily removable is not particularly limited, and preferred examples thereof include a prepreg, a build-up material and a heat resistant adhesive from the standpoint of heat resistance, while not limiting. An adhesive or an adhesive film having high transmittance are necessary for adhering the part, through which an optical signal passes, and the material of the adhesive or the adhesive film 1-10 is preferably the adhesive film disclosed in PCT/JP2008/05465 while not limiting.

The thickness of the adhesive and the adhesive film is not particularly limited and is preferably from 5 μm to 3.0 mm. In the case where the lower support 2-1 and the upper support 2-3 are adhered to the electric circuit board 2-2 through the releasing sheet, the thickness is preferably thicker than the releasing sheet by 5 μm or more.

### Lower Clad Layer and Upper Clad Layer

The lower clad layer 2-4 and the upper clad layer 2-6 used in the present invention (the second invention) will be described. As the lower clad layer 2-4 and the upper clad layer 2-6, a resin for forming a clad layer or a resin film for forming a clad layer may be used.

The resin for forming a clad layer used in the present invention may be the same one as described for the first invention. The resin compositions used as the resin for forming a clad layer may have the same components or different components contained in the resin composition for each of the upper clad layer 2-6 and the lower clad layer 2-4, and the refractive indices of the resin compositions may be the same as or different from each other for each of them.

The method for forming the clad layer is not particularly limited, and the similar method as described for the first invention may be used.

The thicknesses of the lower clad layer 2-4 and the upper clad layer 2-6 may be the same as described for the first invention.

The resin for forming a core layer and the resin film for forming a core layer used in the present invention (the second invention) may also be the same as described for the first invention.

The optical waveguide 2-8 used in the present invention may be a multilayer optical waveguide containing plural polymer layers, each of which contains a core pattern 2-5 and a clad layer, laminated on each other.

### Electric Circuit Board

The electric circuit board 2-2 used in the present invention (the second invention) is not particularly limited, and various kinds of electric circuit boards used in an optoelectronic composite member may be used. Examples thereof include an insulating resin layer or substrate or the substrate 2-7 having a wiring formed directly thereon, a substrate having a metal layer on one surface or both surfaces thereof, and a resin layer having a metal layer on one surface or both surfaces thereof, and a metal layer is laminated on one surface or both surfaces of an insulating resin layer or substrate, thereby forming an electric circuit board.

Examples of the material of the substrate or the resin layer include those exemplified for the aforementioned substrate 2-7.

Examples of the metal forming the metal layer include copper, gold, silver, Al, Ni, Cr, Co, Ti, Pd, Sn, Zn, Na, alloys thereof, and one having two or more layers of these metals.

The electric circuit board 2-2 may be produced by forming an electric wiring pattern after laminating an optical waveguide. The circuit board may be formed to have a multilayer structure.

### (III) Third Invention and Fourth Invention

A method for producing an optoelectronic composite substrate according to the present invention (the third invention) contains a first step of forming a lower clad layer on a substrate surface of an electric circuit board directly or through an adhesive layer, or forming a lower clad layer on a substrate surface of a substrate having a metal foil directly or through an adhesive layer, and then converting the metal foil of the substrate having the metal foil to a conductor pattern to construct an electric circuit board, thereby providing an electric circuit board having the lower clad layer; and a second step of forming sequentially a core pattern and an upper clad layer on the lower clad layer to construct an optical waveguide. In other words, in the method, the electric circuit board having the lower clad layer is produced firstly, and then the constitutional elements of the optical waveguide other than the lower clad layer are accumulated on the lower clad layer, thereby producing the optical waveguide.

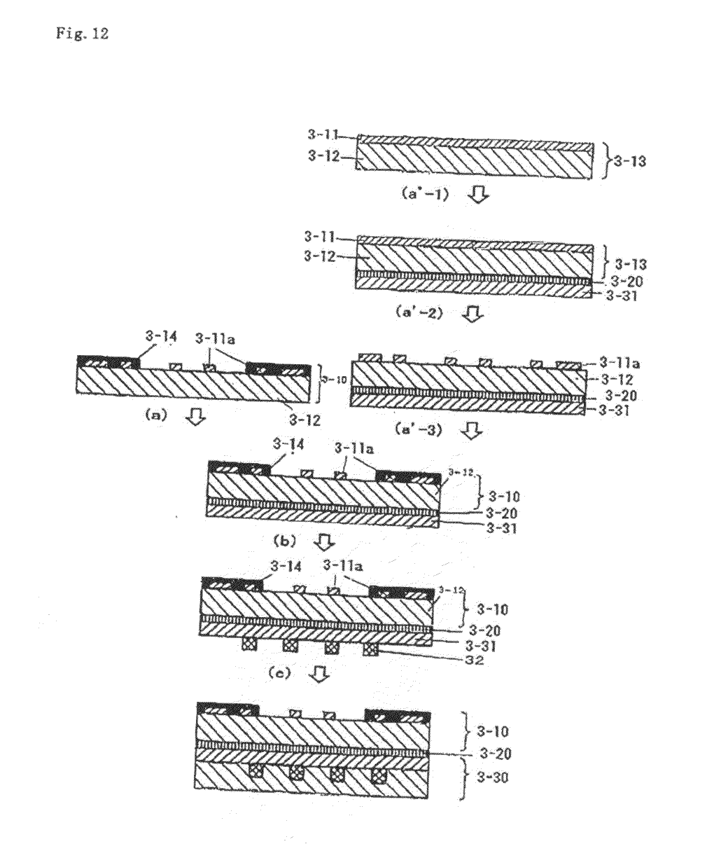

In the first step of the production method of the present invention (the third invention), (1) as shown in FIG. 12(a), a lower clad layer 3-31 is formed directly or through an adhesive layer 3-20 on a surface of a substrate 3-12 of an electric circuit board 3-10 having a conductor pattern 3-11a formed on the substrate 3-12 and having a conductor protective layer 3-14 formed depending on necessity thereon, or in alternative, (2) as shown in FIG. 12(a′-1), a lower clad layer 3-31 is formed directly or through an adhesive layer 3-20 on a surface of a substrate 3-12 of a substrate having a metal foil 3-13 containing a metal foil 3-11 and the substrate 3-12, then as shown in FIG. 12(a′-2), the metal foil 3-11 is processed to a conductor pattern 3-11a, and then as shown in FIG. 12(a′-3), a conductor protective layer 3-14 is formed depending on necessity, thereby providing an electric circuit board having a lower clad layer. The conductor protective layer herein is a layer that is formed for protecting the conductor pattern by insulating or protecting the conductor pattern from dusts, water, mechanical damages and the like, and may be a solder resist for a printed circuit board or a coverlay film.

In the case where the lower clad layer 3-31 is formed directly on the electric circuit board 3-10 or the surface of the substrate of the substrate having a metal foil 3-13, a varnish of a resin for forming a clad layer is coated by a known method, such as spin coating, and then the solvent is removed, thereby forming the lower clad layer.

In the case where the lower clad layer 3-31 is formed on the surface of the substrate through the adhesive layer 3-20, a resin film for forming a clad layer is used. The resin film for forming a clad layer can be easily produced in such a manner that a varnish of a resin for forming a clad layer is coated on a base film depending on necessity by a known method, such as spin coating, and then the solvent is removed. The method using the resin film for forming a clad layer is preferred since the accuracy in thickness of the lower clad layer can be ensured. The method for forming the adhesive layer 3-20 on the surface of the substrate 3-12 is not particularly limited, and an adhesive composition may be coated directly on the surface of the substrate 3-12, but a method of transferring an adhesive layer from an adhesive in a sheet form, which contains a support base and the adhesive layer, to the surface of the substrate 12 is preferred since the adhesive layer is excellent in flatness and is ensured in accuracy of the thickness of the adhesive layer, and such a problem or the like can be avoided that the resin composition for forming the adhesive layer runs off upon forming the adhesive layer. The method of processing the metal foil 3-11 to the conductor pattern 3-11a as shown in FIG. 12(a′-2) and the method of forming the conductor protective layer 3-14 as shown in FIG. 12(a′-3), which are described later, may be any known method.

The second step of the production method of the present invention (the third invention) is a step of constructing an optical waveguide. Specifically, as shown in FIG. 12(b), a core pattern 3-32 is formed on the lower clad layer 3-31, and then as shown in FIG. 12(c), an upper clad layer 3-33 is formed on the core pattern 3-32, thereby constructing an optical waveguide 3-30. The core pattern 3-32 can be formed by forming a layer (core layer) of a resin for forming a core on the lower clad layer 3-31, and exposing and developing the core layer. The method for producing the core layer is not particularly limited, and a varnish of a resin for forming a core may be coated directly on the lower clad layer 3-31 and then drying, but a method using a resin film for forming a core layer is preferred since the accuracy of the thickness of the core layer can be ensured. The core layer thus formed is then exposed and developed, thereby forming the desired core pattern 3-32. As for the method for forming the upper clad layer 3-33 on the core pattern 3-32, the upper clad layer 3-33 may be formed, as similar to the case of the lower clad layer 3-31, by coating a varnish of a resin for forming a clad layer by a known method, such as spin coating and removing the solvent, thereby forming the upper clad layer 3-33 directly on the core pattern 3-32, but a method using a resin film for forming a clad layer is preferred since the accuracy of the thickness of the core layer can be ensured.

A method for producing an optoelectronic composite substrate according to the present invention (the fourth invention) contains a first step of forming a lower clad layer on a substrate surface of a substrate having a metal foil directly or through an adhesive layer; a second step of forming sequentially a core pattern and an upper clad layer on the lower clad layer to construct an optical waveguide; and a third step of constructing an electric circuit board from the substrate having a metal foil. In other words, in the method, a lower clad layer is formed firstly on a substrate surface of a substrate having a metal foil, then the constitutional elements of the optical waveguide other than the lower clad layer are accumulated on the lower clad layer, thereby producing the optical waveguide, and furthermore, the electric circuit board is then constructed from the substrate having a metal foil.

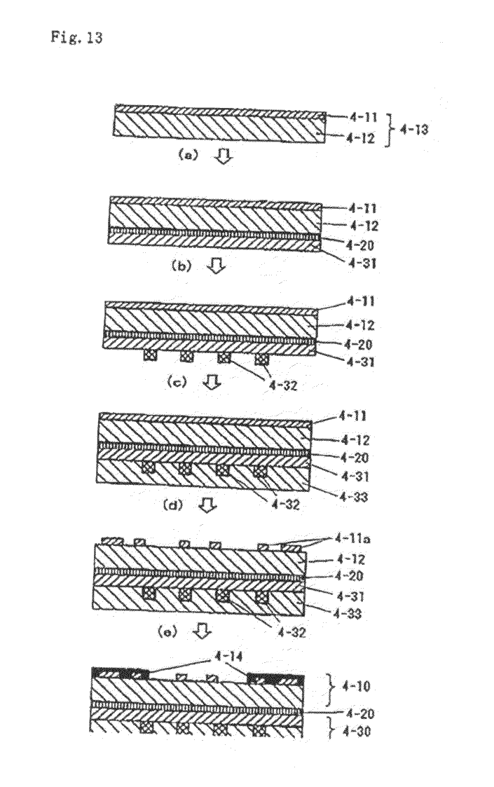

In the first step of the present invention, as shown in FIG. 13(a), a lower clad layer 4-31 is formed directly or through an adhesive layer 4-20 on a substrate 4-13 having a metal foil 4-11 and a substrate 4-12.

The second step of the production method of the present invention is a step of constructing an optical waveguide, in which as shown in FIG. 13(b), a core pattern 4-32 is formed on the lower clad layer 4-31, and then as shown in FIG. 13(c), an upper clad layer 4-33 is formed on the core pattern 4-32, thereby constructing an optical waveguide 4-30.

The third step of the production method of the present invention is a step of constructing an electric circuit board, in which as shown in FIG. 13(d), the metal foil 4-11 is converted to a conductor pattern 4-11a, thereby constructing an electric circuit board 4-10. As shown in FIG. 13(e), a conductor protective layer 4-14 is formed, depending on necessity, on a necessary portion of the conductor pattern 4-11a for protecting the conductor pattern 4-11a. The conductor protective layer herein is a layer that is formed for protecting the conductor pattern by insulating or protecting the conductor pattern from dusts, water, mechanical damages and the like, and may be a solder resist for a printed circuit board or a coverlay film.

The materials and the like used in the steps in the third invention and the fourth invention will be described in detail.

### Electric Circuit Board

The electric circuit board used in the third invention is not particularly limited as far as it is an electric circuit board, in which a conductor pattern is formed on a substrate, and a conductor protective layer is provided, depending on necessity, on the conductor pattern, and various kinds thereof may be used depending on purposes. Examples thereof include an organic circuit board containing a conductor metal, such as copper, aluminum or gold, and such a substrate as a glass-epoxy substrate, polyimide, polyamide, polyether imide, polyethylene terephthalate or a liquid crystal polymer, a ceramic circuit board, such as an alumina substrate and an aluminum nitride substrate, and a semiconductor wafer, such as silicon.

For producing a flexible type optoelectronic composite substrate, ones containing a substrate material of polyimide, polyamide, polyether imide, polyethylene terephthalate, a liquid crystal polymer or the like are used, and in general, one containing polyimide as a substrate material may be used from the standpoint of heat resistance and availability.

A transparent substrate is preferred for viewing conveniently a conductor pattern through the substrate upon constructing an optical waveguide.

### Substrate Having Metal Foil

The substrate having a metal foil used in the present invention may be various kinds depending on purposes. Examples of the metal include copper, aluminum and gold, and examples of the substrate include an organic circuit board using a glass-epoxy substrate, polyimide, polyamide, polyether imide, polyethylene terephthalate, a liquid crystal polymer or the like, a ceramic circuit board, such as an alumina substrate and an aluminum nitride substrate, and a semiconductor wafer, such as silicon.

For producing a flexible type optoelectronic composite substrate, ones containing a substrate material of polyimide, polyamide, polyether imide, polyethylene terephthalate, a liquid crystal polymer or the like are used, and in general, polyimide may be used from the standpoint of heat resistance and availability.

A transparent substrate is preferred for viewing conveniently a conductor pattern through the substrate upon constructing an optical waveguide. For processing the substrate having a metal foil to an electric circuit board, patterning is necessary for providing a wiring, and as a method therefor, a so-called subtractive method has been frequently employed, in which a three-layer substrate having a metal foil containing a metal foil having a thickness necessary for a metal wiring laminated on a substrate through an adhesive layer is used, and an unnecessary part as the conductor pattern is removed from the metal foil of the substrate having a metal foil by etching.

However, in the three-layer substrate having a metal foil, the presence of the adhesive layer influences the performance of the substrate, particularly reliability upon bending. Accordingly, a two-layer substrate having a metal foil containing a metal foil that is laminated directly on a substrate without an adhesive layer is being developed, and various attempts have been made for enhancing the adhesion strength between the metal foil and the substrate.

Examples of the two-layer substrate having a metal foil include one produced in such a manner that a metal thin film is formed on a substrate by a sputtering method or a direct plating method, and the conductor metal is thickened by such a method as an electrolytic plating method. This kind of the two-layer substrate having a metal foil is generally processed to a conductor pattern by the aforementioned subtractive method.

Examples of the two-layer substrate having a metal foil also include one produced by forming a metal thin film on a substrate by a sputtering method or a direct plating method. This kind of the two-layer substrate having a metal foil may be processed to a conductor pattern by a so-called semi-additive method, in which a conductor metal is deposited by such a method as electrolytic plating only on a necessary part as the conductor pattern, thereby providing a necessary thickness. In the case of this kind of the two-layer substrate having a metal foil, the metal thin film may not be the same as the conductor metal, such as copper, aluminum and gold, and may be nickel, palladium, iron or the like.

The present invention includes such a method that the two-layer substrate having a metal foil is used as the substrate having a metal foil, and then an electric circuit board is formed by an additive method (a semi-additive method). In the case where the two-layer substrate having a metal foil has such a metal foil that has a necessary thickness as a metal wiring, the electric circuit board may be formed by a subtractive method.

The thicknesses of the substrate and the metal foil are appropriately determined depending on purpose and are not particularly limited. For example, in the case of a copper-clad polyimide film, the thickness of the copper foil may be approximately from 1 to 50 μm, and the thickness of the substrate may be approximately from 5 to 100 μm. Examples of the substrate having a metal foil include commercially available products, such as “Pixeo”, a trade name, produced by Kaneka Corporation, “Upisel”, a trade name, produced by Ube Industries, Ltd., “Espanex”, a trade name, produced by Nippon Steel Chemical Co., Ltd., “Metaloyal”, a trade name, produced by Toray Advanced Film Co., Ltd., and “Flexbase”, a trade name, produced by Sheldahl.

### Adhesive Layer

In the case where the lower clad layer is formed on the surface of the substrate of the substrate having a metal foil through the adhesive layer as described above, the use of an adhesive in a sheet form is preferred since the adhesive layer is excellent in flatness and is ensured in accuracy of the thickness of the adhesive layer, and such a problem or the like can be avoided that the resin composition for forming the adhesive layer runs off upon forming the adhesive layer.

The adhesive in a sheet form may be an adhesive layer formed directly on a support base, and for facilitating to release the support base from the adhesive layer, one containing a support base having formed sequentially thereon a tacking agent layer and an adhesive layer, and a tacky adhesive sheet containing a support base having formed thereon a tacky adhesive layer are preferred. In particular, a tacky adhesive sheet is more preferred since the production-process thereof is simplified owing to unnecessity of preparation of a tacking agent and an adhesive separately.

A tacky adhesive composition for forming the tacky adhesive layer may be one having been ordinarily used in the optical field, and one having a storage modulus at 125° C. of 10 MPa or less obtained by measuring the tacky adhesive composition under the following condition is preferred. When the storage modulus is 10 MPa or less, the tacky adhesive layer functions as a stress relaxing layer upon expanding the optical waveguide upon heating, thereby preventing advantageously release of the optical waveguide due to the difference in thermal expansion coefficient between the optical waveguide and the substrate. From the standpoint, the storage modulus at 125° C. is more preferably 5 MPa or less.

The thickness of the tacky adhesive layer is not particularly limited and is preferably from 3 to 200 μm. When the thickness is 3 μm or more, sufficient stress relaxing effect is obtained, and when it is 200 μm or less, the demand of miniaturizing the optical device is attained, and economical advantages can be obtained. From the standpoint, the thickness of the tacky adhesive layer is more preferably from 5 to 50 μm, further preferably from 8 to 30 μm, and particularly preferably from 10 to 25 μm.

### Measurement Condition of Storage Modulus

A test specimen has a size of a length of 20 mm, a width of 4 mm and a thickness of 80 μm, and the measurement is performed at a temperature increasing rate of 5° C. per min, at a tensile mode, a vibration frequency of 10 Hz and an automatic static load.

The tacky adhesive composition for forming the tacky adhesive layer is not particularly limited as far as it satisfies the aforementioned condition of storage modulus, and specific examples thereof include a compound having two or more epoxy groups in the molecule and a compound having an ethylenic unsaturated group in the molecule. The compound may be used solely or in combination of two or more kinds thereof.

Specific examples of the preferred tacky adhesive composition include one containing (a) a high molecular weight component containing a functional group and having a weight average molecular weight of 100,000 or more, (b) an epoxy resin, (c) a phenol epoxy curing agent, (d) a photoreactive monomer resulting a cured product having Tg of 250° C. or more through irradiation with an ultraviolet ray, and (e) a photoinitiator generating a base and a radical through irradiation of an ultraviolet ray having a wavelength of from 200 to 450 nm.

In the specification, the components (a) and (c) to (e) may be abbreviated as (a) a high molecular weight component, (c) an epoxy resin curing agent, (d) a photoreactive monomer and (e) a photoinitiator, respectively.

In the present invention, a tacky adhesive sheet is preferably used upon forming the tacky adhesive layer as described above, and in the case where the components (a) to (e) are used, the following advantages are obtained.

(1) The high molecular weight component (a) and the epoxy resin (b) may be incompatible with each other depending on the combination thereof, thereby forming a so-called sea-island structure, which provides low elasticity, adhesiveness, workability and reliability at a high temperature.

(2) The use of the epoxy resin curing agent (c) and the photoreactive monomer (d) enhances the heat resistance and the reflow resistance.

(3) The photoinitiator is used in the presence of the epoxy resin curing agent (c) and the photoreactive monomer (d), whereby the epoxy resin (b) and the photoreactive monomer (d) are substantially not reacted in the absence of irradiation with light, which provide excellent storage stability. Upon irradiation with light, the photoreaction is accelerated, and a curing accelerator for the epoxy resin is generated, whereby the curing reaction of the epoxy resin proceeds smoothly under heating. Thus, both the reactivity and the storage stability are attained simultaneously.

The components constituting the preferred tacky adhesive composition will be described more specifically.

(a) Preferred examples of the high molecular weight component containing a functional group and having a weight average molecular weight of 100,000 or more include ones containing such a functional group as a glycidyl group, an acryloyl group, a methacryloyl group, a carboxyl group, a hydroxyl group and an episulfide group, from the standpoint of enhancement of the adhesiveness, and among these, a glycidyl group is preferred from the standpoint of crosslinking property. Specific examples thereof include a glycidyl group-containing (meth)acrylic copolymer containing glycidyl acrylate or glycidyl methacrylate (which will be hereinafter referred generally to “glycidyl (meth)acrylate”) as a raw material monomer and having a weight average molecular weight of 100,000 or more.

The high molecular weight component (a) is preferably incompatible with the epoxy resin (b) from the standpoint of reflow resistance. The compatibility is not determined only by the characteristics of the high molecular weight component (a), and thus both these components are selected to make an incompatible combination. In the present invention, the term glycidyl group-containing (meth)acrylic copolymer includes both a glycidyl group-containing acrylic copolymer and a glycidyl group-containing methacrylic copolymer.

Examples of the copolymer used include a (meth)acrylate ester copolymer and acrylic rubber, and acrylic rubber is more preferred. Examples of the acrylic rubber include one containing an acrylate ester as a major component and containing a copolymer of butyl acrylate and acrylonitrile, a copolymer of ethyl acrylate and acrylonitrile, or the like. Examples of the monomer for the copolymer include butyl acrylate, methyl acrylate, ethyl acrylate, methyl methacrylate, ethyl methacrylate and acrylonitrile.

In the case where a glycidyl group is selected as the functional group, glycidyl (meth)acrylate or the like is preferably used as the monomer component for the copolymer. The glycidyl group-containing (meth)acrylic copolymer having a weight average molecular weight of 100,000 or more may be produced by selecting the monomer from the aforementioned monomers, and may be a commercially available product (such as HTR-860P-3 and HTR-860P-5, produced by Nagase Chemtex Corporation) may be used.

In the high molecular weight component (a), the number of the functional groups influences the crosslinking density, and in the case where the high molecular weight component is obtained as a copolymer of plural monomers, the functional group-containing monomer used as the raw material is preferably contained in an amount of from 0.5 to 6% by mass of the copolymer while it varies depending on the resin used.

In the case where a glycidyl group-containing acrylic copolymer is used as the component (a), the amount of the glycidyl group-containing monomer, such as glycidyl (meth)acrylate, used as the raw material, and the amount of the glycidyl group-containing repeating unit is preferably from 0.5 to 6% by mass, more preferably from 0.5 to 5% by mass, and particularly preferably from 0.8 to 5% by mass, based on the copolymer. When the amount of the glycidyl group-containing repeating unit is in the range, the adhesive force can be ensured, and gelation can be prevented, owing to the gradual crosslinking reaction of the glycidyl group. Furthermore, the high molecular weight component (a) becomes incompatible with the epoxy resin (b), thereby enhancing the stress relaxing capability.

Another functional group may be introduced to glycidyl (meth)acrylate or the like to make a monomer. The mixing ratio in this case is determined in consideration of the glass transition temperature (which is hereinafter referred to as Tg) of the glycidyl group-containing (meth)acrylic copolymer, and the Tg is preferably −10° C. or more. When the Tg is −10° C. or more, the tacky adhesive layer in the B-stage has suitable tacking property providing no problem in handleability.

In the case where the glycidyl group-containing acrylic copolymer obtained by polymerizing the aforementioned monomers is used as the high molecular weight component (a) containing a functional group and having a weight average molecular weight of 100,000 or more, the polymerization method therefor is not particularly limited, and for example, pearl polymerization, solution polymerization and the like may be employed.

In the present invention, the high molecular weight component (a) has a weight average molecular weight of 100,000 or more, and the weight average molecular weight is preferably from 300,000 to 3,000,000, more preferably from 400,000 to 2,500,000, and particularly preferably from 500,000 to 2,000,000. When the weight average molecular weight is in the range, the tacky adhesive composition formed into a sheet or a film has suitable strength, flexibility and tacking property, and has suitable flow property, thereby ensuring followability to relief of a substrate. In the present invention, the weight average molecular weight means a value obtained by measuring with gel permeation chromatography and calculated by using the standard polystyrene calibration curve.

The epoxy resin (b) used in the tacky adhesive composition is not particularly limited as far as it exhibits adhesion function upon curing, and wide variation of epoxy resins, such as those disclosed in “Epoxy Jushi Handbook” (Epoxy Resin Handbook) (edited by Masaki Shimpo, published by Nikkan Kogyo Shimbun, Ltd., may be used. Specific examples thereof include a bifunctional epoxy resin, such as a bisphenol A type epoxy resin, and a novolac type epoxy resin, such as a phenol novolac type epoxy resin and a cresol novolac type epoxy resin. Furthermore, ordinarily known ones may be used, such as a polyfunctional epoxy resin, a glycidylamine type epoxy resin, a heterocyclic ring-containing epoxy resin and an alicyclic epoxy resin.

Examples of the bisphenol A type epoxy resin as one kind of the epoxy resins include Epikote 807, 815, 825, 827, 828, 834, 1001, 1004, 1007 and 1009, produced by Yuka-Shell Epoxy Co., Ltd., DER-330, 301 and 361, produced by Dow Chemical Company, and YD8125 and YDF8170, produced by Tohto Kasei Co., Ltd. Examples of the phenol novolac type epoxy resin include Epikote 152 and 154, produced by Yuka-Shell Epoxy Co., Ltd., EPPN-201, produced by Nippon Kayaku Co., Ltd., and DEN-438, produced by Dow Chemical Company. Examples of the o-cresol novolac type epoxy resin include EOCN-102S, 103S, 104S, 1012, 1025 and 1027, produced by Nippon Kayaku Co., Ltd., and YDCN701, 702, 703 and 704, produced by Tohto Kasei Co., Ltd. Examples of the polyfunctional epoxy resin include Epon 1031S, produced by Yuka-Shell Epoxy Co., Ltd., Araldite 0163, produced by Ciba Specialty Chemicals Co., Ltd., and Denacol EX-611, 614, 614B, 622, 512, 521, 421, 411 and 321, produced by Nagase Chemtex Corporation. Examples of the amine type epoxy resin include Epikote 604, produced by Yuka-Shell Epoxy Co., Ltd., YH-434, produced by Tohto Kasei Co., Ltd., TETRAD-X and TETRAD-C, produced by Mitsubishi Gas Chemical Co., Ltd., and ELM-120, produced by Sumitomo Chemical Co., Ltd. Examples of the heterocyclic ring-containing epoxy resin include Araldite PT810, produced by Ciba Specialty Chemicals Co., Ltd., and ERL4234, 4299, 4221 and 4206, produced by Union Carbide Corporation. The epoxy resins may be used solely or in combination of two or more kinds thereof. In the present invention, the bisphenol A type epoxy resin and the phenol novolac type epoxy resin are preferred for imparting large adhesive force.

The amount of the epoxy resin (b) used in the tacky adhesive composition is preferably from 5 to 250 parts by mass per 100 parts by mass of the high molecular weight component (a). When the amount of the epoxy resin (b) used is in the range, the elastic modulus and the flow property prevention upon molding can be ensured, and sufficient handleability at a high temperature can also be obtained. The amount of the epoxy resin (b) used is more preferably from 10 to 100 parts by mass, and particularly preferably from 20 to 50 parts by mass. As having been described, the epoxy resin (b) is preferably incompatible with the high molecular weight component (a).

The phenol epoxy curing agent (c) used in the tacky adhesive composition is effective since the combination thereof with the epoxy resin enhances the impact resistance under high temperature and high pressure condition, thereby retaining sufficient adhesion property under severe absorption of moisture under heat.

Examples of the component (c) include a phenol resin, such as a phenol novolac resin, a bisphenol A novolac resin and a cresol novolac resin. More specific examples thereof include Phenolite LF2882, Phenolite LF2822, Phenolite TD-2090, Phenolite TD-2149, Phenolate VH-4150 and Phenolite VH4170, trade names, produced by Dainippon Ink And Chemicals, Inc., and these may be used solely or in combination of two or more kinds thereof.

For imparting humidity resistance reliability to the tacky adhesive composition, the amount of the component (c) used is preferably from 0.5 to 1.5, and more preferably from 0.8 to 1.2, in terms of an equivalent ratio of a phenolic hydroxyl group per one epoxy group of the epoxy resin (b). When the equivalent ratio is in the range, the resin is sufficiently cured (crosslinked), thereby enhancing the heat resistance and the humidity resistance of the cured product.

The photoreactive monomer (d) resulting a cured product having Tg of 250° C. or more through irradiation with an ultraviolet ray used in the tacky adhesive composition enhances the heat resistance of the tacky adhesive sheet described later after irradiation of an ultraviolet ray and can enhance the adhesive force under heat and the reflow resistance thereof.

In the method for measuring the Tg of the photoreactive monomer (d), a specimen having a size of approximately 5 mm×5 mm is shaped from a cured product obtained from the photoreactive monomer having a photoinitiator added thereto through irradiation of an ultraviolet ray. The specimen thus prepared is measured with EXSTRA 6000, produced by Seiko Instruments Inc., in the compression mode, thereby determining the Tg. When the Tg is 250° C. or more, the cured product is excellent in heat resistance and resists heat of 250° C. or more in the evaluation of reflow resistance cracking property. Accordingly, good reflow resistance cracking property is obtained. The Tg is more preferably 260° C. or more for resisting to lead-free solder. When the Tg is too high, there is a tendency that the adhesion property of the tacky adhesive sheet after irradiation of an ultraviolet ray is impaired at ordinary temperature, and thus the upper limit thereof is preferably 350° C.

Specific examples of the photoreactive monomer include a polyfunctional acrylate, such as pentaerythritol acrylate, dipentaerythritol hexaacrylate, dipentaerythritol pentaacrylate, trimethylolpropane triacrylate, isocyanuric acid ethylene oxide (EO) modified triacrylate, ditrimethylolpropane tetraacrylate and pentaerythritol tetraacrylate, and the photoreactive monomer may be used solely or in combination of two or more kinds thereof. In the polyfunctional acrylate, dipentaerythritol hexaacrylate, dipentaerythritol pentaacrylate and the like are preferred from the standpoint of the remaining monomer after irradiation with an ultraviolet ray. Specific examples thereof include A-DPH and A-9300, trade names, produced by Shin-Nakamura Chemical Co., Ltd.

In the case where plural kinds of the photoreactive monomers (d) are used, the Tg thereof is the Tg obtained by measuring the mixture by the aforementioned measuring method, and thus both the monomers each may not necessarily have a Tg of 250° C. or more.

The amount of the photoreactive monomer (d) used in the tacky adhesive composition is preferably from 5 to 100 parts by mass per 100 parts by mass of the high molecular weight component (a). When the amount used is 5 parts by mass or more, polymerization reaction of the photoreactive monomer upon irradiation of an ultraviolet ray is promoted, thereby providing a tendency of enhancing the releasing property of the tacky adhesive sheet from the support base. When it is 100 parts by mass or less, on the other hand, the low elasticity of the high molecular weight component functions to prevent the film from becoming brittle, thereby providing a tendency of enhancing the heat resistance and the humidity resistance of the cured product. Accordingly, the amount thereof is more preferably from 10 to 70 parts by mass, and particularly preferably from 20 to 50 parts by mass.

The photoinitiator (e) generating a base and a radical through irradiation of an ultraviolet ray having a wavelength of from 200 to 450 nm in the tacky adhesive composition is generally referred to as an α-aminoketone compound. The compound is disclosed, for example, in J. Photopolym. Sci. Technol., vol. 13, No. 12001, and undergoes the following reaction upon irradiation of an ultraviolet ray.

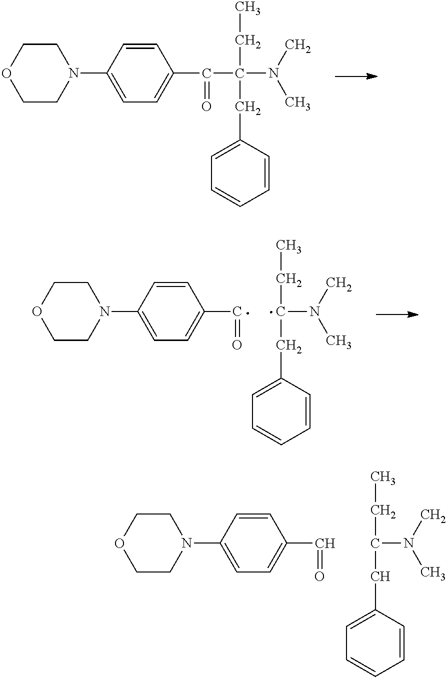

The α-aminoketone compound does not promote polymerization reaction of the photoreactive monomer before irradiation of an ultraviolet ray since no radical is present. Furthermore, it does not accelerate curing of the thermosetting resin owing to the steric hindrance. Upon irradiation with an ultraviolet ray, however, the α-aminoketone compound is dissociated to generate a radical, thereby causing polymerization of the photoreactive monomer. The steric hindrance is reduced through the dissociation of the α-aminoketone compound, thereby producing an activated amine. Accordingly, it is expected that the amine accelerates curing of the thermosetting resin, and the curing acceleration effect proceeds subsequently by heating. According to the mechanism, such a tacky adhesive sheet can be provided that is considerably excellent in storage stability at room temperature owing to the absence of a radical or an activated amine before irradiation with an ultraviolet ray. The curing rates of the photoreactive monomer and the epoxy resin are changed depending on the structures of the radical and the amine generated through irradiation with an ultraviolet ray, and thus the photoinitiator (e) (the base generating agent) can be determined corresponding to the components (b) to (d) used.

Examples of the photoinitiator (e) (the base generating agent) include 2-methyl-1-(4-methylthio)phenyl-2-morpholinopropan-1-one (Irgacure 907, produced by Ciba Specialty Chemicals Co., Ltd.), 2-benzyl-2-dimethylamino-1-(4-morpholinophenyl)-butanon-1-one (Irgacure 369, produced by Ciba Specialty Chemicals Co., Ltd.), a hexaarylbisimidazole derivative (which may have a substituent, such as a halogen, an alkoxy group, a nitro group and a cyano group, substituted on the phenyl group), and a benzoisoxazolone derivative.

In addition to the photoinitiators (the base generating agents) described above, a method of generating a base by the photo Fries rearrangement, the photo Claisen rearrangement, the Curtius rearrangement or the Stevens rearrangement may be employed.

The photoinitiator (the base generating agent) may be used as a low molecular weight compound having a molecular weight of 500 or less, and a compound obtained by introducing the photoinitiator to a main chain or a side chain of a polymer may be used. The molecular weight in this case is preferably from 1,000 to 100,000, and more preferably from 5,000 to 30,000, in terms of weight average molecular weight, from the standpoint of the tacky adhesive property and the flowability as the tacky adhesive.

The amount of the photoinitiator (e) used in the tacky adhesive composition is preferably from 0.1 to 20 parts by mass per 100 parts by mass of the high molecular weight component (a). When the amount is 0.1 part by mass or more, the amount of the remaining monomer is decreased owing to good reactivity, and when it is 20 parts by mass or less, increase of molecular weight by polymerization reaction functions suitably to decrease the amount of the low molecular weight component, thereby reducing the possibility of impairing the reflow resistance. Accordingly, the amount is more preferably from 0.5 to 15 parts by mass, and further preferably from 1 to 5 parts by mass.

Components that may be added to the tacky adhesive layer in addition to the components (a) to (e) will be described. In the tacky adhesive resin composition, (f) a high molecular weight resin having compatibility with the epoxy resin may be added from the standpoint of enhancement of flexibility and reflow, resistance cracking property. The high molecular weight resin is preferably incompatible with the high molecular weight component (a) from the standpoint of enhancement of reliability, and examples thereof include a phenoxy resin, a high molecular weight epoxy resin and a super high molecular weight epoxy resin. These may be used solely or in combination of two or more kinds thereof. In the case where the epoxy resin (b) that has compatibility with the high molecular weight component (a) is used, the use of the high molecular weight resin (f) having compatibility with the epoxy resin may result in the case where the epoxy resin (b) and the high molecular weight component (a) are incompatible with each other since the epoxy resin (b) is compatible with the component (f).

The amount of the high molecular weight resin (f) having compatibility with the epoxy resin used is preferably 40 parts by mass or less per 100 parts by mass of the total amount of the epoxy resin (b) and the epoxy resin curing agent (c). When the amount is in the range, the Tg of the tacky adhesive layer can be ensured.

In the tacky adhesive composition, various kinds of coupling agents may be added for enhancing the interfacial binding between the heterogeneous materials. Examples of the coupling agent include a silane series, a titanium series and an aluminum series.

The silane coupling agent is not particularly limited, and examples thereof include γ-methacryloxypropyltrimethoxysilane, γ-methacryloxypropylmethyldimethoxysilane, γ-mercaptopropyltrimethoxysilane, γ-mercaptopropyltriethoxysilane, 3-aminopropylmethyldiethoxysilane, 3-ureidopropyltriethoxysilane and 3-ureidopropyltrimethoxysilane, which may be used solely or in combination of two or more kinds thereof. Specific examples thereof include NUCA-189 and NUCA-1160, produced by Nippon Unicar Co., Ltd.

The amount of the coupling agent used is preferably from 0.01 to 10 parts by mass per 100 parts by mass of the high molecular weight component (a) containing a functional group and having a weight average molecular weight of 100,000 or more, from the standpoint of the effect thereof, the heat resistance and the cost.

In the tacky adhesive composition, an ion scavenger may be added for adsorbing an ionic impurity, thereby enhancing the humidity resistance reliability. The ion scavenger is not particularly limited, and examples thereof include a compound that is known as a copper inhibitor for preventing copper from being ionized and running off, such as a triazinethiol compound and a bisphenol reducing agent, and an inorganic ion adsorbent, such as zirconium series or antimony-bismuth series magnesium or aluminum compounds.

The amount of the ion scavenger used is preferably from 0.1 to 10 parts by mass per 100 parts by mass of the high molecular weight component (a) containing a functional group and having a weight average molecular weight of 100,000 or more, from the standpoint of effect of the addition, heat resistance and cost.

The tacky adhesive sheet may be obtained by dissolving or dispersing the tacky adhesive composition in a solvent to prepare a varnish, which is coated on a support base, and the solvent is removed by heating.

Specifically, a varnish obtained by dissolving the tacky adhesive composition in an organic solvent or the like is coated on a protective film (which may be referred to as a releasing sheet) by a known method, such as a knife coating method, a roll coating method, a spray coating method, a gravure coating method, a bar coating method and a curtain coating method, and then dried to form a tacky adhesive layer. Thereafter, a support base is laminated, thereby providing a tacky adhesive sheet containing the releasing sheet (protective film), the tacky adhesive layer and the support base. In alternative, the tacky adhesive composition may be coated directly on the support base in the same manner, and then dried to provide a tacky adhesive sheet, In this case, a protective film may be laminated depending on necessity.

Examples of the protective film or the support base used in the tacky adhesive sheet include a plastic film, such as a polytetrafluoroethylene film, a polyethylene film, a polypropylene film and a polymethylpentene film, and a polyester, such as polyethylene terephthalate. The tacky adhesive sheet is irradiated with an ultraviolet ray to polymerize and cure the tacky adhesive having ultraviolet ray-polymerizability, thereby decreasing the adhesion force at the interface between the tacky adhesive and the support base, which enables release of the support base. Accordingly, the support base preferably has ultraviolet ray transmissibility.

The solvent for forming the varnish is not particularly limited as far as it is an organic solvent, and can be determined in consideration of the volatility upon forming the film in view of the boiling point. Specifically, for example, a solvent having a relatively low boiling point, such as methanol, ethanol, 2-methoxyethanol, 2-ethoxyethanol, 2-butoxyethanol, methyl ethyl ketone, acetone, methyl isobutyl ketone, toluene and xylene, is preferred since curing of the film does not proceed upon producing the film. A solvent having a relatively high boiling point, such as dimethyacetamide, dimethylformamide, N-methylpyrrolidone and cyclohexanone, is preferably used for enhancing the property of the coated film. The solvent may be used solely or in combination of two or more kinds thereof.

The thickness of the support base in the tacky adhesive sheet is not particularly limited and is preferably from 5 to 250 μm. When the thickness is 5 μm or more, the workability is improved, and a thickness 250 μm or less is preferred from the standpoint of economy. From the standpoints, the thickness of the support base is more preferably from 10 to 200 μm, further preferably from 20 to 150 μm, and particularly preferably from 25 to 125 μm.

The total thickness of the tacky adhesive layer and the support base of the tacky adhesive sheet is generally from 10 to 250 μm. The thickness of the support base may be set as being equivalent to or slightly larger than the thickness of the tacky adhesive layer, thereby enhancing the workability, and specific examples of the combination of the thicknesses of tacky adhesive layer/support base m) include 5/25, 10/30, 10/50, 25/50, 50/50 and 50/75, which may be appropriately determined depending on conditions and apparatus used.

For obtaining a desired thickness of the tacky adhesive sheet, and for enhancing the flowability under heat, two or more tacky adhesive sheets, which are separately prepared, may be laminated on the side of the tacky adhesive sheet where the tacky adhesive layer is formed. In this case, the lamination condition is necessarily selected in such a manner that the tacky adhesive layers are not released from each other.

Upon irradiating the tacky adhesive sheet having the aforementioned structure with an ultraviolet ray, the adhesion strength of the support base is largely decreased after irradiation of an ultraviolet ray, and thus the support base of the tacky adhesive sheet can be released with the tacky adhesive layer retained on the substrate.

### Resin for Forming Clad Layer

The resin for forming a clad layer used in the lower clad layer and the upper clad layer is not particularly limited as far as a cured product of the resin film for forming a clad layer has a lower refractive index than a cured product of the resin film for forming a core layer described later, and is a resin that is cured through light or heat, and may be a thermosetting resin or a photosensitive resin. The resin for forming a clad layer is preferably constituted by a resin composition containing (i) a base polymer, (ii) a photopolymerizable compound and (iii) a photopolymerization initiator.

As the base polymer (i), the same base polymer (A) as described for the first invention may be used.

The base polymer (A) is preferably an epoxy resin, particularly an epoxy resin in a solid state at room temperature, from the standpoint of three-dimensional crosslinking and enhancement of the heat resistance.

Examples of the epoxy resin in a solid state at room temperature include bisphenol A type epoxy resins, such as “Epotohto YD-7020”, “Epotohto YD-7019” and “Epotohto YD-7017”, trade names, produced by Tohto Kasei Co., Ltd., and “Epikote 1010”, “Epikote 1009” and “Epikote 1008”, trade names, produced by Japan Epoxy Resin Co., Ltd.

The molecular weight of the base polymer (i) is generally 5,000 or more in terms of number average molecular weight from the standpoint of film forming property. The number average molecular weight is preferably 10,000 or more, and more preferably 30,000 or more.

The upper limit of the number average molecular weight is not particularly limited, and is generally 1,000,000 or less from the standpoint of compatibility with the photopolymerizable compound (II) and exposure developing property.

The upper limit of the number average molecular weight is preferably 500,000 or less, and more preferably 200,000 or less.

The number average molecular weight means a value obtained by measuring with gel permeation chromatography (GPC) and calculated by using the standard polystyrene.

The amount of the base polymer (i) mixed is generally approximately from 10 to 80% by mass based on the total amount of the base polymer as the component (i) and the photopolymerizable compound as the component (ii).

When the amount mixed is 10% by mass or more, a film having a thickness of approximately from 50 to 500 μm, which is necessary for constructing an optical waveguide, can be advantageously obtained easily, and when it is 80% by mass or less, the photocuring reaction proceeds sufficiently.

From the standpoints, the amount of the component (i) mixed is preferably from 20 to 70% by mass, and more preferably from 25 to 65% by mass.

The photopolymerizable compound (ii) is not particularly limited as far as it can be polymerized through irradiation with an ultraviolet ray, and examples thereof include a compound having two or more epoxy group in the molecule and a compound having an ethylenic unsaturated group in the molecule.

Specific examples of the compound having two or more epoxy groups in the molecule include a bifunctional aromatic glycidyl ether, such as a bisphenol A type epoxy resin, a tetrabromobisphenol A type epoxy resin, a bisphenol F type epoxy resin, a bisphenol AD type epoxy resin and a naphthalene type epoxy resin, a polyfunctional aromatic glycidyl ether, such as a phenol novolac type epoxy resin, a cresol novolac type epoxy resin, a dicyclopentadiene phenol type epoxy resin and a tetraphenylolethane type epoxy resin, a bifunctional aliphatic glycidyl ether, such as a polyethylene glycol type epoxy resin, a polypropylene glycol type epoxy resin, a neopentyl glycol type epoxy resin and a hexanediol type epoxy resin, a bifunctional alicyclic glycidyl ether, such as a hydrogenated bisphenol A type epoxy resin, a polyfunctional aliphatic glycidyl ether, such as a trimethylolpropane type epoxy resin, a sorbitol type epoxy resin and a glycerin type epoxy resin, a bifunctional aromatic glycidyl ester, such as diglycidyl phthalate, a bifunctional alicyclic glycidyl ester, such as diglycidyl tetrahydrophthalate and diglycidyl hexahydrophthalate, a bifunctional aromatic glycidylamine, such as N,N-diglycidylaniline and N,N-diglycidyltrifluoromethylaniline, a polyfunctional aromatic glycidylamine, such as N,N,N′,N′-tetraglycidyl-4,4-diaminodiphenylmethane, 1,3-bis(N,N-glycidylaminomethyl)cyclohexane and N,N,O -triglycidyl-p-aminophenol, a bifunctional alicyclic epoxy resin, such as alicyclic diepoxyacetal, alicyclic diepoxyadipate, alicyclic diepoxy carboxylate and vinylcyclohexene oxide, a bifunctional heterocyclic epoxy resin, such as diglycidylhydantoin, a polyfunctional heterocyclic epoxy resin, such as triglycidylisocyanurate, and a bifunctional or polyfunctional silicon-containing epoxy resin, such as an organosiloxane type epoxy resin.

The compound having two or more epoxy group in the molecule generally has a molecular weight of from 100 to 2,000, and the compound that is in a liquid state at room temperature may be used. The molecular weight is preferably from 150 to 1,000, and more preferably from 200 to 800.

The compound may be used solely or in combination of two or more kinds thereof, and may be used in combination with another photopolymerizable compound.

The molecular weight may be measured by a gel permeation chromatography (GPC) method or a mass spectrometry.

Specific examples of the compound having an ethylenic unsaturated group in the molecule include a (meth)acrylate, a halogenated vinylidene, a vinyl ether, vinylpyridine and vinylphenol, and among these, a (meth)acrylate is preferred from the standpoint of transparency and heat resistance, and a monofunctional one, a bifunctional one and a trifunctional or higher functional one may be used.

Examples of the monofunctional (meth)acrylate include methoxypolyethylene glycol (meth)acrylate, phenoxypolyethylene glycol (meth)acrylate, lauryl (meth)acrylate, isostearyl (meth)acrylate, 2-(meth)acryloylolxyethyl succinate, p-cumylphenoxyethylene glycol (meth)acrylate, 2-tetrahydropyranyl (meth)acrylate, isobornyl (meth)acrylate, methyl (meth)acrylate, ethyl (meth)acrylate, butyl (meth)acrylate and benzyl (meth)acrylate.

Examples of the bifunctional (meth)acrylate include ethoxylated 2-methyl-1,3-propanediol di(meth)acrylate, neopentyl glycol di(meth)acrylate, 1,6-hexanediol di(meth)acrylate, 2-methyl-1,8-octanediol diacrylate, 1,9-nonanediol di(meth)acrylate, 1,10-nonanediol di(meth)acrylate, ethoxylated polypropylene glycol di(meth)acrylate, propoxylated ethoxylated bisphenol A diacrylate, ethylene glycol di(meth)acrylate, triethylene glycol di(meth)acrylate, tetraethylene glycol di(meth)acrylate, polyethylene glycol di(meth)acrylate, polypropylene glycol di(meth)acrylate, ethoxylated bisphenol A di(meth)acrylate, tricyclodecane di(meth)acrylate, ethoxylated cyclohexanedimethanol di(meth)acrylate, 2-hydroxy-1-acryloxy-3-methacryloxypropane, 2-hydroxy-1,3-dimethacryloxypropane, 9,9-bis(4-(2-acryloyloxyethoxy)phenyl)fluorene, 9,9-(bis(3-phenyl-4-acryloylpolyoxyethoxy)fluorene, and bisphenol A type, phenol novolac type, a cresol novolac type and glycidyl ether type epoxy (meth)acrylates.

Examples of the trifunctional or higher functional (meth)acrylate include ethoxylated isocyanuric acid tri(meth)acrylate, ethoxylated glycerin tri(meth)acrylate, trimethylolpropane tri(meth)acrylate, ethoxylated trimethylolpropane tri(meth)acrylate, pentaerythritol tri(meth)acrylate, pentaerythritol tetra(meth)acrylate, ethoxylated pentaerythritol tetra(meth)acrylate, propoxylated pentaerythritol tetra(meth)acrylate, ditrimethylolpropane tetra(meth)acrylate, caprolactone-modified ditrimethylolpropane tetraacrylate and dipentaerythritol hexa(meth)acrylate.

These compounds may be used solely or in combination of two or more kinds thereof.

The term (meth)acrylate herein means acrylate and methacrylate.

The amount of the photopolymerizable compound (II) mixed is generally approximately from 20 to 90% by mass based on the total amount of the base polymer as the component (i) and the photopolymerizable compound as the component (ii).

When the amount mixed is 20% by mass or more, the base polymer can be cured easily with the photopolymerizable compound entrained therein, and when it is 90% by mass or less, a clad layer having a sufficient thickness can be easily formed.

From the standpoints, the amount of the component (ii) mixed is preferably from 25 to 85% by mass, and more preferably from 30 to 80% by mass.

The photopolymerization initiator as the component (iii) is not particularly limited, and examples of the initiator for the epoxy compound include an aryldiazonium salt, such as p-methoxybenzenediazonium hexafluorophosphate, a diaryliodonium salt, such as diphenyliodonium hexafluorophosphonium salt and diphenyliodonium hexafluoroantimonate salt, a triarylsulfonium salt, such as triphenylsulfonium hexafluorophosphonium salt, triphenylsulfonium hexafluoroantimonate salt, diphenyl-4-thiophenoxyphenyl sulfonium hexafluoroantimonate salt and diphenyl-4-thiophenoxyphenyl sulfonium pentafluorohydroxyantimonate salt, a triarylselenonium salt, such as triphenylselenonium hexafluorophosphonium salt, triphenylselenonium borofluoride salt and triphenylselenonium hexafluoroantimonate salt, a dialkylphenazylsulfonium salt, such as dimethylphenazylsulfonium hexafluoroantimonate salt and diethylphenazylsulfonium hexafluoroantimonate salt, a dialkyl-4-hydroxyphenylsulfonium salt, such as 4hydroxyphenyldimethylsulfonium hexafluoroantimonate salt and 4-hydroxyphenylbenzylmethylsulfonium hexafluoroantimonate salt, a sulfonate ester, such as α-hydroxymethylbenzoyl sulfonate, N-hydroxyimide sulfonate, α-sulfonyloxy ketone and β-sulfonyloxy ketone.

Examples of the initiator for the compound having an ethylenic unsaturated group in the molecule include an aromatic ketone, such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 2-benzyl-2-dimethylamino-1-(4-morpholinophenyl)-butan-1-one, 2,2-dimethoxy-1,2-diphenylethan-1-one, 1-hydroxycyclohexyl phenyl ketone, 2-hydroxy-2-methyl-1-phenylpropan-1-one, 1-(4-(2-hydroxyethoxy)phenyl)-2-hydroxy-2-methyl-1-propan-1-one and 1,2-methyl-1-(4-(methylthio)phenyl)-2-morpholinopropan-1-one, a quinone compound, such as 2-ethylanthraquinone, phenanthrenequinone, 2-tert-butylanthraquinone, octylmethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone and 2,3-dimethylanthraquinone, a benzoin ether compound, such as benzoin methyl ether, benzoin ethyl ether and benzoin phenyl ether, a benzoin compound, such as benzoin, methylbenzoin and ethylbenzoin, a benzyl derivative, such as benzyl methyl ketal, a 2,4,5-triarylimidazole dimer, such as 2-(o-chlorophenyl)-4,5-diphenyl imidazole dimer, 2-(o-chlorophenyl)-4,5-di(methoxyphenyl)imidazole dimer, 2-(o-fluorophenyl)-4,5-diphenylimidazole dimer, 2-(o-methoxyphenyl)-4,5-diphenylimidazole dimer and 2-(p-methoxyphenyl)-4,5-diphenylimidazole dimer, a phosphine oxide compound, such as bis(2,4,6-trimethylbenzoyl)phenylphosphine oxide, bis(2,6-dimethoxybenzoyl)-2,4,4-rimethylpentylphosphine oxide and 2,4,6-trimethylbenzoyldiphenylphosphine oxide, an acridine derivative, such as 9-phenylacrydine and 1,7-bis(9,9′-acrydinyl)heptane, N-phenylglycine, an N-phenylglycine derivative, and a coumarin compound.

In the case where an aryl group is substituted in 2,4,5-triarylimidazole dimer, two aryl groups may be the same as each other to form a symmetric dimer, or may be different from each other to form an asymmetric dimer.

A combination of a thioxanthone compound and a tertiary amine compound, such as a combination of diethylthioxanthone and dimethylaminobenzoic acid, may be used.

Among the photopolymerization initiators, an aromatic ketone and a phosphine oxide compound are preferred from the standpoint of enhancement of the transparency of the core layer and the clad layer.

The photopolymerization initiator (iii) may be used solely or in combination of two or more kinds thereof.

The amount of the photopolymerization initiator (iii) used is generally approximately from 0.1 to 10 parts by mass per 100 parts by mass of the total amount of the base polymer as the component (i) and the photopolymerizable compound as the component (ii).

When the amount used is 0.1 part by mass or more, sufficient photosensitivity can be obtained, and when it is 10 parts by mass or less, only the surface of the optical waveguide is selectively cured, whereby decrease of the transmission loss due to the photopolymerization initiator itself can be prevented from being increased while preventing curing from being insufficient.

From the standpoints, the amount of the component (iii) used is preferably from 0.5 to 5 parts by mass, and more preferably from 1 to 4 parts by mass.

The resin for forming a clad layer used in the present invention may further contain, depending on necessity, so-called additives, such as an antioxidant, a yellowing preventing agent, an ultraviolet ray absorbent, a visible ray absorbent, a colorant, a plasticizer, a stabilizer and a filler, in such proportions that do not impair the advantages of the present invention.

The resin for forming a clad layer may be used as a resin varnish for forming a clad layer by dissolving a resin composition containing the base polymer (i), the photopolymerizable compound (II) and the photopolymerization initiator (iii) in a solvent.

The resin film for forming a clad layer is preferably used for forming the lower clad layer and the upper clad layer as described above, and the resin film for forming a clad layer can be easily produced by coating the resin varnish for forming a clad layer on a base film depending on necessity, and then removing the solvent.

The base film, which is used depending on necessity in the production process of the resin film for forming a clad layer, is a support that supports the resin film for forming a clad layer, and the material therefor is not particularly limited. Preferred examples of the material include polyester, such as polyethylene terephthalate (PET), polypropylene, and polyethylene, from the standpoint that the resin film for forming a clad layer can be easily released from the base film, and the base film has heat resistance and solvent resistance.

The base film may be subjected to a releasing treatment, an antistatic treatment or the like for facilitating release of the resin film for forming a clad layer in a later stage.

The thickness of the base film is generally from 5 to 50 μm. When the thickness of the base film is 5 μm or more, the strength as the support can be advantageously obtained easily, and when it is 50 μm or less, the winding property upon producing in the form of a roll is advantageously enhanced. From the standpoints, the thickness of the base film is preferably from 10 to 40 μm, and more preferably from 15 to 30 μm.

A protective film may be adhered to the resin film for forming a clad layer in consideration of protection of the film and the winding property upon producing in the form of a roll.

The protective film used may be the similar ones as exemplified as the base film above, and may be subjected to a releasing treatment, an antistatic treatment or the like depending on necessity.

The solvent used in the resin varnish for forming a clad layer is not particularly limited as far as it can dissolve a resin composition containing the components (i) to (iii), and examples thereof include acetone, methyl ethyl ketone, methyl cellosolve, ethyl cellosolve, toluene, N,N-dimethylacetamide, propylene glycol monomethyl ether, propylene glycol monomethyl ether acetate, cyclohexanone, N-methyl-2-pyrrolidone and mixed solvents thereof.

The solid content of the varnish for forming a clad layer is generally from 30 to 80% by mass, preferably from 35 to 75% by mass, and more preferably from 40 to 70% by mass.

The thickness of the resin film for forming a clad layer is not particularly limited and is generally controlled to in such a manner that the thickness of the clad layer after drying is from 5 to 500 μm. When the thickness of the clad layer is 5 μm or more, the thickness of the clad layer that is necessary for confining light can be ensured, and when it is 500 μm or less, the thickness of the clad layer can be easily controlled uniformly. From the standpoints, the thickness of the clad layer is preferably from 10 to 100 μm, and more preferably from 20 to 90 μm.

The thicknesses of the clad layers may be the same as or different from each other between the lower clad layer firstly formed and the upper clad layer for embedding the core pattern, and the thickness of the upper clad layer is preferably larger for embedding the core pattern than the cove layer.

### Resin for Forming Core Layer

The resin for forming a core layer used in the present invention is designed in such a manner that a cured product thereof has a higher refractive index than the clad layer. A resin composition capable of forming a core pattern with an ultraviolet ray may be used, and a photosensitive resin composition is preferred.

Specifically, a resin composition that is similar to the resin for forming the clad layer is preferably used.

Specifically, the resin composition contains the base polymer (i), the photopolymerizable compound (II) and the photopolymerization initiator (iii) and may further contain the arbitrary components, as described above.

Accordingly, the cured product of the resin film for forming a core layer is designed to have a higher refractive index than the cured product of the resin film for forming an optical waveguide used in the clad layer. The resin for forming a core layer may be used as a resin varnish for forming a core layer by dissolving a resin composition containing the base polymer (i), the photopolymerizable compound (ii) and the photopolymerization initiator (iii) in a solvent.

The resin film for forming a core layer can be easily produced by coating the resin varnish for forming a core layer on a base film depending on necessity, and then removing the solvent. The base film, which is used depending on necessity in the production process of the resin film for forming a core layer, is a support that supports the resin film for forming a core layer. The material therefor is not particularly limited, and the similar base film used in the production process of the resin film for forming a clad layer may be used.

Preferred examples of the material include polyester, such as polyethylene terephthalate (PET), polypropylene, and polyethylene, from the standpoint that the resin film for forming a core layer can be easily released from the base film, and the base film has heat resistance and solvent resistance.

A highly transparent flexible base film is preferably used for enhancing the transmittance of light for exposure and for reducing the roughness on the side wall of the core pattern. The highly transparent base film generally has a haze value of 5% or less, preferably 3% or less, and more preferably 2% or less.

Examples of the commercially available base film include “Cosmoshine A1517” and “Cosmoshine A4100”, trade names, produced by Toyobo Co., Ltd.

The base film may be subjected to a releasing treatment, an antistatic treatment or the like for facilitating release of the resin film for forming a core layer in a later stage.

The thickness of the base film is generally from 5 to 50 μm. When the thickness of the base film is 5 μm or more, the strength as the support can be advantageously obtained easily, and when it is 50 μm or less, the gap to the mask upon forming the pattern is reduced, thereby enabling formation of a finer pattern advantageously. From the standpoints, the thickness of the base film is preferably from 10 to 40 μm, and more preferably from 15 to 30 μm.

A protective film may be adhered to the resin film for forming a core layer in consideration of protection of the film and the winding property upon producing in the form of a roll. The protective film used may be the similar ones as exemplified as the base film used in the resin film for forming a clad layer, and may be subjected to a releasing treatment, an antistatic treatment or the like depending on necessity.

The solvent used in the resin varnish for forming a core layer is not particularly limited as far as it can dissolve a resin composition containing the components (i) to (iii), and examples thereof include acetone, methyl ethyl ketone, methyl cellosolve, ethyl cellosolve, toluene, N,N-dimethylacetamide, propylene glycol monomethyl ether, propylene glycol monomethyl ether acetate, cyclohexanone, N-methyl-2-pyrrolidone and mixed solvents thereof.

The solid content of the varnish for forming a core layer is generally from 30 to 80% by mass, preferably from 35 to 75% by mass, and more preferably from 40 to 70% by mass.

The thickness of the resin film for forming a core layer is not particularly limited and is generally controlled to in such a manner that the thickness of the core layer after drying is from 10 to 100 μm. When the thickness of the core layer is 10 μm or more, the positioning tolerance upon coupling a light receiving/emitting device or an optical fiber after forming an optical waveguide can be advantageously enhanced, and when it is 100 μm or less, the coupling efficiency with a light receiving/emitting device or an optical fiber after forming an optical waveguide can be advantageously improved. From these standpoints, the thickness of the core layer is preferably from 29 to 90 μm, and more preferably in a range of from 30 to 80 μm.

The core layer can be easily produced by coating the resin varnish for forming a core layer by a spin coating method or the like on the clad layer, and then removing the solvent.

The method for producing an optoelectronic composite substrate of the present invention (the third invention) will be described with reference to FIG. 12. In the first step, (1) as shown in FIG. 12(a), a lower clad layer 3-31 is formed directly or through an adhesive layer 3-20 on a surface of a substrate 12 of an electric circuit board 3-10 having a conductor pattern 3-11a formed on the substrate 3-12 and having a conductor protective layer 3-14 formed depending on necessity thereon, or in alternative, (2) as shown in FIG. 12(a′-1), a lower clad layer 3-31 is formed directly or through an adhesive layer 3-20 on a surface of a substrate 3-12 of a substrate having a metal foil 3-13 containing a metal foil 3-11 and the substrate 3-12, then as shown in FIG. 12(a′-2), the metal foil 3-11 is processed to a conductor pattern 3-11a, and then as shown in FIG. 12(a′-3), a conductor protective layer 3-14 is formed depending on necessity, thereby providing an electric circuit board having a lower clad layer.

In the case where the lower clad layer 3-31 is formed directly on the surface of the substrate 3-12, such a method is employed that the varnish of the resin for forming a clad layer is coated by a known method, such as a spin coating method, and the solvent is removed.

In the case where the lower clad layer 3-31 is formed on the surface of the substrate 3-12 through the adhesive layer 3-20, the resin film for forming a clad layer is used. The resin film for forming a clad layer can be easily produced by coating the varnish of the resin for forming a clad layer on a base film by a known method, such as a spin coating method, depending on necessity, and then removing the solvent. The method using the resin film for forming a clad layer is preferred since the accuracy in thickness of the lower clad layer can be ensured. The adhesive layer 3-20 may be formed by coating an adhesive composition directly on the surface of the substrate 3-12, and as described above, an adhesive in the form of a sheet containing a support base having formed thereon an adhesive layer, particularly a tacky adhesive sheet containing a support base having formed thereon a tacky adhesive layer, is preferably used.

In the case where the tacky adhesive sheet is used, after releasing the protective film on the tacky adhesive layer, the tacky adhesive layer is laminated on the surface of the substrate 3-12 of the electric circuit board 3-10 or the substrate having a metal foil 3-13, and then the support base is released to form the tacky adhesive layer 3-20. Upon irradiating the tacky adhesive sheet having the aforementioned structure with an ultraviolet ray, the adhesion force to the support base is largely decreased, and the support base can be easily released with the tacky adhesive layer retained on the substrate 3-12. The heating temperature upon laminating is preferably from 50 to 130° C., and the compression pressure is preferably approximately from 0.1 to 1.0 MPa (from 1 to 10 kgf/cm²), but the conditions are not particularly limited. The protective film and the support base are preferably not subjected to an adhesion treatment and are preferably subjected to a releasing treatment depending on necessity, for facilitating release from the tacky adhesive layer.

The resin film for forming a clad layer is adhered on the tacky adhesive layer formed on the surface of the substrate 3-12 in this manner. Upon adhering, the aforementioned laminator may be used. In the case where the resin film for forming a clad layer has a protective film on the opposite side to the base film, the protective film is released, and the resin film for forming a clad layer is pressed under heating onto the tacky adhesive sheet, and is cured by light or heat, thereby forming a clad layer. The resin film for forming a clad layer is preferably laminated under reduced pressure from the standpoint of adhesion and followability, and the conditions therefor may be the same as the case of laminating the tacky adhesive layer.

In the aforementioned method, the adhesive layer 3-20 is formed on the surface of the substrate 3-12, and then the resin film for forming a clad layer is adhered thereon, and the order of the operations may be reversed.

Examples of the method for forming the conductor pattern 3-11a from the metal foil 3-11 as shown in FIG. 12(a′-2) include a subtractive method, in which the unnecessary part as the conductor pattern is removed from the metal foil having the necessary thickness, and a semi-additive method, in which a metal is deposited by electrolytic plating or the like on the necessary part as the conductor pattern on a relatively thin metal foil to obtain the necessary thickness.

In the case of the method for forming a conductor pattern by the subtractive method, a photocurable film is formed on the surface of the metal foil, and developed after exposing through a photomask, and then a resist pattern is formed with an etching resist. Thereafter, the part that is not covered with the etching resist is removed by etching, thereby forming a conductor pattern, and finally the etching resist is removed to construct an electric circuit board. The photocurable film formed on the surface of the metal foil may be formed by coating a varnish, which is obtained by mixing or dispersing a thermosetting resin, such as an epoxy resin, a photocuring agent and a curing accelerator, and depending on necessity, a pigment, a flowability controlling agent, a viscosity controlling agent and the like, in a diluent, directly on the surface of the metal foil, followed by drying. In alternative, the photocurable film may also be formed in such a manner that the varnish is coated on a carrier film, followed by drying, to prepare a semi-cured dry film, which is laminated on the metal foil.

Examples of a commercially available product of the etching resist material in the form of a varnish include Opto-ER N-350 (a trade name, produced by Nippon Paint Co., Ltd.), and examples of a commercially available product of the etching resist material in the form of a dry film include Photec H-N930 (a trade name, produced by Hitachi Chemical Co., Ltd.). After forming the resist pattern, for removing the part that is not covered by the etching resist, such an etching solution may be used, such as a cupric chloride solution, a ferric chloride solution and an ammonium persulfate solution, and the etching solution may be sprayed to remove the part that is not covered by the etching resist, thereby forming the conductor pattern.

In the case of the method for forming a conductor pattern by the semi-additive method, a photoresist material is coated on the metal foil, which is then subjected to photolithography to form a plated resist layer (a resist pattern). Thereafter, a conductor is deposited on the exposed part of the metal foil without the resist layer by performing electrolytic plating with the metal foil as a power feeding film, thereby forming a conductor layer (a conductor pattern). Subsequently, the plated resist layer is removed to expose the metal foil, and then the metal foil exposed by removing the plated resist layer is removed by etching with the conductor layer as a mask, thereby constructing the electric circuit board.

The photoresist material is not particularly limited, and various commercially available materials may be used. For example, a liquid positive resist containing a novolac resin as a major component, and containing a photosensitizing agent and a solvent, such as ethyl lactate and n-butyl acetate, may be used. The liquid positive resist is commercially available, for example as OFPR (produced by Tokyo Ohka Kogyo Co., Ltd.). As the photoresist material, a photoresist film may be adhered. The photoresist film is not particularly limited, and various commercially available materials may be used. For example, in the case where Sunfort® ASG-253, a trade name, produced by Asahi Kasei Corporation, is used, it may be adhered to a polyimide film by using a commercially available laminator under a pressure of approximately 0.4 MPa under heating to 110° C. Upon developing, the non-exposed part can be removed by using a sodium carbonate aqueous solution.

After forming the resist layer, electrolytic plating is performed with the metal foil as a power feeding film, thereby depositing a conductor layer on the exposed part of the metal foil. Examples of the electrolytic plating solution for plating copper include a sulfate salt bath and a sulfamine bath. Examples thereof for plating silver, gold or an alloy thereof include a cyan bath. After performing the electrolytic plating, the resist layer is removed to expose the metal foil. For example, the photoresist may be released or dissolved by immersing a releasing solution. Specifically, in the case where the film resist produced by Asahi Kasei Corporation is used, the resist may be removed with an aqueous solution of sodium hydroxide or potassium hydroxide having a concentration of approximately from 2 to 3% or an organic amine releasing solution. In the case of the liquid resist containing a novolac resin as a major component, a releasing solution containing an organic solvent, such as propylene glycol methyl ether acetate and alkylbenzene sulfonate, may be used. After forming the resist layer, the resist layer is removed to expose the metal foil, which is removed by etching, and thus the metal foil and the conductor layer are made to remain only on the area of the conductor pattern.

The etching solution is determined depending on the metal of the metal foil film and the metal of the conductor layer. The etching solution preferably has such selectivity that the metal foil is removed, but the conductor layer is not removed, but since there is a difference in thickness between the metal foil and the conductor layer, the metal foil can be completely removed while the conductor layer is not completely removed by controlling the etching time, and thus a solution capable of removing at least the metal foil may be used. In the case where the metal foil and the conductor layer are formed of the same metal, the metal foil is completely removed while the conductor layer is not completely removed by controlling the etching time.

For example, in the case where the metal foil is formed of nickel and the conductor layer is formed of copper, a aqueous solution of FeCl₃, HNO₃ and an acid including HNO₃ may be used as the etching solution. HNO₃ is particularly preferred since it dissolves nickel but does not dissolve copper.

For example, in the case where the metal foil is formed of copper and the conductor layer is also formed of copper, aqueous solutions of FeCl₃, CuCl₂, (NH₄)₂S₂O₈ and the like, an aqueous ammonia and the like may be used.

Furthermore, for example, in the case where the metal foil is formed of silver, HNO₃, a mixed solution of H₂SO₄ and H₂O₂, an aqueous solution of Fe(NO₃)₃, and the like may be used as the etching solution.

Moreover, for example, in the case where the metal foil is formed of iron, HNO₃ may be used as the etching solution. Furthermore, for example, in the case where the metal foil is formed of palladium, an aqueous solution of NH₃I and the like may be used as the etching solution.

Upon forming the conductor protective layer 3-14 on the conductor pattern 3-11a, a photocurable film is formed on the surface of the conductor pattern 3-11a and developed after exposing through a photomask, thereby forming the conductor protective layer 14 for insulating and protecting the conductor pattern as shown in FIG. 12(e). The photocurable film formed on the surface of the conductor pattern may be formed by coating a varnish, which is obtained by mixing or dispersing a thermosetting resin, such as an epoxy resin, a photocuring agent and a curing accelerator, and depending on necessity, a pigment, a flowability controlling agent, a viscosity controlling agent and the like, in a diluent, directly on the surface of the conductor pattern, followed by drying. In alternative, the photocurable film may also be formed in such a manner that the varnish is coated on a carrier film, followed by drying, to prepare a semi-cured dry film, which is laminated on the substrate. Examples of a commercially available product of the solder resist material in the form of a varnish include Probicote 5000 (a trade name, produced by Nippon Paint Co., Ltd.), and examples of a commercially available product of the solder resist material in the form of a dry film include Photec SR-2300G-50 (a trade name, produced by Hitachi Chemical Co., Ltd.).

The core pattern is formed by providing a layer (a core layer) of the resin for forming a core on the lower clad layer, and then exposing and developing the core layer. The method for forming the core layer is not particularly limited, and a method of coating a varnish of the resin for forming a core directly on the lower clad layer, followed by drying, may be employed, but a method of using a resin film for forming a core layer is preferred since the accuracy in thickness of the core layer can be ensured.

The resin film for forming a core layer that contains a layer of the resin for forming a core layer and a base film is preferred owing to good handleability thereof, but the resin film for forming a core layer may be formed solely of a layer of the resin for forming a core layer.

In the case where a protective film is provided on the resin film for forming a core layer on the side opposite to the base film, the protective film is released, and then the resin film for forming a core layer is laminated. In this case, the protective film and the base film are preferably not subjected to an adhesion treatment and are preferably subjected to a releasing treatment depending on necessity, for facilitating release from the core layer.

The core layer thus formed is then exposed and developed, thereby forming a desired core pattern. Specifically, the core layer is irradiated imagewise with an ultraviolet ray through a photomask pattern.

Examples of the light source of an ultraviolet ray include known light sources capable of irradiating an ultraviolet ray effectively, such as a carbon arc lamp, a mercury vapor arc lamp, a super high pressure mercury lamp, a high pressure mercury lamp and a xenon lamp.

In the case where the base film remains on the core layer, the base film is released, and the unexposed part is removed by development, such as wet development, thereby forming the core pattern.

Upon performing wet development, an organic solvent developer liquid or an alkali developer liquid, which is suitable for the resin film for forming a core layer or the resin varnish for forming a core layer, is used, and the development is performed by a known method, such as spraying, immersion under shaking, brushing or scrubbing.

Examples of the organic solvent developer liquid include N-methylpyrrolidone, N,N-dimethylformamide, N,N-dimethylacetamide, cyclohexanone, methyl ethyl ketone, methyl isobutyl ketone, γ-butyrolactone, methyl cellosolve, ethyl cellosolve, propylene glycol monomethyl ether and propylene glycol monomethyl ether acetate.

Water may be added to the organic solvent in an amount of from 1 to 20 parts by mass per 100 parts by mass of the organic solvent for preventing ignition.

Examples of the alkali developer liquid include an alkaline aqueous solution and an aqueous developer liquid. The base of the alkaline aqueous solution is not particularly limited, and examples thereof include an alkali hydroxide, such as hydroxides of lithium, sodium and potassium, an alkali carbonate, such as carbonate salts or bicarbonate salts of lithium, sodium, potassium and ammonium, an alkali metal phosphate salt, such as potassium phosphate and sodium phosphate, an alkali metal pyrophosphate, such as sodium pyrophosphate and potassium pyrophosphate, a sodium salt, such as borax and sodium metasilicate, and an organic base, such as tetramethylammonium hydroxide, triethanolamine, ethylenediamine, diethylenetriamine, 2-amino-2-hydroxymethyl-1,3-propanediol and 1,3-diaminopropanol-2-morpholine.

The alkaline aqueous solution used for developing preferably has pH of from 9 to 11, and the temperature thereof is controlled corresponding to the developing property of the layer of the resin composition for forming a core.

The alkaline aqueous solution may contain a surfactant, a defoaming agent and a small amount of an organic solvent for promoting development.

Among these, aqueous solutions of lithium carbonate, sodium carbonate and potassium carbonate are preferred since they have less stimulation on the human body and less load on the environments.

An organic solvent may be used in combination with the alkali aqueous solution depending on necessity. The organic solvent referred herein is not limited as far as it is miscible with the alkali aqueous solution, and examples thereof include an alcohol, such as methanol, ethanol, isopropanol, butanol, ethylene glycol and propylene glycol, a ketone, such as acetone and 4-hydroxy-4-methyl-2-pentanone, and a polyhydric alcohol alkyl ether, such as ethylene glycol monomethyl ether, ethylene glycol monoethyl ether, propylene glycol monomethyl ether, propylene glycol monoethyl ether, diethylene glycol monomethyl ether, diethylene glycol monoethyl ether and diethylene glycol monobutyl ether.

These may be used solely or in combination of two or more kinds thereof.

As a post-treatment of the development, the core pattern of the optical waveguide may be rinsed with a rinsing liquid containing water and the aforementioned organic solvent depending on necessity. The organic solvent may be used solely or in combination of two or more kinds thereof. The concentration of the organic solvent is preferably from 2 to 90% by mass, and the temperature is controlled corresponding to the developing property of the layer of the resin composition for forming a core.

The method of the development include dipping, paddling, spraying, such as high-pressure spraying, brushing and scrubbing, and high-pressure spraying is most suitable for enhancing the resolution.

Two or more kinds of the developing methods may be used in combination depending on necessity.

As a post-treatment of the development, the core pattern may be heated to approximately from 60 to 250° C. or exposed to approximately from 0.1 to 1,000 mJ/cm², thereby further curing the core pattern.

Subsequently, a layer of the resin for forming a clad layer is formed on the core pattern and then cured to form the upper clad layer. As described above, the upper clad layer may be formed by coating the varnish of the resin composition for forming a clad layer directly thereon, but the resin film for forming an upper clad layer is preferably used. In this case, the operation of laminating the resin film for forming an upper clad layer for embedding the core pattern, and the operation of curing the layer of the resin for forming a clad layer of the resin film for forming the upper clad layer, thereby forming the upper clad layer are performed.

The thickness of the upper clad layer in this case is preferably larger than the thickness of the core layer as described above.

The curing operation is performed with light or heat in the similar manner as above.

In the case where the resin film for forming a clad layer has a protective film on the opposite side to the base film, the protective film is released, and the resin film for forming a clad layer is pressed under heating and cured by light or heat, thereby forming a clad layer. The base film in this case may be released or may remain adhered depending on necessity.

In the case where the base film remains adhered, the layer of the resin for forming a clad layer is preferably formed on the base film having been subjected to an adhesive treatment.

The protective film is preferably not subjected to an adhesion treatment and is preferably subjected to a releasing treatment depending on necessity, for facilitating release from the resin film for forming a clad layer.

In the optoelectronic composite substrate obtained by the production method of the present invention, an optical path conversion mirror or a light receiving device may be mounted, thereby coupling easily the electric circuit board portion and the optical waveguide portion to each other. An optical device, such as a plane emission laser or diode, may be mounted on the optoelectronic composite substrate obtained by the production method of the present invention, thereby providing easily an optoelectronic composite module.

The production method of an optoelectronic composite substrate of the present invention (the fourth invention) will be described with reference to FIG. 13. In the modified first step, as shown in FIG. 13(a), a lower clad layer 4-31 is formed on a surface of a substrate 4-12 of a substrate having a metal foil 4-13 having a metal foil 4-11 and the substrate 4-12 directly or through an adhesive layer 4-20.

In the case where the lower clad layer 4-31 is formed directly on the surface of the substrate 4-12, such a method is employed that the varnish of the resin for forming a clad layer is coated by a known method, such as a spin coating method, and the solvent is removed.

In the case where the lower clad layer 4-31 is formed on the surface of the substrate 4-12 through the adhesive layer 4-20, the resin film for forming a clad layer is used. The resin film for forming a clad layer can be easily produced by coating the varnish of the resin for forming a clad layer on a base film by a known method, such as a spin coating method, depending on necessity, and then removing the solvent. The method using the resin film for forming a clad layer is preferred since the accuracy in thickness of the lower clad layer can be ensured.

The method for forming the adhesive layer 4-20 on the surface of the substrate 4-12 is not particularly limited, and an adhesive composition may be coated directly on the surface of the substrate, but a method of transferring an adhesive layer from an adhesive in a sheet form, which contains a support base and the adhesive layer, to the surface of the substrate 4-12 is preferred since the adhesive layer is excellent in flatness and is ensured in accuracy of the thickness of the adhesive layer, and such a problem or the like can be avoided that the resin composition for forming the adhesive layer runs off upon forming the adhesive layer. The adhesive in a sheet form is particularly preferably a tacky adhesive sheet containing a support base having thereon a tacky adhesive layer.

In the case where the tacky adhesive sheet is used, after releasing the protective film on the tacky adhesive layer, the tacky adhesive layer is laminated on the surface of the substrate 4-12 of the substrate having a metal foil 4-13, and then the support base is released to form the tacky adhesive layer 4-20. Upon irradiating the tacky adhesive sheet having the aforementioned structure with an ultraviolet ray, the adhesion force to the support base is largely decreased, and the support base can be easily released with the tacky adhesive layer retained on the substrate.

The heating temperature upon laminating is preferably from 50 to 130° C., and the compression pressure is preferably approximately from 0.1 to 1.0 MPa (from 1 to 10 kgf/cm²), but the conditions are not particularly limited. The protective film and the support base are preferably not subjected to an adhesion treatment and are preferably subjected to a releasing treatment depending on necessity, for facilitating release from the tacky adhesive layer.

The resin film for forming a clad layer is laminated on the tacky adhesive layer formed in this manner. In the case where the resin film for forming a clad layer has a protective film on the opposite side to the base film, the protective film is released, and the resin film for forming a clad layer is pressed under heating onto the tacky adhesive sheet, and is cured by light or heat, thereby forming a clad layer. The resin film for forming a clad layer is preferably laminated under reduced pressure from the standpoint of adhesion and followability, and the conditions therefor may be the same as the case of laminating the tacky adhesive layer.

In the aforementioned method, the adhesive layer 4-20 is formed on the surface of the substrate 4-12, and then the resin film for forming a clad layer is adhered thereon, and the order of the operations may be reversed.

The second step of the production method of the present invention (the fourth invention) is a step of constructing an optical waveguide, in which specifically as shown in FIG. 13(b), a core pattern 4-32 is formed on the lower clad layer 4-31, and then as shown in FIG. 13(c), an upper clad layer 4-33 is formed on the core pattern 4-32, thereby constructing an optical waveguide 4-30.

The core pattern 4-32 is formed by providing a layer (a core layer) of the resin for forming a core on the lower clad layer 4-31, and then exposing and developing the core layer. The method for forming the core layer may be those described for the third invention.

The third step of the production method of the present invention (the fourth invention) is a step of constructing an electric circuit board from a substrate having a metal foil, in which specifically as shown in FIG. 13(d), an electric circuit board 4-10 is constructed by converting a metal foil 4-11 to a conductor pattern 4-11a. This step is the same as the step of converting the metal foil of the substrate having a metal foil to the conductor pattern in the third invention (the first step of the third invention), and the methods and conditions therefor may be the same as those in the third invention.

In the optoelectronic composite substrate obtained by the production method of the present invention (the fourth invention), an optical path conversion mirror or a light receiving device may be mounted, thereby coupling easily the electric circuit board portion and the optical waveguide portion to each other.

An optical device, such as a plane emission laser or diode, may be mounted on the optoelectronic composite substrate obtained by the production method of the present invention, thereby providing easily an optoelectronic composite module.

### Example

The present invention will be described in more detail with reference to examples below, but the present invention is not limited to the examples.

The present invention will be described in more detail with reference to examples below, but the present invention is not limited to the examples.

### (1) Production of Optical Waveguide

### Production of Resin Film for Forming Clad Layer

48 parts by mass of a phenoxy resin (Phenotohto YP-70, a trade name, produced by Tohto Kasei Co., Ltd.) as the base polymer (A), 50 parts by mass of an alicyclic diepoxy carboxylate (molecular weight: 252, KRM-2110, a trade name, produced by Asahi Denka Kogyo Co., Ltd.) as the photopolymerizable compound (B), 2 parts by mass of triphenylsulfonium hexafluoroantimonate salt (SP-170, a trade name, produced by Asahi Denka Kogyo Co., Ltd.) as the photopolymerization initiator (C), and 40 parts by mass of propylene glycol monomethyl ether acetate as an organic solvent were weighed in a wide-mouth resin bottle, and were stirred with a mechanical stirrer, a shaft and a propeller under conditions of a temperature of 25° C. and a rotation number of 400 rpm for 6 hours, thereby preparing a resin varnish A for forming a clad layer. Thereafter, the varnish was filtered under pressure with a Polyflon filter (PF020, a trade name, produced by Advantec Toyo Kaisha, Ltd.) having a pore diameter of 2 μm under conditions of a temperature of 25° C. and a pressure of 0.4 MPa, and then defoamed with a vacuum pump and a bell jar under conditions of a depressurization degree of 50 mmHg for 15 minutes.

The resin varnish A for forming a clad layer obtained above was coated on a releasing PET film (thickness: 25 μm, Purex A31, a trade name, produced by Teijin DuPont Films Japan, Ltd.) with a coating machine (Multicoater TM-MC, produced by Hirano Tecseed Co., Ltd.), and dried at 80° C. for 10 minutes and then at 100° C. for 10 minutes, to which a releasing PET film (thickness: 25 μm, Purex A31, a trade name, produced by Teijin DuPont Films Japan, Ltd.) as a protective film was adhered with the releasing surface directed to the resin, thereby providing a resin film for forming a clad layer. The thickness of the resin layer can be arbitrarily controlled by adjusting the gap of the coating machine. In this example, the thickness was controlled to make a thickness after curing of 25 μm for the lower clad layer and 70 μm for the upper clad layer.

### Production of Resin Film for Forming Core Layer

A resin varnish B for forming a core layer was prepared in the same manner under the same conditions as in the aforementioned production example except that 26 parts by mass of a phenoxy resin (Phenotohto YP-70, a trade name, produced by Tohto Kasei Co., Ltd.) as the base polymer (A), 36 parts by mass of 9,9-bis(4-(2-acryloyloxyethoxy)phenyl)fluorene (A-BPEF, a trade name, produced by Shin-Nakamura Chemical Co., Ltd.) and 36 parts by mass of a bisphenol A type epoxy acrylate (EA-1020, a trade name, produced by Shin-Nakamura Chemical Co., Ltd.) as the photopolymerizable compound (B), 1 part by mass of bis(2,4,6-trimethylbenzoyl)phenylphosphine oxide (Irgacure 819, a trade name, produced by Ciba Specialty Chemicals Co., Ltd.) and 1 part by mass of 1-(4-(2-hydroxyethoxy)phenyl)-2-hydroxy-2-methyl-1-propan-1-one (Irgacure 2959, a trade name, produced by Ciba Specialty Chemicals Co., Ltd.) as the photopolymerization initiator (C), and 40 parts by mass of propylene glycol monomethyl ether acetate as an organic solvent were used. Thereafter, the varnish was filtered in the same manner under the same conditions as in the aforementioned production example.

The resin varnish B for forming a core layer obtained above was coated on a non-treated surface of a PET film (thickness: 16 μm, (Cosmoshine A1517″, a trade name, produced by Toyobo Co., Ltd.) and dried in the same manner as in the aforementioned production example, to which a releasing PET film (thickness: 25 μm, Purex A31, a trade name, produced by Teijin DuPont Films Japan, Ltd.) as a protective film was adhered with the releasing surface directed to the resin, thereby providing a resin film for forming a core layer. In this example, the gap of the coating machine was controlled to make a thickness after curing of 50 μm.

### (2) Production of Circuit Board

The method for producing a circuit board as a composite with an optical waveguide will be described with reference to FIG. 2 sub number 2.

### Lamination of Second Support 1-8 and First Substrate 1-1

A copper foil (thickness: 18 μm, 3EC-VLP, a trade name, produced by Mitsui Mining And Smelting Co., Ltd.) of 140 mm square as the second releasing layer 1-6 was placed on the center of a polyimide surface of a polyimide having a copper foil on one surface (thickness of copper foil: 5 g m, thickness of polyimide: 12.5 μm, “Upisel N”, a trade name, produced by UBE-NITTO KASEI CO., LTD.) of 150 mm square as the first substrate 1-1, and thereon, a prepreg (thickness: 40 μm, GEA-679FG, a trade name, produced by Hitachi Chemical Co., Ltd.) of 150 mm square as the second adhesive layer 1-7 and a copper laminated plate (thickness: 0.6 mm, MCL-E679F, produced by Hitachi Chemical Co., Ltd.) as the second support 1-8 were constructed. The assembly was vacuumed to 4 kPa or less and then laminated under heating at under conditions of a pressure of 2.5 MPa, a temperature of 180° C. and a pressing time of 1 hour, thereby laminating the first substrate 1-1 on the second substrate 1-8 (see FIG. 2(a)).

### Formation of Circuit by Subtractive Method

Thereafter, a photosensitive dry film resist (thickness: 25 μm, Photec, a trade name, produced by Hitachi Chemical Co., Ltd.) was adhered to the copper foil surface of the polyimide having a copper foil on one surface with a roll laminator (HLM-1500, produced by Hitachi Chemical Technoplant Co., Ltd.) under conditions of a pressure of 0.4 MPa, a temperature of 50° C. and a laminating speed of 0.2 m/min. The assembly was then irradiated from the side of the photosensitive dry film resist with an ultraviolet ray (wavelength: 365 nm) in 120 mJ/cm² through a negative photomask having a width of 50 μm with an ultraviolet ray exposing machine (EXM-1172, produced by Oac Manufacturing Co., Ltd.), and the unexposed part of the photosensitive dry film resist was removed with a diluted solution of sodium carbonate having a concentration of from 0.1 to 5% by mass at 35° C. Thereafter, the copper foil exposed through the removal of the photosensitive dry film resist was removed by etching using ferric chloride solution, and the photosensitive dry film resist on the exposed part was removed with a sodium hydroxide aqueous solution having a concentration of from 1 to 10% by mass at 35° C. Consequently, the second support 1-8 having the first substrate 1-1 having formed on one surface thereof the circuit 1-9 was obtained (see FIG. 1(b)).

### Lamination of First Support 1-4

As the first releasing sheet 1-2 of the second support 1-8 having the first substrate 1-1 having formed on one surface thereof the circuit 1-9 obtained above, a releasing sheet (thickness: 30 μm, Aflex, a trade name, produced by Asahi Glass Co., Ltd.) of 130 mm square was plated on the center of the surface of the circuit 1-9, and after vacuuming to 500 Pa or less, a build-up material (thickness: 40 μm, AS-Z II, a trade name, produced by Hitachi Chemical Co., Ltd.) of 150 mm square was adhered thereon by pressing under heat under conditions of a pressure of 0.4 MPa, a temperature of 110° C. and a pressing time of 30 seconds. Thereafter, a copper laminated plate (thickness: 0.6 mm, MCL-E679F, produced by Hitachi Chemical Co., Ltd.) as the first support 1-4 was further constructed on the surface of the build-up material and adhered by pressing under heat under the same conditions as above, thereby laminating the first support 1-4 (see FIG. 2(c)).

### Separation of Second Support

The product thus formed above was cut out by 12 mm for each edges thereof, and only the second support 1-8 was separated (see FIG. 1(d)). Consequently, a polyimide having a circuit on one surface thereof laminated on the first support 1-4 was obtained.

### Production of Adhesive Film

The adhesive film disclosed in Example 1 of PCT/JP2008/05465 was produced. Specifically, cyclohexanone was added to a composition containing 55 parts by mass of YDCN-703 (a trade name, produced by Tohto Kasei Co., Ltd., a cresol novolac type epoxy resin, epoxy equivalent: 210) as the epoxy resin (a), 45 parts by mass of Milex XLC-LL (a trade name, produced by Mitsui Chemicals, Inc., a phenol resin, hydroxyl group equivalent: 175, water absorption degree: 1.8% by mass, weight reduction rate under heating to 350° C.: 4%) as the curing agent (b), 1.7 parts by mass of NUCA-189 (a trade name, produced by Nippon Unicar Co., Ltd., γ-mercaptopropyltrimethoxysilane) and 3.2 parts by mass of NUCA-1160 (a trade name, produced by Nippon Unicar Co., Ltd., γ-ureidopropyltriethoxysilane) as the silane coupling agent, and 32 parts by mass of Aerosil R972 (a trade name, produced by Nippon Aerosil Co., Ltd., a filler having an organic group, such as a methyl group, on the surface thereof, obtained by coating dimethyldichlorosilane on the surface of silica and hydrolyzed in a reactor at 400° C., silica, average particle diameter: 0.016 μm) as the filler (d), and they were mixed by stirring and kneaded with a bead mill for 90 minutes. 280 parts by mass of acrylic rubber HTR-860P-3 (a trade name, produced by Nagase Chemtex Corporation, weight average molecular weight: 800,000) containing 3% by mass of glycidyl acrylate or glycidyl methacrylate as the polymer compound (c) and 0.5 part by mass of Curezol 2PZ-CN (a trade name, produced by Shikoku Chemicals Corporation, 1-cyanoethyl-2-phenylimidazole) as a curing promoter (e) were added thereto, and they were mixed by stirring and then deaerated in vacuum. The resulting adhesive varnish was coated on a polyethylene terephthalate (PET) film (Purex A31) having a thickness of 75 μm and having been subjected to a releasing treatment, and dried under heat to 140° C. for 5 minutes, thereby providing a coated film having a thickness of 10 μm. Subsequently, a polyethylene terephthalate (PET) film (Purex A31) having a thickness of 25 μM and having been subjected to a releasing treatment as the second protective film was adhered with the releasing surface directed to the resin, thereby providing an adhesive film.

Production of Circuit Board as Composite with Optical Waveguide

The releasing PET film (Purex A31) as the protective film of the adhesive film obtained above was released, and the adhesive film was laminated as the adhesive layer 1-10 on the polyimide surface of the first substrate 1-1 with a roll laminator (HLM-1500, produced by Hitachi Chemical Technoplant Co., Ltd.) under conditions of a pressure of 0.4 MPa, a temperature of 50° C. and a laminating speed of 0.2 m/min. The assembly was then irradiated from the side of the adhesive film with an ultraviolet ray (wavelength: 365 nm) in 1 J/cm² with an ultraviolet ray exposing machine (EXM-1172, produced by Oac Manufacturing Co., Ltd.), and the releasing PET film (Purex A31) as the second protective film of the adhesive film was released.

Subsequently, the releasing PET film (Purex A31) as the protective film of the resin film for forming a clad layer was released, and the resin film for forming a clad layer was adhered to the adhesive film of the first substrate 1-1 obtained above under the same lamination conditions as above. The lower clad layer 1-11 was irradiated with an ultraviolet ray (wavelength: 365 nm) in 1.5 J/cm² with an ultraviolet ray exposing machine (EXM-1172, produced by Oac Manufacturing Co., Ltd.) and then subjected to a heat treatment at 80° C. for 10 minutes, thereby forming the lower clad layer 1-11.

The resin film for forming a core layer was then laminated on the lower clad layer 1-11 under the same lamination conditions as above, thereby forming the core layer.

The core layer was irradiated with an ultraviolet ray (wavelength: 365 nm) in 0.8 mJ/cm² with the ultraviolet ray exposing machine through a negative photomask having a width of 50 μm and subjected to post-exposure heating at 80° C. for 5 minutes. Thereafter, the PET film as the support film was released, and the core pattern 1-12 was developed with a developer solution (propylene glycol monomethyl ether acetate/N,N-dimethylacetamide=7/3 by mass). Subsequently, the assembly was rinsed with a rinsing liquid (isopropanol) and dried under heating to 100° C. for 10 minutes.

The assembly was vacuumed to 500 Pa or less and then adhered under heat under the conditions of a pressure of 0.4 MPa, a temperature of 50° C. and a pressing time of 30 seconds with a vacuum pressure laminator (MVLP-500, produced by Meiki Co., Ltd.) as a flat plate laminator, thereby laminating the resin film for forming the clad layer as the upper clad layer 1-13.

Furthermore, the upper clad layer was cured by irradiation with an ultraviolet ray (wavelength: 365 nm) in 3 J/cm² and then subjected to a heat treatment at 160° C. for 1 hour, thereby curing the upper clad layer for producing the optical waveguide 1-15 (see FIG. 2(e)-2).

A 45° mirror was formed on the side of the upper clad layer 1-13 of the resulting optical waveguide 1-15 having the first substrate 1-1 and the circuit 1-9 with a dicing saw (DAC552, produced by Disco Corporation), thereby providing a circuit board as a composite with an optical waveguide.

### Separation of First Support

The first substrate 1-1 having the first support 1-3 thus produced above was cut out by 10 mm for each edges thereof, and the first support 1-3 was separated (see FIG. 2(f)-2).

The resulting circuit board as a composite with the optical waveguide was measured for a deviation amount from the design value of the circuit on the outermost layer of the first substrate 1-1 in the following manner. The results are shown in Table 1.

### Measurement Method of Deviation Amount

The measurement was performed before separating the first support 1-3. The 30 alignment markers disposed in the circuit in the outermost layer of the first substrate 1-1 were measured for X-coordinate and the Y-coordinate. By using the alignment markers on the four corners, the intersecting point of the lines each connecting the diagonal alignment markers was designated as a scaling factor origin (hereinafter abbreviated as an S/F origin), and the average value of the values obtained by dividing the distances between the four alignment markers by the designed value was designated as the scaling factor (hereinafter abbreviated as S/F). For example, for the designed alignment markers on the four corners A, 8, C and D and the measured alignment markers on the four corners A′, B′, C′ and D′, in the case where A (or A′) and C (or C′), or B (or B′) and D (or D′) are each positioned diagonally, the intersecting point of the line connecting A and C and the line connecting B and D is the S/F origin of the designed value, and the intersecting point of the line connecting A′ and C′ and the line connecting B′ and D′ is the S/F origin of the measured value. The average value of (A′-B′ distance)/(A-B distance), (B′-C′ distance)/(B-C distance), (C′-D′ distance)/(C-D distance) and (D′-A′ distance)/(D-A distance) is the S/F. Thereafter, the X-coordinate and the Y-coordinate thus measured were converted from the S/F origin of the measured value to the S/F origin of the designed value, and further multiplied by the S/F of the design value, and the deviation amounts of the designed values with respect to the X-coordinate and the Y-coordinate were calculated. The deviation amount corresponds to the minimum deviation amount upon aligning with the optical waveguide 1-15 and the other circuits.

The contraction degree of the optical waveguide was calculated by (1−S/F)×100 (%) as determined above.

In Table 1, X means the deviation amount in the crosswise direction, Y means the deviation amount in the lengthwise direction, and XY means the distance of deviation. According to the results in Table 1, the maximum deviation amount was 7.5 μm, and the contraction degree was 0.04%.

TABLE 1

| | Deviation amount (μm) | | |
|---|---|---|---|
| | X | Y | XY |
| Minimum value | −3.5 | −1.5 | 0.6 |
| Maximum value | 6.6 | 5.2 | 7.5 |
| Average | −0.9 | 1.3 | 2.3 |

After separating the second support 1-8, the first substrate 1-1 was cut with a dicing saw, and the relief of the polyimide substrate of the first substrate 1-1 on the opposite side to the first support was observed from the cross sectional surface. The measurement method therefor will be shown below.

### Measurement Method of Relief

As shown in FIG. 5, the difference in height between the substrate 1-101 of the releasing surface side of the portion of the first substrate 1-1 where the circuit was present and the substrate 1-102 of the releasing surface side of the portion of the first substrate 1-1 where the circuit was not present was measured. As a result, the difference was 0.5 μm.

Furthermore, the core width of the optical waveguide had a fluctuation between 49.9 μm as the minimum value and 50.2 μm as the maximum value.

### Example 2

In Example 1, the first substrate 1-1 was formed by using a polyimide substrate having a copper foil on one surface thereof and performing formation of circuit after separating the second support 1-8 according to the semi-additive method under the conditions disclosed in Example 2 of JP-A-2006-93199 shown below.

### Conditions for Semi-Additive Method

Equipment: plasma reactor, Model PR-501A (a trade name, produced by Yamato Scientific Co., Ltd.)
Etching depth: 1.5 μm

### Power: 300 W

Gas used and flow rate: CF₄: 20 SCCM, oxygen: 50 SCCM
Substrate temperature: room temperature (25° C.)
Vacuum degree: 100 Pa
Etching rate: 300 nm/min

In the step before laminating the first support 1-1, an optical waveguide 1-15 was formed in the same manner as in Example 1. Furthermore, a polyimide substrate having on one surface thereof a circuit formed in advance by the aforementioned subtractive method is adhered to the polyimide surface with the adhesion film obtained above, and then the surface of the adhesion film was adhered to the optical waveguide 1-15. The other procedures were performed in the same manner as in Example 1 (FIG. 2(f)-3).

The resulting circuit board as a composite with the optical waveguide was measured for the deviation amount of the position of the circuit in the outermost layer of the first substrate 1-1 in the same manner as in Example 1. The results are shown in Table 2.

According to the results in Table 2, the maximum deviation amount was 7.2 μm, and the contraction degree was 0.05%.

TABLE 2

| | Deviation amount (μm) | | |
|---|---|---|---|
| | X | Y | XY |
| Minimum value | −6.7 | −4.8 | 0.3 |
| Maximum value | 3.6 | 5.3 | 7.2 |
| Average | −1.4 | 0.3 | 3.6 |

The difference in height between the substrate 1-101 of the releasing surface side of the portion of the first substrate 1-1 where the circuit was present and the substrate 1-102 of the releasing surface side of the portion of the first substrate 1-1 where the circuit was not present was measured in the same manner as in Example 1. As a result, the difference was 0.5 μm.

Furthermore, the core width of the optical waveguide had a fluctuation between 50.0 μm as the minimum value and 50.3 μm as the maximum value.

### Example 3

In Example 1, instead of the optical waveguide as the second substrate 1-5, a prepreg (thickness: 40 μm, GEA-679FG, a trade name, produced by Hitachi Chemical Co., Ltd.) and a copper foil (thickness: 18 μm, 3EC-VLP, a trade name, produced by Mitsui Mining And Smelting Co., Ltd.) were formed sequentially on the surface of the first substrate 1-1 having the circuit formed thereof, and after vacuuming to 4 kPa or less, they are laminated by heating under conditions of a pressure of 2.5 MPa, a temperature of 180° C. and a pressing time of 1 hour. Furthermore, a circuit was formed with the copper foil by the subtractive method (see FIG. 2(f)-1).

The resulting circuit board was measured for the deviation amount of the position of the circuit in the outermost layer of the first substrate 1-1 in the same manner as in Example 1. The results are shown in Table 3.

According to the results in Table 3, the maximum deviation amount was 9.6 μm, and the contraction degree was 0.05%.

TABLE 3

| | Deviation amount (μm) | | |
|---|---|---|---|
| | X | Y | XY |
| Minimum value | −8.2 | −8.3 | 1.4 |
| Maximum value | 8.6 | 9.6 | 9.6 |
| Average | 0.6 | −1.9 | 5.6 |

### Example 4

In Example 3, an optical waveguide 1-15 was formed on the surface of the second substrate 1-5 having the circuit formed thereon in the same manner as in Example 1 (see FIG. 2(f)-4).

The difference in height between the substrate 1-101 of the releasing surface side of the portion of the first substrate 1-1 where the circuit was present and the substrate 1-102 of the releasing surface side of the portion of the first substrate 1-1 where the circuit was not present was measured in the same manner as in Example 1. As a result, the difference was 1.5 μm.

Furthermore, the core width of the optical waveguide had a fluctuation between 50.1 μm as the minimum value and 50.2 μm as the maximum value.

### Example 5

In Example 1, the circuit 1-9 was formed as the step A, and then an optical waveguide 1-15 and a polyimide substrate (a substrate X16) were formed on the surface where the circuit 1-9 was formed under the same conditions as in Example 2, thereby forming the first substrate 1-1. The subsequent procedures as the step B were performed in the same manner as in Example 3 except that the second substrate 1-5 was not formed (see FIG. 3).

The difference in height between the substrate 1-101 of the releasing surface side of the portion of the first substrate 1-1 where the circuit was present and the substrate 1-102 of the releasing surface side of the portion of the first substrate 1-1 where the circuit was not present was measured in the same manner as in Example 1. As a result, the difference was 1.0 μm.

Furthermore, the core width of the optical waveguide had a fluctuation between 49.7 μm as the minimum value and 50.3 μm as the maximum value.

### Comparative Example 1

The same procedures as in Example 1 were performed except that the first releasing layer 1-2, the first adhesive layer 1-3, the first support 1-4, the second releasing layer 1-6, the second adhesive layer 1-7 and the second support 1-8 were not used, and the formation of the circuit of the polyimide substrate was performed by the subtractive method.

The resulting circuit board as a composite with the optical waveguide was measured for the deviation amount of the position of the circuit in the outermost layer of the first substrate 1-1 in the same manner as in Example 1. The results are shown in Table 4.

According to the results in Table 4, the maximum deviation amount was 32.3 μm, and the contraction degree was 0.15%.

TABLE 4

| | Deviation amount (μm) | | |
|---|---|---|---|
| | X | Y | XY |
| Minimum value | −19.8 | −22.2 | 5.9 |
| Maximum value | 30.1 | 27.0 | 32.3 |
| Average | 13.5 | 3.2 | 17.9 |

The difference in height between the substrate 1-101 of the releasing surface side of the portion of the first substrate 1-1 where the circuit was present and the substrate 1-102 of the releasing surface side of the portion of the first substrate 1-1 where the circuit was not present was measured in the same manner as in Example 1. As a result, the difference was 3.0 μm. Furthermore, the core width of the optical waveguide had a fluctuation between 48 μm as the minimum value and 53 μm as the maximum value.

### Example 6

### Production of Optoelectronic Composite Member

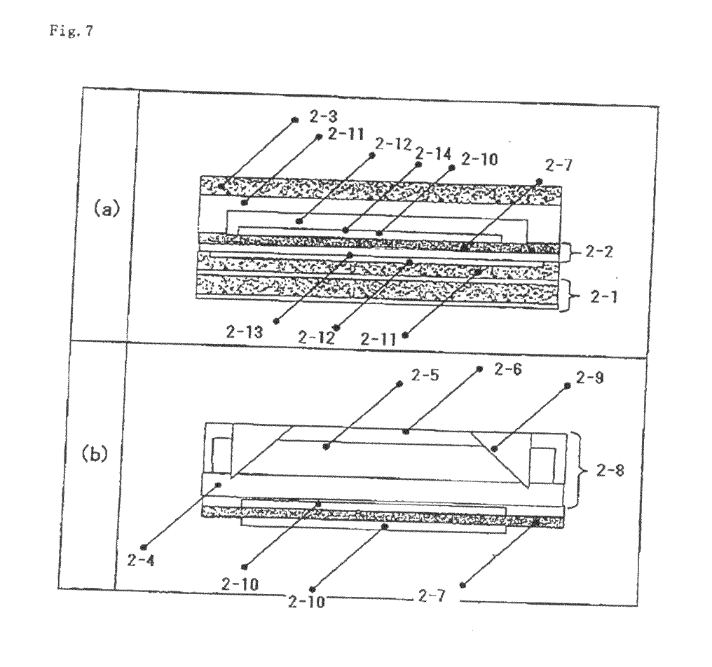

The production method of an optoelectronic composite member will be described with reference to FIGS. 6 and 7 below.

### Lamination of Lower Support

A copper foil (thickness: 18 μm, 3EC-VLP, a trade name, produced by Mitsui Mining And Smelting Co., Ltd.) of 140 mm square was placed on the center of a copper foil surface of a polyimide having copper foils on both surfaces (thickness of copper foil: 5 μm, thickness of polyimide: 12.5 μm, “Upisel N”, a trade name, produced by UBE-NITTO KASEI CO., LTD.) of 150 mm square, and thereon, a prepreg (thickness: 40 μm, GEA-679FG, a trade name, produced by Hitachi Chemical Co., Ltd.) of 150 mm square and a copper laminated plate (thickness: 0.6 mm, MCL-E679F, produced by Hitachi Chemical Co., Ltd.) were constructed. The assembly was vacuumed to 4 kPa or less and then laminated under heating at under conditions of a pressure of 2.5 MPa, a temperature of 180° C. and a pressing time of 1 hour, thereby laminating the electric wiring 2-2 to the lower support 2-1 (see FIG. 6(a)). Thereafter, a circuit was formed on one surface of the polyimide having copper foils on both surfaces by the subtractive method. Consequently, the lower support 2-1 having the electric circuit board 2-2 having an electric wiring on one surface thereof was obtained (see FIG. 6(b)).

### Lamination of Upper Support

A releasing sheet (thickness: 30 μm, Aflex, a trade name, produced by Asahi Glass Co., Ltd.) of 130 mm square was plated on the center of the electric wiring surface of the lower support 2-1 having the electric circuit board 2-2 formed above, and thereon, after vacuuming to 500 Pa or less, a build-up material (thickness: 40 μm, AS-Z II, a trade name, produced by Hitachi Chemical Co., Ltd.) of 150 mm square was adhered thereon by pressing under heat under conditions of a pressure of 0.4 MPa, a temperature of 110° C. and a pressing time of 30 seconds. Thereafter, a copper laminated plate (thickness: 0.6 mm, MCL-E679F, produced by Hitachi Chemical Co., Ltd.) was further constructed on the surface of the build-up material and adhered by pressing under heat under the same conditions as above, thereby laminating the upper support 2-3 (see FIG. 6(c)). The detailed layer structure is shown in FIG. 7(a).

### Separation of Lower Support

The product thus formed above was cut out by 12 mm for each edges thereof, and only the lower support 2-1 was separated (see FIG. 6(d)). Thereafter, a circuit was formed on the copper foil surface of the polyimide having a copper foil as the released surface, by the subtractive method. Consequently, a polyimide having circuits on both surfaces thereof laminated on the upper support 2-3 was obtained.

### Production of Optoelectronic Composite Member

The releasing PET film (Purex A31) as the protective film of the adhesive film obtained in Example 1 was released, and the adhesive film was laminated on the polyimide surface of the lower support 2-1 with a roll laminator (HLM-1500, produced by Hitachi Chemical Technoplant Co., Ltd.) under conditions of a pressure of 0.4 MPa, a temperature of 50° C. and a laminating speed of 0.2 m/min. The assembly was then irradiated from the side of the adhesive film with an ultraviolet ray (wavelength: 365 nm) in 1 J/cm² with an ultraviolet ray exposing machine (EXM-1172, produced by Oac Manufacturing Co., Ltd.), and the releasing PET film (Purex A31) as the second protective film of the adhesive film was released.

Subsequently, the releasing PET film (Purex A31) as the protective film of the resin film for forming a lower clad layer was released, and the resin film for forming a lower clad layer was adhered to the adhesive film of the lower support 2-1 obtained above under the same lamination conditions as above. The lower clad layer 2-4 was irradiated with an ultraviolet ray (wavelength: 365 nm) in 1.5 J/cm² with an ultraviolet ray exposing machine (EXM-1172, produced by Oac Manufacturing Co., Ltd.) and then subjected to a heat treatment at 80° C. for 10 minutes, thereby forming the lower clad layer 2-4.

The resin film for forming a core layer was then laminated on the lower clad layer 4 under the same lamination conditions as above, thereby forming the core layer.

The core layer was irradiated with an ultraviolet ray (wavelength: 365 nm) in 0.8 J/cm² with the ultraviolet ray exposing machine through a negative photomask having a width of 50 μm and subjected to post-exposure heating at 80° C. for 5 minutes. Thereafter, the PET film as the support film was released, and the core pattern 2-5 was developed with a developer solution (propylene glycol monomethyl ether acetate/N,N-dimethylacetamide=7/3 by mass). Subsequently, the assembly was rinsed with a rinsing liquid (isopropanol) and dried under heating to 100° C. for 10 minutes.

The assembly was vacuumed to 500 Pa or less and then adhered under heat under the conditions of a pressure of 0.4 MPa, a temperature of 50° C. and a pressing time of 30 seconds with a vacuum pressure laminator (MVLP-500, produced by Meiki Co., Ltd.) as a flat plate laminator, thereby laminating the resin film for forming an upper clad layer as the upper clad layer 2-6.

Furthermore, the upper clad layer was cured by irradiation with an ultraviolet ray (wavelength: 365 nm) in 3 J/cm² and then subjected to a heat treatment at 160° C. for 1 hour, thereby curing the upper clad layer for producing the optical waveguide 2-8 (see FIG. 6(e)).

A 45° mirror was formed on the side of the upper clad layer 2-6 of the resulting optical waveguide 2-8 having the electric circuit board 2-2 with a dicing saw (DAC552, produced by Disco Corporation), thereby providing an optoelectronic composite member (see FIG. 6(f)).

Separation of Upper Support

The electric circuit board 2-2 having the upper support 2-3 thus produced above was cut out by 10 mm for each edges thereof, and the upper support 2-3 was separated (see FIGS. 6(g) and 7(b)).

The resulting optoelectronic composite member was evaluated for distortion occurring in the optical waveguide as the deviation amount from the design value of the position of the core of the optical waveguide 2-8. The results are shown in Table 5.

### Measurement Method of Deviation Amount

The measurement was performed before separating the upper support 2-3. The 30 alignment markers disposed within a 125 mm square of the optical waveguide 2-8 were measured for X-coordinate and the Y-coordinate, and the deviation amount was calculated in the same manner as in Example 1.

TABLE 5

| | Deviation amount (μm) | | |
|---|---|---|---|
| | X | Y | XY |
| Minimum value | −3.5 | −1.5 | 0.6 |
| Maximum value | 6.6 | 5.2 | 7.5 |
| Average | −0.9 | 1.3 | 2.3 |

### Example 7

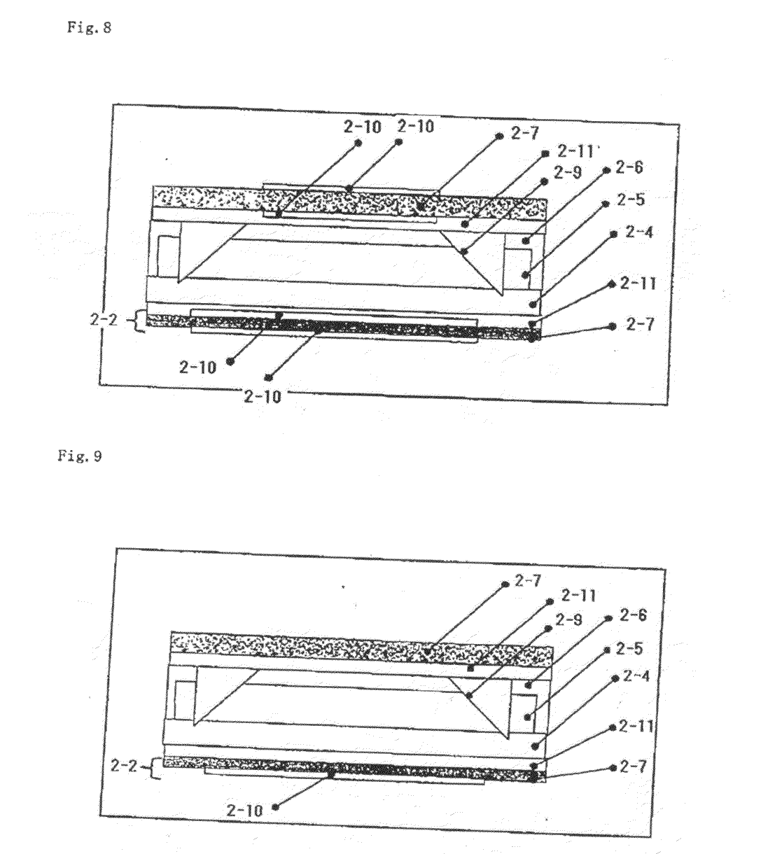

In Example 6, after separating the upper support 2-3, an FR-4 plate having a thickness of 0.6 mm having a circuit formed by the subtractive method was laminated with the adhesive produced in Example 1 and adhered to the FR-4 plate, and then the adhesive surface was vacuumed to 500 Pa or less with a vacuum pressure laminator (MVLP-500, produced by Meiki Co., Ltd.), and then press adhered by heating to the optical waveguide 2-8 from the side of the upper clad under conditions of a pressure of 0.4 MPa, a temperature of 100° C. and a pressing time of 30 seconds. The other procedures were performed in the same manner, thereby producing an optoelectronic composite member (see FIG. 8).

The resulting optoelectronic composite member was measured for the deviation amount of the position of the core in the optical waveguide 2-8 in the same manner as in Example 6. The results are shown in Table 6.

According to the results in Table 6, the maximum deviation amount was 6.9 μm, and the contraction degree was 0.05%.

TABLE 6

| | Deviation amount (μm) | | |
|---|---|---|---|
| | X | Y | XY |
| Minimum value | −2.9 | −3.2 | 0.0 |
| Maximum value | 5.8 | 6.0 | 6.9 |
| Average | 2.7 | 3.2 | 3.9 |

### Example 8

In Example 6, a polyimide having a copper foil on one surface thereof (thickness of copper foil: 5 μm, thickness of polyimide: 12.5 μm, “Upisel N”, a trade name, produced by UBE-NITTO KASEI CO., LTD.) was used instead of the polyimide having copper foils on both surfaces thereof, and the polyimide surface and the lower support 2-1 were adhered to each other with Kapton double-face adhesive tape with one surface having slight tackiness (product number: 4309, produced by Sumitomo 3M, Ltd.). The surface having strong tackiness was directed to the lower support 2-1, and the surface having slight tackiness was directed to the polyimide surface. After separating the upper support 2-3, an FR-4 plate having a thickness of 0.6 mm having been etched on both surfaces thereof was laminated on the FR-4 plate from the upper clad with the adhesive produced in the production of the adhesive film, under the above conditions and then the adhesive surface was vacuumed to 500 Pa or less with a vacuum pressure laminator (MVLP-500, produced by Meiki Co., Ltd.), and then press adhered by heating to the optical waveguide 2-8 from the side of the upper clad under conditions of a pressure of 0.4 MPa, a temperature of 100° C. and a pressing time of 30 seconds. The other procedures were performed in the same manner, thereby producing an optoelectronic composite member (see FIG. 9).

The resulting optoelectronic composite member was measured for the deviation amount of the position of the core in the optical waveguide 2-8 in the same manner as in Example 6. The results are shown in Table 7.

According to the results in Table 7, the maximum deviation amount was 7 μm, and the contraction degree was 0.05%.

TABLE 7

| | Deviation amount (μm) | | |
|---|---|---|---|
| | X | Y | XY |
| Minimum value | −3.5 | −6.4 | 0.2 |
| Maximum value | 6.5 | 6.1 | 7.0 |
| Average | 1.1 | −0.1 | 3.2 |

### Example 9

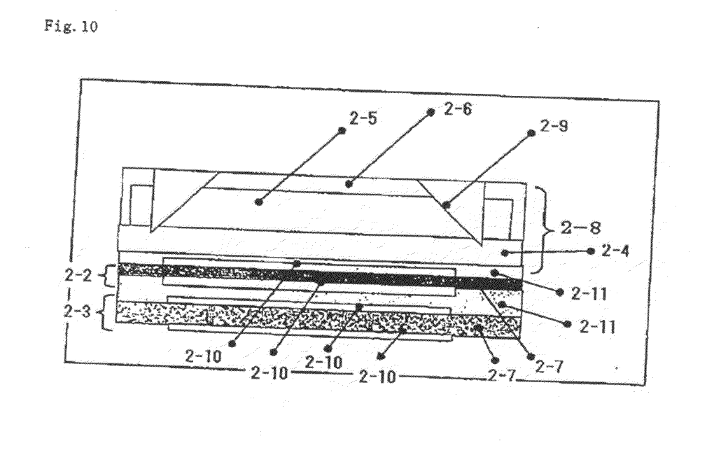

An optoelectronic composite member was produced in the same manner as in Example 6 except that the upper support 2-3 was a copper laminated plate (thickness: 0.6 mm, MCL-E679FB, produced by Hitachi Chemical Co., Ltd.) having circuits formed by the subtractive method on both surfaces thereof, a build-up material (thickness: 40 μm, AS-Z II, a trade name, produced by Hitachi Chemical Co., Ltd.) of 150 mm square was press adhered on the surface having the circuit by heating under the aforementioned conditions and then adhered to the electric circuit board 2-2 under the aforementioned conditions, and the upper support 2-3 was not separated (see FIG. 10).

The resulting optoelectronic composite member was measured for the deviation amount of the position of the core in the optical waveguide 2-8 in the same manner as in Example 6. The results are shown in Table 8.

According to the results in Table 4, the maximum deviation amount was 5.7 μm, and the contraction degree was 0.05%.

TABLE 8

| | Deviation amount (μm) | | |
|---|---|---|---|
| | X | Y | XY |
| Minimum value | −3.2 | −1.4 | 1.1 |
| Maximum value | 3.9 | 5.3 | 5.7 |
| Average | −0.2 | 1.1 | 2.9 |

### Example 10

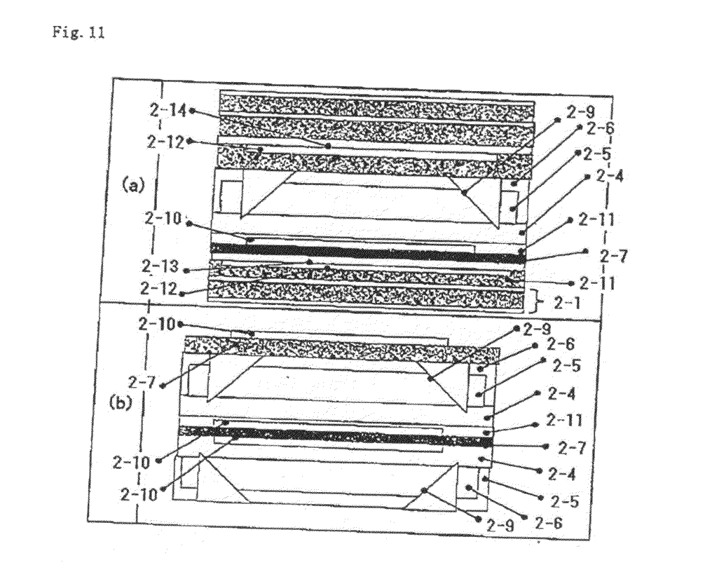

The lower support 2-1 and the electric circuit board 2-2 were laminated in the same manner as in Example 6, and after forming a circuit, the optical waveguide 2-8 was formed on the electric circuit board 2-2 under the same conditions as in Example 6. Thereafter, the mirror was formed under the aforementioned conditions. As a step of laminating the upper support 2-1, a prepreg (thickness: 40 μm, GEA-679FG, a trade name, produced by Hitachi Chemical Co., Ltd.) of 150 mm square, a copper foil (thickness: 18 g m, 3EC-VLP, a trade name, produced by Mitsui Mining And Smelting Co., Ltd.) of 130 mm square, a copper foil (thickness: 18 μm, 3EC-VLP, a trade name, produced by Mitsui Mining And Smelting Co., Ltd.) of 150 mm square, a prepreg (thickness: 40 μm, GEA-679FG, a trade name, produced by Hitachi Chemical Co., Ltd.) of 150 mm square, and a copper laminated plate (thickness: 0.6 mm, MCL-E679F, produced by Hitachi Chemical Co., Ltd.) were constructed sequentially, and after vacuuming to 4 kPa or less, they are laminated by heating under conditions of a pressure of 2.5 MPa, a temperature of 180° C. and a pressing time of 1 hour, thereby producing the lower support 2-1 having an electric wiring with the optical waveguide 2-8 disposed as an internal layer. The detailed layer structure is shown in FIG. 11(a). The product work was cut by 12 mm for each edge thereof, and after separating the lower support 2-1, a circuit was formed on the copper foil surface of the polyimide having a copper foil as the released surface, by the subtractive method.

After forming the optical waveguide 8 on the surface having the circuit formed on the copper foil surface of the polyimide having a copper foil in the same manner as in Example 6, the product work was cut by 10 mm for each edge thereof, and the upper support 2-3 was separated. A circuit was formed on the copper foil of 140 mm square as the released surface after separating the upper support 2-3, by the subtractive method. A mirror part was formed in the optical waveguide 2-8 as the outermost layer under the aforementioned conditions, and the product work was cut by 10 mm for each edge thereof, thereby providing an optoelectronic composite member. The layer structure is shown in FIG. 11(b).

After forming the optical waveguide 2-8 as the outer layer, the resulting optoelectronic composite member was measured for the deviation amount of the position of the core in the optical waveguide 2-8 in the same manner as in Example 6. The results of the optical waveguide 2-8 as the inner layer are shown in Table 9, and the results of the optical waveguide 2-8 as the outer layer are shown in Table 10.

According to the results in Table 9, the maximum deviation amount was 7.2 μm, and the contraction degree was 0.08%. According to the results in Table 10, the maximum deviation amount was 11.2 μm, and the contraction degree was 0.05%.

TABLE 9

| | Deviation amount (μm) | | |
|---|---|---|---|
| | X | Y | XY |
| Minimum value | −1.3 | −1.0 | 0.9 |
| Maximum value | 3.4 | 4.2 | 7.2 |
| Average | 1.8 | 0.5 | 3.3 |

TABLE 10

| | Deviation amount (μm) | | |
|---|---|---|---|
| | X | Y | XY |
| Minimum value | −9.8 | −8.5 | 0.9 |
| Maximum value | 5.2 | 10.2 | 11.2 |
| Average | 1.5 | 3.2 | 5.5 |

### Comparative Example 2

An optoelectronic composite member was produced in the same manner as in Example 6 except that adhesion of the upper support 2-3 and the lower support 2-1 was not performed.

The resulting optoelectronic composite member was measured for the deviation amount of the position of the core in the optical waveguide 2-8 in the same manner as in Example 6. The results are shown in Table 11.

According to the results in Table 11, the maximum deviation amount was 75 μm, and the contraction degree was 1.0%.

TABLE 11

| | Deviation amount (μm) | | |
|---|---|---|---|
| | X | Y | XY |
| Minimum value | −19.2 | −52.1 | 15.6 |
| Maximum value | 52.7 | 61.4 | 75.0 |
| Average | 12.1 | −8.2 | 43.7 |

### Example 11

An optoelectronic composite substrate was produced by performing the steps in the following manner.

### (1) Production of Tacky Adhesive Sheet

100 parts by mass of HTR-860P-3 (a trade name, produced by Nagase Chemtex Corporation, glycidyl group-containing acrylic rubber, weight average molecular weight: 800,000, Tg: −7° C.) as the high molecular weight component (a), 5.4 parts by mass of YDCN-703 (a trade name, produced by Tohto Kasei Co., Ltd., an o-cresol novolac type epoxy resin, epoxy equivalent: 210) and 16.2 parts by mass of YDCN-8170C (a trade name, produced by Tohto Kasei Co., Ltd., a bisphenol F type epoxy resin, epoxy equivalent: 157) as the epoxy resin (b), 15.3 parts by mass of Phenolite LF2882 (a trade name, produced by Dainippon Ink And Chemicals, Inc., a bisphenol A type novolac resin, hydroxyl group equivalent: 118 g/eq) as the epoxy resin curing agent, 0.1 part by mass of NUCA-189 (a trade name, produced by Nippon Unicar Co., Ltd., γ-mercaptopropyltrimethoxysilane) and 0.3 part by mass of NUCA-1160 (a trade name, produced by Nippon Unicar Co., Ltd., 3-ureidopropyltriethoxysilane) as the silane coupling agent, 30 parts by mass of A-DPH (a trade name, produced by Shin-Nakamura Chemical Co., Ltd., dipentaerythritol hexaacrylate) as the photoreactive monomer (d), 1.5 parts by mass of Irgacure 369 (a trade name, produced by Ciba Specialty Chemicals Co., Ltd., 2-benzyl-2-dimethylamino-1-(4-morpholinophenyl)-butanon-1-one, I-369) as the photo-base generating agent (e), and cyclohexanone as an organic solvent were mixed by stirring and deaerated in vacuum. The resulting varnish of a tacky adhesive resin composition was coated on a polyethylene terephthalate having a releasing surface (Teijin Tetoron Film A-31, produced by Teijin, Ltd.) having a thickness of 75 μm and dried by heating to 80° C. for 30 minutes, thereby providing a tacky adhesive sheet. An ultraviolet ray transmissible support base having a thickness of 80 μm (a three-layer film of low density polyethylene terephthalate/vinyl acetate/low density polyethylene terephthalate, FH-100, produced by Thermo Co., Ltd.) was laminated on the tacky adhesive sheet, thereby producing a tacky adhesive sheet containing the protective film (the aforementioned polyethylene terephthalate having a releasing surface), the tacky adhesive layer, and the ultraviolet ray transmissible support base.

The tacky adhesive sheet was irradiated with an ultraviolet ray of 365 nm in 500 mJ/cm² and then cured at 160° C. for 1 hour to prepare a tacky adhesive resin composition, which was measured for storage modulus with a dynamic modulus measuring device (DVE-V4, produced by Rheology Co., Ltd.) (specimen size: 20 mm in length, 4 mm in width and 80 μm in thickness, temperature increasing rate: 5° C. per minute, tensile mode, a vibration frequency: 10 Hz, automatic static load). As a result the storage modulus was 400 MPa at 25° C., 1 MPa at 125° C., and 5 MPa at 260° C.

### (2) Formation of Lower Clad Layer on Surface of Substrate of Substrate Having Metal Foil

The protective film of the tacky adhesive sheet produced in the item (1) was peeled, and the tacky adhesive sheet was laminated on a polyimide surface of a substrate having a copper foil (length: 150 mm, width: 150 mm, substrate: polyimide (thickness: 25 μm), thickness of copper foil: 18 μm, Metaloyal, a trade name, produced by Toray Advanced Film Co., Ltd.) with a roll laminator (HLM-1500, produced by Hitachi Chemical Technoplant Co., Ltd.) under conditions of a temperature of 60° C., a pressure of 0.5 MPa and a feeding speed of 0.2 m/min in such a manner that the tacky adhesive layer was in contact with the substrate. The thickness of the tacky adhesive layer was 10 μm. Subsequently, the tacky adhesive sheet was irradiated with an ultraviolet ray (365 nm) from the side of the support base in 250 mJ/cm², thereby reducing the adhesion force at the interface between the tacky adhesive layer and the support base, and the support base was released to expose the tacky adhesive layer.

Thereafter, the protective film of the resin film for forming a clad layer produced in Example 1 was released, and the resin film for forming a clad layer was laminated thereon in such a manner that the resin layer for forming a clad layer was in contact with the tacky adhesive layer with a roll laminator (HLM-1500, produced by Hitachi Chemical Technoplant Co., Ltd.) under conditions of a temperature of 80° C., a pressure of 0.5 MPa and a feeding speed of 0.5 m/min. Furthermore, after irradiation with an ultraviolet ray (wavelength: 365 nm) in 1 J/cm², the support base of the resin film for forming a clad layer was released, and the assembly was subjected to a heat treatment at 80° C. for 10 minutes to form a lower clad layer, thereby providing a substrate having a copper foil having a lower clad layer on the surface of the substrate.

### (3) Formation of Conductor Pattern

Photec H-N930 (a trade name, produced by Hitachi Chemical Co., Ltd.) for an etching resist having a thickness of 30 μm as a photocurable film was laminated on the surface of the copper foil of the substrate having a copper foil having a lower clad layer produced in the item (2) above. A photomask for a conductor pattern was superimposed on the dry film for an etching resist, which was exposed under vacuum of 60 mmHg. Thereafter, the etching resist was developed and sprayed with a cupric chloride solution to remove the unnecessary copper foil, thereby forming a conductor pattern.

### (4) Formation of Conductor Protective Layer (Solder Resist Layer)

A dry film for a solder resist, SR-2300G-50 (a trade name, produced by Hitachi Chemical Co., Ltd.) having a thickness of 50 μm was laminated on the substrate having the conductor pattern formed thereon. A photomask for the conductor pattern to be protected was superimposed on the dry film for a solder resist, which was exposed under vacuum of 60 mmHg. The dry film for a solder resist was developed to for a solder resist layer, followed by drying, thereby constructing an electric circuit board.

### (5) Formation of Core Pattern

The resin film for forming a core layer produced in Example 1 was laminated on the lower clad layer of the electric circuit board having a lower clad layer produced in the item (4) above with a roll laminator (HLM-1500, produced by Hitachi Chemical Technoplant Co., Ltd.) under conditions of a pressure of 0.4 MPa, a temperature of 50° C. and a laminating speed of 0.2 m/min, and after vacuuming to 500 Pa or less, they are laminated by heating with a vacuum pressure laminator (MVLP-500, produced by Meiki Co., Ltd.) as a flat plate laminator under conditions of a pressure of 0.4 MPa, a temperature of 50° C. and a pressing time of 30 seconds, thereby forming a core layer.

The core layer was irradiated with an ultraviolet ray (wavelength: 365 nm) in 0.6 J/cm² with the ultraviolet ray exposing machine through a negative photomask having a width of 50 μm and subjected to post-exposure heating at 80° C. for 5 minutes. Thereafter, the PET film as the support film was released, and the core pattern was developed with a developer solution (propylene glycol monomethyl ether acetate/N,N-dimethylacetamide=8/2 by mass). Subsequently, the assembly was rinsed with a rinsing liquid (isopropanol) and dried under heating to 100° C. for 10 minutes.

Subsequently, the resin film for forming a clad layer was laminated thereon under the same lamination conditions as in the lamination of the lower clad layer. Furthermore, after irradiating the assembly with an ultraviolet ray (wavelength: 365 nm) in 3 J/cm², the support base of the resin film for forming a clad layer was released, and then the assembly was subjected to a heat treatment at 180° C. for 1 hour to form an upper clad layer, thereby constructing an optical waveguide.

The refractive indices of the core layer and the clad layer were measured with a prism coupler (Model 2010, produced by Metricon Corporation), and the refractive index at a wavelength of 830 nm was 1.584 for the core layer and 1.550 for the clad layer. The transmission loss of the optical waveguide thus produced was measured with a plane emission laser of 850 nm (FLS-300-01-VCL, produced by EXFO, Inc.) as a light source and Q82214, produced by Advantest Corporation, as a light receiving sensor by a cut-back method (measured waveguide length: 10, 5, 3 and 2 cm, incoming fiber: GI-50/125 multimode fiber (NA=0.20), outgoing fiber: SI-114/125 (NA=0.22)), and the transmission loss was 0.1 dB/cm.

### Example 12

The same procedures as in Example 11 were performed except that the substrate having a metal foil in the item (2) in Example 11 was changed to a flexible electric circuit board having an electric wiring (length: 48 mm, width: 4 mm, base material: Kapton EN, 25 μm, thickness of copper circuit: 12 μm), and the items (3) and (4) in Example 1 were not performed.

The optoelectronic composite boards obtained in Examples 11 and 12 had a deviation in position of the optical wiring and the electric wiring of 10 μm or less per 100 mm and thus were excellent in coupling efficiency.

### Example 13

### (1) Construction of Optical Waveguide

The resin film for forming a core layer produced in Example 1 was laminated on the lower clad layer of the substrate having a copper foil having a lower clad layer produced in Example 11 with the same roll laminator under the conditions of a pressure of 0.4 MPa, a temperature of 50° C. and a laminating speed of 0.2 m/min, and after vacuuming to 500 Pa or less, they are laminated by heating with a vacuum pressure laminator (MVLP-500, produced by Meiki Co., Ltd.) as a flat plate laminator under conditions of a pressure of 0.4 MPa, a temperature of 50° C. and a pressing time of 30 seconds, thereby forming a core layer.

The core layer was irradiated with an ultraviolet ray (wavelength: 365 nm) in 0.6 J/cm² with the ultraviolet ray exposing machine through a negative photomask having a width of 50 μm and subjected to post-exposure heating at 80° C. for 5 minutes. Thereafter, the PET film as the support film was released, and the core pattern was developed with a developer solution (propylene glycol monomethyl ether acetate/N,N-dimethylacetamide=8/2 by mass). Subsequently, the assembly was rinsed with a rinsing liquid (isopropanol) and dried under heating to 100° C. for 10 minutes.

Subsequently, the resin film for forming a clad layer produced in Example 1 was laminated thereon under the same lamination conditions as in the lamination of the lower clad layer. Furthermore, after irradiating the assembly with an ultraviolet ray (wavelength: 365 nm) in 3 J/cm², the support base of the resin film for forming a clad layer was released, and then the assembly was subjected to a heat treatment at 180° C. for 1 hour to form an upper clad layer, thereby constructing an optical waveguide.

The refractive indices of the core layer and the clad layer were measured with a prism coupler (Model 2010), produced by Metricon Corporation, and the refractive index at a wavelength of 830 nm was 1.584 for the core layer and 1.550 for the clad layer. The transmission loss of the optical waveguide thus produced was measured with a plane emission laser of 850 nm (FLS-300-01-VCL, produced by EXFO, Inc.) as a light source and Q82214, produced by Advantest Corporation, as a light receiving sensor by a cut-back method (measured waveguide length: 10, 5, 3 and 2 cm, incoming fiber: GI-50/125 multimode fiber (NA=0.20), outgoing fiber: SI-114/125 (NA=0.22)), and the transmission loss was 0.1 dB/cm.

### (2) Formation of Conductor Pattern

Photec H-N930 (a trade name, produced by Hitachi Chemical Co., Ltd.) for an etching resist having a thickness of 30 μm as a photocurable film was laminated on the surface of the copper foil of the substrate having a copper foil. A photomask for a conductor pattern was superimposed on the dry film for an etching resist, which was exposed under vacuum of 60 mmHg. Thereafter, the etching resist was developed and sprayed with a cupric chloride solution to remove the unnecessary copper foil, thereby forming a conductor pattern.

### (3) Formation of Conductor Protective Layer (Solder Resist Layer)

A dry film for a solder resist, SR-2300G-50 (a trade name, produced by Hitachi Chemical Co., Ltd.) having a thickness of 50 μm was laminated on the substrate having the conductor pattern formed thereon. A photomask for the conductor pattern to be protected was superimposed on the dry film for a solder resist, which was exposed under vacuum of 60 mmHg. The dry film for a solder resist was developed to for a solder resist layer, followed by drying, thereby constructing an electric circuit board.

The optoelectronic composite board obtained in the aforementioned process had a deviation in position of the optical wiring and the electric wiring of 10 μm or less per 100 mm and thus were excellent in coupling efficiency.

### INDUSTRIAL APPLICABILITY

According to the method for producing a circuit board of the present invention, for a circuit board having only an electric circuit, a fine circuit board can be obtained that is reduced in defects due to short circuit or open circuit with less relief on a base material in the production process, and thus highly reliable circuit board (such as a mother board and a semiconductor chip-mounted board), semiconductor package and flexible board having a fine wiring can be produced. For a circuit board as a composite with an optical waveguide, distortion occurring in the optical waveguide in the production process can be considerably reduced to enhance the dimensional stability, and the core width can be formed uniformly with less relief on the base material, whereby the production method can be applied to a wide range of fields, such as optical interconnection with low transmission loss among boards or within a board.

According to the method for producing an optoelectronic composite member of the present invention, distortion occurring in the optical waveguide in the production process can be considerably reduced to enhance the dimensional stability, whereby the production method can be applied to a wide range of fields, such as optical interconnection among boards or within a board.

According to the method for producing an optoelectronic composite substrate of the present invention, an excellent optoelectronic composite substrate can be produced efficiently without a problem of positional alignment. An optoelectronic composite substrate produced by the method of the present invention can be applied to a wide range of fields, such as optical interconnection, and is effective in the case where an extremely precise core pattern is demanded and the case where an optoelectronic composite board with a large area is demanded.

1. A method for producing a circuit board, comprising, in this order, a step A of forming a circuit on a first substrate; a step B of laminating a first support on a surface of the first substrate having the circuit formed, through a first releasing layer; and a step C of forming a second substrate or circuit on a surface of the first substrate opposite to the surface having the circuit formed.

2. The method for producing a circuit board according to claim 1, wherein, in the step B, the circuit formed on the first substrate is embedded in the first releasing layer.

3. The method for producing a circuit board according to claim 1, wherein, the method further comprises, before the step A, a step D of laminating the first substrate on a second support; in the step A, the circuit is formed on a surface of the first substrate opposite to the surface having the second support formed; and the method further comprises, before the step C, a step E of removing the second support from the first substrate.

4. A method for producing an optoelectronic composite member, comprising, in this order, a step of laminating an electric circuit board on a second support; a step of laminating a first support; a step of releasing the second support; and a step of forming an optical waveguide on a surface where the second support is released.

5. The method for producing an optoelectronic composite member according to claim 4, wherein a circuit is formed on the electric circuit board to form an electric circuit board having an electric circuit layer, after laminating the electric circuit board on the second support and before forming the optical waveguide.

6. A method for producing an optoelectronic composite substrate, comprising a first step of forming a lower clad layer on a substrate surface of an electric circuit board directly or through an adhesive layer, or forming a lower clad layer on a substrate surface of a substrate having a metal foil directly or through an adhesive layer, and then converting the metal foil of the substrate having the metal foil to a conductor pattern to construct an electric circuit board, thereby providing an electric circuit board having the lower clad layer; and a second step of forming sequentially a core pattern and an upper clad layer on the lower clad layer to construct an optical waveguide.

7. A method for producing an optoelectronic composite substrate, comprising a first step of forming a lower clad layer on a substrate surface of a substrate having a metal foil directly or through an adhesive layer; a second step of forming sequentially a core pattern and an upper clad layer on the lower clad layer to construct an optical waveguide; and a third step of converting the metal foil of the substrate having the metal foil to a conductor pattern to construct an electric circuit board.

8. The method for producing a circuit board according to claim 3, wherein in the step D, the first substrate is formed on the second substrate through a second releasing layer; and in the step E, the second releasing layer and the second support are removed from the first substrate.

9. The method for producing a circuit board according to claim 1, wherein the method further comprises, after the step C, a step F of removing the first support and the first releasing layer from the first substrate.

10. The method for producing a circuit board according to claim 1, wherein in the step A, the first substrate is a substrate having a metal layer, and the metal layer is patterned to form a circuit.

11. The method for producing a circuit board according to claim 1, wherein the second substrate is an optical waveguide.

12. The method for producing a circuit board according to claim 1, wherein the second substrate is a multilayer substrate.

13. The method for producing a circuit board according to claim 1, wherein the second substrate is an optoelectronic mixed substrate containing an optical waveguide having formed thereon an electric circuit or an electric circuit board.

14. The method for producing a circuit board according to claim 1, the first substrate is an optoelectronic mixed substrate containing a substrate X having formed thereon an optical waveguide and an electric circuit board in this order, and the circuit is formed on a surface of the substrate X opposite to the surface having the optical waveguide formed.

15. The method for producing an optoelectronic composite member according to claim 4, wherein after releasing the second support and before forming the optical waveguide, a circuit is formed on the surface of the electric circuit board where the second support is released, thereby forming an electric circuit board having an electric circuit layer formed.

16. The method for producing an optoelectronic composite member according to claim 4, wherein the method further comprises, after forming the optical waveguide, a step of laminating an electric circuit board on the optical waveguide.

17. The method for producing an optoelectronic composite member according to claim 4, wherein the method further comprises, after forming the optical waveguide or after laminating an electric circuit board on the optical waveguide, a step of releasing the first support.

18. The method for producing an optoelectronic composite member according to claim 17, wherein the method further comprises, after releasing the first support from the electric circuit board, a step of forming an electric circuit board or an optical waveguide on a surface where the first support is released.

19. The method for producing an optoelectronic composite member according to claim 4, wherein the first support is an electric circuit board or an optical waveguide.

20. The method for producing an optoelectronic composite member according to claim 4, wherein the electric circuit board is a substrate having a metal layer on one surface thereof or having metal layers on both surfaces thereof.

21. The method for producing an optoelectronic composite member according to claim 4, wherein the electric circuit board is a resin layer having a metal layer on one surface thereof or having metal layers on both surfaces thereof.

22. The method for producing an optoelectronic composite member according to claim 4, wherein the electric circuit board is an insulating resin layer or substrate, and the method further comprises a step of laminating a metal layer on one surface or both surfaces of the insulating resin layer or substrate.

23. The method for producing an optoelectronic composite member according to claim 5, wherein the electric circuit layer is formed by patterning the electric circuit board by any one of a subtractive method, a semi-additive method and an additive method.

24. The method for producing an optoelectronic composite member according to claim 20, wherein the electric circuit layer or the electric circuit board has a multilayer structure.

25. The method for producing an optoelectronic composite member according to claim 4, wherein the optical waveguide is formed in such a manner that a lower clad layer is formed on the electric circuit board or the electric circuit board having a multilayer structure, then a resin for forming a core layer is laminated on the lower clad layer to form a core pattern, and an upper clad layer is formed on the core pattern.

26. The method for producing an optoelectronic composite member according to claim 4, wherein the optical waveguide is formed in such a manner that an optical waveguide having a lower clad layer, a core pattern and an upper clad layer is laminated on the electric circuit board or the electric circuit board having a multilayer structure.

27. The method for producing an optoelectronic composite member according to claim 4, wherein the electric circuit board is a rigid circuit board or a flexible circuit board.

28. The method for producing an optoelectronic composite member according to claim 4, wherein the method further comprises a step of forming an optical path conversion mirror on the optical waveguide.

29. The method for producing an optoelectronic composite substrate according to claim 6, wherein the second step comprises laminating a resin film for forming a core layer on the lower clad layer to form a core layer, forming the core pattern by exposure and development, and laminating a resin film for forming an upper clad layer on the core pattern.

30. The method for producing an optoelectronic composite substrate according to claim 6, wherein the electric circuit board is constructed by forming a resist pattern with an etching resist on the metal foil of the substrate having a metal foil, then forming the conductor pattern by etching, and removing the etching resist.

31. The method for producing an optoelectronic composite substrate according to claim 6, wherein the electric circuit board is constructed by forming a resist pattern with a plating resist on the metal foil of the substrate having a metal foil, then forming the conductor pattern by pattern plating, and then performing removal of the plating resist and etching of the exposed metal foil.

32. The method for producing an optoelectronic composite substrate according to claim 7, wherein the third step comprises forming a resist pattern with an etching resist on the metal foil, then forming the conductor pattern by etching, and removing the etching resist.

33. The method for producing an optoelectronic composite substrate according to claim 7, wherein the third step comprises forming a resist pattern with a plating resist on the metal foil, then forming the conductor pattern by pattern plating, and then performing removal of the plating resist and etching of the exposed metal foil.

34. The method for producing an optoelectronic composite substrate according to claim 6, wherein the method further comprises forming a conductor protective layer on the conductor pattern.

35. The method for producing an optoelectronic composite substrate according to claim 6, wherein the optoelectronic composite substrate is a flexible type optoelectronic composite substrate.

36. An optoelectronic composite substrate produced by the production method according to claim 6.

37. An optoelectronic composite module comprising the optoelectronic composite substrate according to claim 36.
